(19) United States
(12) Patent Application Publication
(10) Pub. No.: US 2012/0091520 A1
(43) Pub. Date: Apr. 19, 2012

(54) SEMICONDUCTOR DEVICE, METHOD FOR FORMING THE SAME, AND DATA PROCESSING SYSTEM

(75) Inventor: Nobuyuki NAKAMURA, Tokyo (JP)

(73) Assignee: ELPIDA MEMORY, INC., Tokyo (JP)

(21) Appl. No.: 13/271,853

(22) Filed: Oct. 12, 2011

(30) Foreign Application Priority Data
Oct. 15, 2010 (JP) 2010-232641

(51) Int. Cl. H01L 27/108

(52) U.S. Cl. 257/303; 257/E27.084

(57) ABSTRACT

A semiconductor device includes a semiconductor substrate, a first interlayer insulating film over the semiconductor substrate, a first interconnect over the first interlayer insulating film, and a via plug penetrating the semiconductor substrate and the first interlayer insulating film. The via plug is coupled to the first interconnect.

### BACKGROUND OF THE INVENTION

1. Field of the Invention

The present invention relates to a semiconductor device, to a method for manufacturing a semiconductor device, and to a data processing system. Priority is claimed on Japanese Patent Application No. 2010-232641, filed Oct. 15, 2010, the content of which is incorporated herein by reference.

2. Description of the Related Art

In recent years, with the move to high-capacity semiconductor devices, progress has been made in development of art for high-density packaging of semiconductor memories such as DRAMs. Known art for achieving a large-capacity memory with a limited packaging surface area includes stacking a plurality of DRAMs in a single semiconductor package, and making electrical connections between the DRAMs using through electrodes. These matters are disclosed in Japanese Unexamined Patent Application, First Publications, Nos. JPA 2009-277719, JPA 2009-111061, and JPA 2008-251964.

Although a method is known of integrating a large number of MOS transistors into a memory cell region to achieve micro-structuring of a semiconductor device, the distance between adjacent MOS transistors becomes short. For this reason, the length of the MOS transistor gate also becomes shorting, making it difficult to obtain a transistor with the desired characteristics. To avoid this short-channel effect in the MOS transistors, a trench gate transistor is adopted in which a gate electrode is buried in a trench formed within the semiconductor substrate. These matters are disclosed in Japanese Unexamined Patent Application, First Publication, No. JPA 2006-339476.

### SUMMARY

In one embodiment, a semiconductor device may include, but is not limited to, a semiconductor substrate having a memory cell region and a peripheral circuit region; memory cells in the memory cell region; buried word lines in a plurality of grooves of the semiconductor substrate in the memory cell region; a first interlayer insulating film over the semiconductor substrate; a first interconnect over the first interlayer insulating film; and a via plug penetrating the semiconductor substrate and the first interlayer insulating film. The via plug is coupled to the first interconnect.

In another embodiment, a semiconductor device may include, but is not limited to, a semiconductor substrate having a memory cell region and a peripheral circuit region; a first interlayer insulating film over the semiconductor substrate; a first local interconnect disposed over the first interlayer insulating film, the first local interconnect being in the peripheral circuit region, the first local interconnect including a first patterned portion of a conductive film; a capacitive contact pad disposed over the first interlayer insulating film and in the memory cell region; a capacitive contact pad disposed over the first interlayer insulating film, the capacitive contact pad being in the memory cell region, the capacitive contact pad including a second patterned portion of the conductive film; and a via plug penetrating the semiconductor substrate and the first interlayer insulating film. The via plug is coupled to the first local interconnect.

In still another embodiment, a semiconductor device may include, but is not limited to, a semiconductor substrate having a memory cell region and a peripheral circuit region; a first interlayer insulating film over the semiconductor substrate; memory cells in the memory cell region; buried word lines in a plurality of grooves of the semiconductor substrate in the memory cell region; a first local interconnect disposed over the first interlayer insulating film, the first local interconnect being in the peripheral circuit region, the first local interconnect including a first patterned portion of a conductive film; a capacitive contact pad disposed over the first interlayer insulating film, the capacitive contact pad being in the memory cell region, the capacitive contact pad including a second patterned portion of the conductive film; and a via plug penetrating the semiconductor substrate and the first interlayer insulating film, the via plug being coupled to the first interconnect, the via plug including a projecting portion that projects from the semiconductor substrate.

In yet another embodiment, a method of forming a semiconductor device may include, but is not limited to, forming a plurality of grooves in a memory cell region of a semiconductor substrate; forming first gate insulating films on inner walls of the plurality of grooves; forming a cell gate electrode film covering the first gate insulating films and a main surface of the semiconductor substrate; selectively removing the cell gate electrode film to form cell gate electrodes in the plurality of grooves, the cell gate electrodes having top surfaces which are lower than the main surface of the semiconductor substrate; forming first insulating films over the cell gate electrodes and in the plurality of grooves; forming second gate insulating films on the main surface of the semiconductor substrate; forming peripheral gate electrodes on the second gate insulating films in a peripheral circuit region of the semiconductor substrate; forming a first interlayer insulating film covering the main surface of the semiconductor substrate; forming a first metal film over the first interlayer insulating film; patterning the first metal film to form simultaneously a capacitive contact pad in the memory cell region and a local interconnect in the peripheral circuit region; forming an opening which penetrates the semiconductor substrate and the first interlayer insulator to expose a bottom surface of the local interconnect; and forming a via plug in the opening, the via plug being connected to the local interconnect.

In an additional embodiment, a data processor includes a semiconductor device as recited above.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic plan view of a semiconductor device in accordance with one or more embodiments of the present invention;

FIG. 2 is a fragmentary plan view of memory cell region of the semiconductor device of FIG. 1;

FIG. 3A is a fragmentary cross sectional elevation view of the semiconductor device, taken along an A-A′ line of FIG. 2;

FIG. 3B is a fragmentary cross sectional elevation view of the semiconductor device, taken along a B-B′ line of FIG. 2;

FIG. 4 is a fragmentary cross sectional elevation view of the semiconductor device in accordance with one or more embodiments of the present invention;

FIG. 5 is a fragmentary cross sectional elevation view of a step, subsequent to the step of FIG. 4, involved in the method of forming the semiconductor device in accordance with one or more embodiments of the present invention;

FIG. 6 is a fragmentary cross sectional elevation view of a step, subsequent to the step of FIG. 5, involved in the method of forming the semiconductor device in accordance with one or more embodiments of the present invention;

FIG. 7A is a fragmentary cross sectional elevation view, taken along an A-A′ line of FIG. 2, of a step, subsequent to the step of FIG. 6, involved in the method of forming the semiconductor device in accordance with one or more embodiments of the present invention;

FIG. 7B is a fragmentary cross sectional elevation view, taken along a B-B′ line of FIG. 2, of a step, subsequent to the step of FIG. 6, involved in the method of forming the semiconductor device in accordance with one or more embodiments of the present invention;

FIG. 8 is a fragmentary cross sectional elevation view of a step, subsequent to the step of FIGS. 7A and 7B, involved in the method of forming the semiconductor device in accordance with one or more embodiments of the present invention;

FIG. 9A is a fragmentary cross sectional elevation view, taken along an A-A′ line of FIG. 2, of a step, subsequent to the step of FIG. 8, involved in the method of forming the semiconductor device in accordance with one or more embodiments of the present invention;

FIG. 9B is a fragmentary cross sectional elevation view, taken along a B-B′ line of FIG. 2, of a step, subsequent to the step of FIG. 8, involved in the method of forming the semiconductor device in accordance with one or more embodiments of the present invention;

FIG. 10 is a fragmentary cross sectional elevation view of a step, subsequent to the step of FIGS. 9A and 9B, involved in the method of forming the semiconductor device in accordance with one or more embodiments of the present invention;

FIG. 11A is a fragmentary cross sectional elevation view, taken along an A-A′ line of FIG. 2, of a step, subsequent to the step of FIG. 10, involved in the method of forming the semiconductor device in accordance with one or more embodiments of the present invention;

FIG. 11B is a fragmentary cross sectional elevation view, taken along a B-B′ line of FIG. 2, of a step, subsequent to the step of FIG. 10, involved in the method of forming the semiconductor device in accordance with one or more embodiments of the present invention;

FIG. 12 is a fragmentary cross sectional elevation view of a step, subsequent to the step of FIGS. 11A and 11B, involved in the method of forming the semiconductor device in accordance with one or more embodiments of the present invention;

FIG. 13 is a fragmentary cross sectional elevation view of a step, subsequent to the step of FIG. 12, involved in the method of forming the semiconductor device in accordance with one or more embodiments of the present invention;

FIG. 14A is a fragmentary cross sectional elevation view, taken along an A-A′ line of FIG. 2, of a step, subsequent to the step of FIG. 13, involved in the method of forming the semiconductor device in accordance with one or more embodiments of the present invention;

FIG. 14B is a fragmentary cross sectional elevation view, taken along a B-B′ line of FIG. 2, of a step, subsequent to the step of FIG. 13, involved in the method of forming the semiconductor device in accordance with one or more embodiments of the present invention;

FIG. 15 is a fragmentary cross sectional elevation view of a step, subsequent to the step of FIGS. 14A and 14B, involved in the method of forming the semiconductor device in accordance with one or more embodiments of the present invention;

FIG. 16A is a fragmentary cross sectional elevation view, taken along an A-A′ line of FIG. 2, of a step, subsequent to the step of FIG. 15, involved in the method of forming the semiconductor device in accordance with one or more embodiments of the present invention;

FIG. 16B is a fragmentary cross sectional elevation view, taken along a B-B′ line of FIG. 2, of a step, subsequent to the step of FIG. 15, involved in the method of forming the semiconductor device in accordance with one or more embodiments of the present invention;

FIG. 17 is a fragmentary cross sectional elevation view of a step, subsequent to the step of FIGS. 16A and 16B, involved in the method of forming the semiconductor device in accordance with one or more embodiments of the present invention;

FIG. 18A is a fragmentary cross sectional elevation view, taken along an A-A′ line of FIG. 2, of a step, subsequent to the step of FIG. 17, involved in the method of forming the semiconductor device in accordance with one or more embodiments of the present invention;

FIG. 18B is a fragmentary cross sectional elevation view, taken along a B-B′ line of FIG. 2, of a step, subsequent to the step of FIG. 17, involved in the method of forming the semiconductor device in accordance with one or more embodiments of the present invention;

FIG. 19 is a fragmentary cross sectional elevation view of a step, subsequent to the step of FIGS. 18A and 18B, involved in the method of forming the semiconductor device in accordance with one or more embodiments of the present invention;

FIG. 20A is a fragmentary cross sectional elevation view, taken along an A-A′ line of FIG. 2, of a step, subsequent to the step of FIG. 19, involved in the method of forming the semiconductor device in accordance with one or more embodiments of the present invention;

FIG. 20B is a fragmentary cross sectional elevation view, taken along a B-B′ line of FIG. 2, of a step, subsequent to the step of FIG. 19, involved in the method of forming the semiconductor device in accordance with one or more embodiments of the present invention;

FIG. 21A is a fragmentary cross sectional elevation view, taken along an A-A′ line of FIG. 2, of a step, subsequent to the step of FIGS. 20A and 20B, involved in the method of forming the semiconductor device in accordance with one or more embodiments of the present invention;

FIG. 21B is a fragmentary cross sectional elevation view, taken along a B-B′ line of FIG. 2, of a step, subsequent to the step of FIGS. 20A and 20B, involved in the method of forming the semiconductor device in accordance with one or more embodiments of the present invention;

FIG. 22 is a fragmentary cross sectional elevation view of a step, subsequent to the step of FIGS. 21A and 21B, involved in the method of forming the semiconductor device in accordance with one or more embodiments of the present invention;

FIG. 23A is a fragmentary cross sectional elevation view, taken along an A-A′ line of FIG. 2, of a step, subsequent to the step of FIG. 22, involved in the method of forming the semiconductor device in accordance with one or more embodiments of the present invention;

FIG. 23B is a fragmentary cross sectional elevation view, taken along a B-B′ line of FIG. 2, of a step, subsequent to the step of FIG. 22, involved in the method of forming the semiconductor device in accordance with one or more embodiments of the present invention;

FIG. 24A is a fragmentary cross sectional elevation view, taken along an A-A′ line of FIG. 2, of a step, subsequent to the step of FIGS. 23A and 23B, involved in the method of forming the semiconductor device in accordance with one or more embodiments of the present invention;

FIG. 24B is a fragmentary cross sectional elevation view, taken along a B-B′ line of FIG. 2, of a step, subsequent to the step of FIGS. 23A and 23B, involved in the method of forming the semiconductor device in accordance with one or more embodiments of the present invention;

FIG. 25 is a fragmentary cross sectional elevation view of a step, subsequent to the step of FIGS. 24A and 24B, involved in the method of forming the semiconductor device in accordance with one or more embodiments of the present invention;

FIG. 26 is a fragmentary cross sectional elevation view of a step, subsequent to the step of FIG. 25, involved in the method of forming the semiconductor device in accordance with one or more embodiments of the present invention;

FIG. 27A is a fragmentary cross sectional elevation view, taken along an A-A′ line of FIG. 2, of a step, subsequent to the step of FIG. 26, involved in the method of forming the semiconductor device in accordance with one or more embodiments of the present invention;

FIG. 27B is a fragmentary cross sectional elevation view, taken along an B-B′ line of FIG. 2, of a step, subsequent to the step of FIG. 26, involved in the method of forming the semiconductor device in accordance with one or more embodiments of the present invention;

FIG. 28 is a fragmentary cross sectional elevation view of a step, subsequent to the step of FIGS. 27A and 27B, involved in the method of forming the semiconductor device in accordance with one or more embodiments of the present invention;

FIG. 29A is a fragmentary cross sectional elevation view, taken along an A-A′ line of FIG. 2, of a step, subsequent to the step of FIG. 28, involved in the method of forming the semiconductor device in accordance with one or more embodiments of the present invention;

FIG. 29B is a fragmentary cross sectional elevation view, taken along a B-B′ line of FIG. 2, of a step, subsequent to the step of FIG. 28, involved in the method of forming the semiconductor device in accordance with one or more embodiments of the present invention;

FIG. 30 is a fragmentary cross sectional elevation view of a step, subsequent to the step of FIGS. 29A and 29B, involved in the method of forming the semiconductor device in accordance with one or more embodiments of the present invention;

FIG. 31A is a fragmentary cross sectional elevation view, taken along an A-A′ line of FIG. 2, of a step, subsequent to the step of FIG. 30, involved in the method of forming the semiconductor device in accordance with one or more embodiments of the present invention;

FIG. 31B is a fragmentary cross sectional elevation view, taken along a B-B′ line of FIG. 2, of a step, subsequent to the step of FIG. 30, involved in the method of forming the semiconductor device in accordance with one or more embodiments of the present invention;

FIG. 32 is a fragmentary cross sectional elevation view of a step, subsequent to the step of FIGS. 31A and 31B, involved in the method of forming the semiconductor device in accordance with one or more embodiments of the present invention;

FIG. 33A is a fragmentary cross sectional elevation view, taken along an A-A′ line of FIG. 2, of a step, subsequent to the step of FIG. 32, involved in the method of forming the semiconductor device in accordance with one or more embodiments of the present invention;

FIG. 33B is a fragmentary cross sectional elevation view, taken along a B-B′ line of FIG. 2, of a step, subsequent to the step of FIG. 32, involved in the method of forming the semiconductor device in accordance with one or more embodiments of the present invention;

FIG. 34 is a fragmentary cross sectional elevation view of a step, subsequent to the step of FIGS. 33A and 33B, involved in the method of forming the semiconductor device in accordance with one or more embodiments of the present invention;

FIG. 35 is a fragmentary cross sectional elevation view of a step, subsequent to the step of FIG. 36, involved in the method of forming the semiconductor device in accordance with one or more embodiments of the present invention;

FIG. 36A is a fragmentary cross sectional elevation view, taken along an A-A′ line of FIG. 2, of a step, subsequent to the step of FIG. 35, involved in the method of forming the semiconductor device in accordance with one or more embodiments of the present invention;

FIG. 36B is a fragmentary cross sectional elevation view, taken along a B-B′ line of FIG. 2, of a step, subsequent to the step of FIG. 35, involved in the method of forming the semiconductor device in accordance with one or more embodiments of the present invention;

FIG. 37 is a fragmentary cross sectional elevation view of a step, subsequent to the step of FIGS. 36A and 36B, involved in the method of forming the semiconductor device in accordance with one or more embodiments of the present invention;

FIG. 38A is a fragmentary cross sectional elevation view, taken along an A-A′ line of FIG. 2, of a step, subsequent to the step of FIG. 37, involved in the method of forming the semiconductor device in accordance with one or more embodiments of the present invention;

FIG. 38B is a fragmentary cross sectional elevation view, taken along a B-B′ line of FIG. 2, of a step, subsequent to the step of FIG. 37, involved in the method of forming the semiconductor device in accordance with one or more embodiments of the present invention;

FIG. 39 is a fragmentary cross sectional elevation view of a step, subsequent to the step of FIGS. 38A and 38B, involved in the method of forming the semiconductor device in accordance with one or more embodiments of the present invention;

FIG. 40A is a fragmentary cross sectional elevation view, taken along an A-A′ line of FIG. 2, of a step, subsequent to the step of FIG. 39, involved in the method of forming the semiconductor device in accordance with one or more embodiments of the present invention;

FIG. 40B is a fragmentary cross sectional elevation view, taken along a B-B′ line of FIG. 2, of a step, subsequent to the step of FIG. 39, involved in the method of forming the semiconductor device in accordance with one or more embodiments of the present invention;

FIG. 41A is a fragmentary cross sectional elevation view, taken along an A-A′ line of FIG. 2, of a step, subsequent to the step of FIGS. 40A and 40B, involved in the method of forming the semiconductor device in accordance with one or more embodiments of the present invention;

FIG. 41B is a fragmentary cross sectional elevation view, taken along a B-B′ line of FIG. 2, of a step, subsequent to the step of FIGS. 40A and 40B, involved in the method of forming the semiconductor device in accordance with one or more embodiments of the present invention;

FIG. 42 is a fragmentary cross sectional elevation view of a step, subsequent to the step of FIGS. 41A and 41B, involved in the method of forming the semiconductor device in accordance with one or more embodiments of the present invention;

FIG. 43A is a fragmentary cross sectional elevation view, taken along an A-A′ line of FIG. 2, of a step, subsequent to the step of FIG. 42, involved in the method of forming the semiconductor device in accordance with one or more embodiments of the present invention;

FIG. 43B is a fragmentary cross sectional elevation view, taken along a B-B′ line of FIG. 2, of a step, subsequent to the step of FIG. 42, involved in the method of forming the semiconductor device in accordance with one or more embodiments of the present invention;

FIG. 44A is a fragmentary cross sectional elevation view, taken along an A-A′ line of FIG. 2, of a step, subsequent to the step of FIGS. 43A and 43B, involved in the method of forming the semiconductor device in accordance with one or more embodiments of the present invention;

FIG. 44B is a fragmentary cross sectional elevation view, taken along a B-B′ line of FIG. 2, of a step, subsequent to the step of FIGS. 43A and 43B, involved in the method of forming the semiconductor device in accordance with one or more embodiments of the present invention;

FIG. 45 is a fragmentary cross sectional elevation view of a step, subsequent to the step of FIGS. 44A and 44B, involved in the method of forming the semiconductor device in accordance with one or more embodiments of the present invention;

FIG. 46A is a fragmentary cross sectional elevation view, taken along an A-A′ line of FIG. 2, of a step, subsequent to the step of FIG. 45, involved in the method of forming the semiconductor device in accordance with one or more embodiments of the present invention;

FIG. 46B is a fragmentary cross sectional elevation view, taken along a B-B′ line of FIG. 2, of a step, subsequent to the step of FIG. 45, involved in the method of forming the semiconductor device in accordance with one or more embodiments of the present invention;

FIG. 47 is a fragmentary cross sectional elevation view of a step, subsequent to the step of FIGS. 46A and 46B, involved in the method of forming the semiconductor device in accordance with one or more embodiments of the present invention;

FIG. 48A is a fragmentary cross sectional elevation view, taken along an A-A′ line of FIG. 2, of a step, subsequent to the step of FIG. 47, involved in the method of forming the semiconductor device in accordance with one or more embodiments of the present invention;

FIG. 48B is a fragmentary cross sectional elevation view, taken along a B-B′ line of FIG. 2, of a step, subsequent to the step of FIG. 47, involved in the method of forming the semiconductor device in accordance with one or more embodiments of the present invention;

FIG. 49A is a fragmentary cross sectional elevation view, taken along an A-A′ line of FIG. 2, of a step, subsequent to the step of FIGS. 48A and 48B, involved in the method of forming the semiconductor device in accordance with one or more embodiments of the present invention;

FIG. 49B is a fragmentary cross sectional elevation view, taken along a B-B′ line of FIG. 2, of a step, subsequent to the step of FIGS. 48A and 48B, involved in the method of forming the semiconductor device in accordance with one or more embodiments of the present invention;

FIG. 50A is a fragmentary cross sectional elevation view, taken along an A-A′ line of FIG. 2, of a step, subsequent to the step of FIGS. 49A and 49B, involved in the method of forming the semiconductor device in accordance with one or more embodiments of the present invention;

FIG. 50B is a fragmentary cross sectional elevation view, taken along a B-B′ line of FIG. 2, of a step, subsequent to the step of FIGS. 49A and 49B, involved in the method of forming the semiconductor device in accordance with one or more embodiments of the present invention;

FIG. 51 is a fragmentary cross sectional elevation view of a step, subsequent to the step of FIGS. 50A and 50B, involved in the method of forming the semiconductor device in accordance with one or more embodiments of the present invention;

FIG. 52A is a fragmentary cross sectional elevation view, taken along an A-A′ line of FIG. 2, of a step, subsequent to the step of FIG. 51, involved in the method of forming the semiconductor device in accordance with one or more embodiments of the present invention;

FIG. 52B is a fragmentary cross sectional elevation view, taken along a B-B′ line of FIG. 2, of a step, subsequent to the step of FIG. 51, involved in the method of forming the semiconductor device in accordance with one or more embodiments of the present invention;

FIG. 53 is a fragmentary cross sectional elevation view of a step, subsequent to the step of FIGS. 51A and 51B, involved in the method of forming the semiconductor device in accordance with one or more embodiments of the present invention;

FIG. 54A is a fragmentary cross sectional elevation view, taken along an A-A′ line of FIG. 2, of a step, subsequent to the step of FIG. 53, involved in the method of forming the semiconductor device in accordance with one or more embodiments of the present invention;

FIG. 54B is a fragmentary cross sectional elevation view, taken along a B-B′ line of FIG. 2, of a step, subsequent to the step of FIG. 53, involved in the method of forming the semiconductor device in accordance with one or more embodiments of the present invention;

FIG. 55 is a fragmentary cross sectional elevation view of a step, subsequent to the step of FIGS. 54A and 54B, involved in the method of forming the semiconductor device in accordance with one or more embodiments of the present invention;

FIG. 56 is a fragmentary cross sectional elevation view of a step, subsequent to the step of FIG. 55, involved in the method of forming the semiconductor device in accordance with one or more embodiments of the present invention;

FIG. 57 is a fragmentary cross sectional elevation view of a step, subsequent to the step of FIG. 56, involved in the method of forming the semiconductor device in accordance with one or more embodiments of the present invention;

FIG. 58 is a fragmentary cross sectional elevation view of a step, subsequent to the step of FIG. 57, involved in the method of forming the semiconductor device in accordance with one or more embodiments of the present invention;

FIG. 59 is a fragmentary cross sectional elevation view of a step, subsequent to the step of FIG. 58, involved in the method of forming the semiconductor device in accordance with one or more embodiments of the present invention;

FIG. 60 is a cross sectional elevation view of a semiconductor package including DRAM in accordance with one or more embodiments of the present invention;

FIG. 61 is a cross sectional elevation view of a semiconductor package including DRAM in accordance with one or more embodiments of the present invention; and

FIG. 62 is a cross sectional elevation view of a date processor including DRAM in accordance with one or more embodiments of the present invention.

### DETAILED DESCRIPTION OF THE PREFERRED EMBODIMENTS

Before describing the present invention, the related art will be explained, in order to facilitate the understanding of the present invention.

In a memory cell of a conventional DRAM (dynamic random access memory) using a trench gate type transistor, a part of the gate electrode protrudes outward from the main surface of the semiconductor substrate. For this reason, it is not possible restrict the length of a contact plug provided between an interconnect layer of bit lines and the like provided in a layer over the gate electrode and the semiconductor substrate. Also, in a DRAM using the gate electrodes as word lines and having bit lines provided in a direction that intersects with the word lines, a contact plug must be formed between adjacent word lines. For this reason, with a reduction of the spacing between word lines, there is also a reduction of the contacting surface area between the contact plug and the semiconductor substrate. For this reason, it is difficult to form the contact plugs, and there is the problem of a high connection resistance via the contact plug.

The difficulty of forming a shrunken contact plug is a great impediment to the achievement of shrunken DRAMs.

Given the above, for the purpose of facilitating the formation of the above-noted contact plugs and avoiding the problem of the short-channel effect in the MOS transistors, investigations have been done regarding a buried-gate MOS transistor in which a word line that functions as a gate electrode is buried into a trench formed within the semiconductor substrate and also in which the top part of the word line in the trench is buried by an insulating film. A buried-gate MOS transistor is constituted so that the gate electrode (word line) is buried within the semiconductor substrate. For this reason, it is only the bit line that is positioned above the surface of the semiconductor substrate as an interconnect that is part of the memory cell. For this reason, the method for manufacturing a semiconductor device having a buried-gate MOS translator alleviates the difficulty in processing the contact plug in the memory cell formation processes.

If a buried-gate MOS translator is formed in a peripheral circuit region, there is the problem of a reduction in the on current. For this reason, a DRAM having a new structure, in which a buried-gate MOS translator is formed in the memory cell region and a conventional planar gate electrode is formed in the peripheral circuit region, is desirable.

Upon the inventors researching a method for forming in a DRAM a through electrode having the above-noted new structure, it became clear that the match between the method for manufacturing the DRAM having the new structure and the method for manufacturing a through electrode is very poor. For example, if a through electrode is formed in a DRAM having the above-noted new structure using the related art method of Japanese Unexamined Patent Application, First Publications, Nos. JPA 2009-277719, and JPA 2009-111061, the matching between the process steps to form the memory cell and the process steps to form the peripheral circuit region is very poor, and it is not possible to apply the conventional method for manufacturing a through electrode to the method for manufacturing a DRAM having the above-noted new structure. This is because the method for manufacturing a DRAM having the above-noted new structure is complex and differs greatly from the method of manufacturing a conventional DRAM.

Specifically, for example, in the method disclosed in Japanese Unexamined Patent Application, First Publication, No. JPA 2009-111061, a conductor (pad) that is formed simultaneously using the memory cell formation process is used to form a through electrode. It is difficult to form this type of structure simultaneously with the memory cell having the new structure noted above. Although it is possible to form such a structure by adding to the manufacturing process, this greatly increases the manufacturing cost. For this reason, it is not possible to use the method disclosed in Japanese Unexamined Patent Application, First Publication, No. JPA 2009-111061, as a method for manufacturing a DRAM having the above-noted new structure. Also, if electrically conductive polysilicon is used as a contact pad, such as in the method disclosed in Japanese Unexamined Patent Application, First Publication, No. JPA 2009-111061, there is the problem of the connection resistance increasing, and the electrical characteristics worsening.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a semiconductor substrate having a memory cell region and a peripheral circuit region; memory cells in the memory cell region; buried word lines in a plurality of grooves of the semiconductor substrate in the memory cell region; a first interlayer insulating film over the semiconductor substrate; a first interconnect over the first interlayer insulating film; and a via plug penetrating the semiconductor substrate and the first interlayer insulating film. The via plug is coupled to the first interconnect.

In some cases, the via plug may be in contact with the first interconnect.

In some cases, the first interconnect may include, but is not limited to, a local interconnect disposed on the first interlayer insulating film.

In some cases, the via plug may include, but is not limited to, a projecting portion that projects from the semiconductor substrate.

In some cases, the semiconductor device may further include, but is not limited to, a first insulating film on a first surface of the semiconductor substrate. The first interlayer insulating film is disposed over a second surface of the semiconductor substrate, the second surface is opposite to the first surface. The second surface is opposite to the first surface. The via plug penetrates the first insulating film, the semiconductor substrate and the first interlayer insulating film. The projecting portion projects from the first insulating film.

In some cases, the semiconductor device may further include, but is not limited to, a first isolating film in the semiconductor substrate. The first isolating film surrounds the via plug in the semiconductor substrate. The first isolating film isolates the via plug from outside the first isolating film.

In some cases, the semiconductor device may further include, but is not limited to, a capacitive contact pad disposed over the first interlayer insulating film. The capacitive contact pad is disposed in a memory cell region of the semiconductor substrate. The first interconnect may further include, but is not limited to, a local interconnect disposed over the first interlayer insulating film. The local interconnect is disposed in a peripheral circuit region of the semiconductor substrate. The capacitive contact pad may further include, but is not limited to, a first patterned portion of a conductive film. The interconnect may further include, but is not limited to, a second patterned portion of the conductive film.

In some cases, the semiconductor device may further include, but is not limited to, a capacitor being disposed in the memory cell region. The capacitor is coupled to the capacitive contact pad.

In some cases, the semiconductor device may further include, but is not limited to, a second interlayer insulating film covering the capacitive contact pad and the first interconnect. The second interlayer insulating film buries the capacitor.

In some cases, the semiconductor device may further include, but is not limited to, a third interlayer insulating film disposed over the second interlayer insulating film, and multi-level interconnects buried in the third interlayer insulating film.

In some cases, the semiconductor device may further include, but is not limited to, a first bump disposed over the third interlayer insulating film in the peripheral circuit region; and a contact plug structure penetrating the second and third interlayer insulating films in the peripheral circuit region. The contact plug is coupled through the multi-level interconnects to the first bump. The contact plug is coupled through the first interconnect to the via plug.

In some cases, the via plug may further include, but is not limited to, a copper bump; a seed film covering side surfaces and a top surface of the copper bump, the top surface facing to the local interconnect; and a metal film covering a bottom surface of the copper bump. The bottom surface is projected outside the semiconductor substrate.

In another embodiment, a semiconductor device may include, but is not limited to, a semiconductor substrate having a memory cell region and a peripheral circuit region; a first interlayer insulating film over the semiconductor substrate; a first local interconnect disposed over the first interlayer insulating film, the first local interconnect being in the peripheral circuit region, the first local interconnect including a first patterned portion of a conductive film; a capacitive contact pad disposed over the first interlayer insulating film and in the memory cell region; a capacitive contact pad disposed over the first interlayer insulating film, the capacitive contact pad being in the memory cell region, the capacitive contact pad including a second patterned portion of the conductive film; and a via plug penetrating the semiconductor substrate and the first interlayer insulating film. The via plug is coupled to the first local interconnect.

In some cases, the semiconductor device may further include, but is not limited to, a capacitor being disposed in the memory cell region, the capacitor being coupled to the capacitive contact pad.

In some cases, the via plug includes a projecting portion that projects from the semiconductor substrate.

In still another embodiment, a semiconductor device may include, but is not limited to, a semiconductor substrate having a memory cell region and a peripheral circuit region; a first interlayer insulating film over the semiconductor substrate; memory cells in the memory cell region; buried word lines in a plurality of grooves of the semiconductor substrate in the memory cell region; a first local interconnect disposed over the first interlayer insulating film, the first local interconnect being in the peripheral circuit region, the first local interconnect including a first patterned portion of a conductive film; a capacitive contact pad disposed over the first interlayer insulating film, the capacitive contact pad being in the memory cell region, the capacitive contact pad including a second patterned portion of the conductive film; and a via plug penetrating the semiconductor substrate and the first interlayer insulating film, the via plug being coupled to the first interconnect, the via plug including a projecting portion that projects from the semiconductor substrate.

In some cases, the semiconductor device may further include, but is not limited to, a capacitor being disposed in the memory cell region, the capacitor being coupled to the capacitive contact pad; a second interlayer insulating film over the first interlayer insulating film, the second interlayer insulating film burying the first local interconnect and the capacitive contact pad; a third interlayer insulating film over the second interlayer insulating film; a fourth interlayer insulating film over the third interlayer insulating film; a first bump over the fourth interlayer insulating film and in the peripheral circuit region; multi-level interconnects buried in the fourth interlayer insulating film in the peripheral circuit region; and a contact plug structure penetrating the second, third and fourth interlayer insulating films in the peripheral circuit region, the contact plug being coupled through the multi-level interconnects to the first bump, and the contact plug being coupled through the first local interconnect to the via plug.

In some cases, the semiconductor device may further include, but is not limited to, a first isolating film in the semiconductor substrate, the first isolating film surrounding the via plug in the semiconductor substrate. The first isolating film isolates the via plug from outside portions of the semiconductor substrate outside the first isolating film.

In some cases, the semiconductor device may further include, but is not limited to, a bottom insulating film on a first surface of the semiconductor substrate. The first interlayer insulating film is disposed over a second surface of the semiconductor substrate. The second surface is opposite to the first surface. The via plug penetrates the bottom insulating film, the semiconductor substrate and the first inter-layer insulating film. The projecting portion projects from the first insulating film.

In some cases, the first local interconnect and the capacitive contact pad have substantially the same thickness and substantially the same material.

In yet another embodiment, a method of forming a semiconductor device may include, but is not limited to, forming a plurality of grooves in a memory cell region of a semiconductor substrate; forming first gate insulating films on inner walls of the plurality of grooves; forming a cell gate electrode film covering the first gate insulating films and a main surface of the semiconductor substrate; selectively removing the cell gate electrode film to form cell gate electrodes in the plurality of grooves, the cell gate electrodes having top surfaces which are lower than the main surface of the semiconductor substrate; forming first insulating films over the cell gate electrodes and in the plurality of grooves; forming second gate insulating films on the main surface of the semiconductor substrate; forming peripheral gate electrodes on the second gate insulating films in a peripheral circuit region of the semiconductor substrate; forming a first interlayer insulating film covering the main surface of the semiconductor substrate; forming a first metal film over the first interlayer insulating film; patterning the first metal film to form simultaneously a capacitive contact pad in the memory cell region and a local interconnect in the peripheral circuit region; forming an opening which penetrates the semiconductor substrate and the first interlayer insulator to expose a bottom surface of the local interconnect; and forming a via plug in the opening, the via plug being connected to the local interconnect.

In some cases, the method of forming a semiconductor device may further include, but is not limited to, forming a capacitor formation layer over the first interlayer insulating film, after forming simultaneously the capacitive contact pad and the local interconnect; forming a capacitor buried in the capacitor formation layer in the memory cell region, the capacitor being connected to the capacitive contact pad; forming an interconnect formation layer over the capacitor formation layer; forming interconnects buried in the interconnect formation layer; forming a contact plug which penetrates the interconnect formation layer and the capacitor formation layer in the peripheral circuit region, the contact plug being connected to the local interconnect; and forming a bump projecting from the interconnect formation layer, the bump being connected to the contact plug, before forming the via plug.

In some cases, the method of forming a semiconductor device may further include, but is not limited to, forming a first groove in the semiconductor substrate in the peripheral circuit region; and forming a first isolating film in the first groove before forming the plurality of grooves.

In some cases, the method of forming a semiconductor device may further include, but is not limited to, subjecting a bottom surface of the semiconductor substrate to back-grind to expose a bottom of the first isolating film after forming the bump and before forming the opening.

In some cases, the method of forming a semiconductor device may further include, but is not limited to, forming a bottom insulating film of silicon nitride on the bottom surface of the semiconductor substrate after exposing the bottom of the first isolating film and before forming the opening.

In some cases, the method of forming a semiconductor device may further include, but is not limited to, forming a conductor which fills the opening and covers the bottom insulating film; and patterning the conductor to form the via plug having a projecting portion which projects from the bottom insulating film, the projecting portion including a peripheral portion which faces toward the bottom surface of the semiconductor substrate through the bottom insulating film.

In some cases, forming the via plug may further include, but is not limited to, forming a seed film containing titanium and copper, which covers inner walls of the opening; forming a copper bump in the opening; and forming a metal layer on a bottom surface of the copper bump.

In some cases, forming the peripheral gate electrode may further include, but is not limited to, forming a second gate insulating film on the main surface of the semiconductor substrate; forming a peripheral gate electrode film including a polysilicon film on the second gate insulating film in the peripheral circuit region; introducing a first impurity of a first type conductivity into a first region of the polysilicon film and a second impurity of a second type conductivity into a second region of the polysilicon film; and patterning the peripheral gate electrode film to form first and second gate electrodes from the first and second regions, respectively.

In some cases, the method of forming a semiconductor device may further include, but is not limited to, forming a cell transistor having a gate electrode which is a part of the word line; forming a bit line at the same time of patterning the peripheral gate electrode film, the bit line being connected to one of source and drain regions of the cell transistor.

In an additional embodiment, a data processor includes a semiconductor device as recited above.

A semiconductor device 100 according to the present invention is described below, with references made to drawings. As a convenience in assisting an understanding of the features, the drawings used in the following descriptions sometimes show such features enlarged, and the dimensional ratios and the like of constituent elements are not necessarily the same as in actuality. Also, the raw materials and dimensions and the like given as examples in the following descriptions are only examples, and the present invention is not restricted thereto, it being possible to embody arbitrarily variations within a scope that does not change the essence thereof.

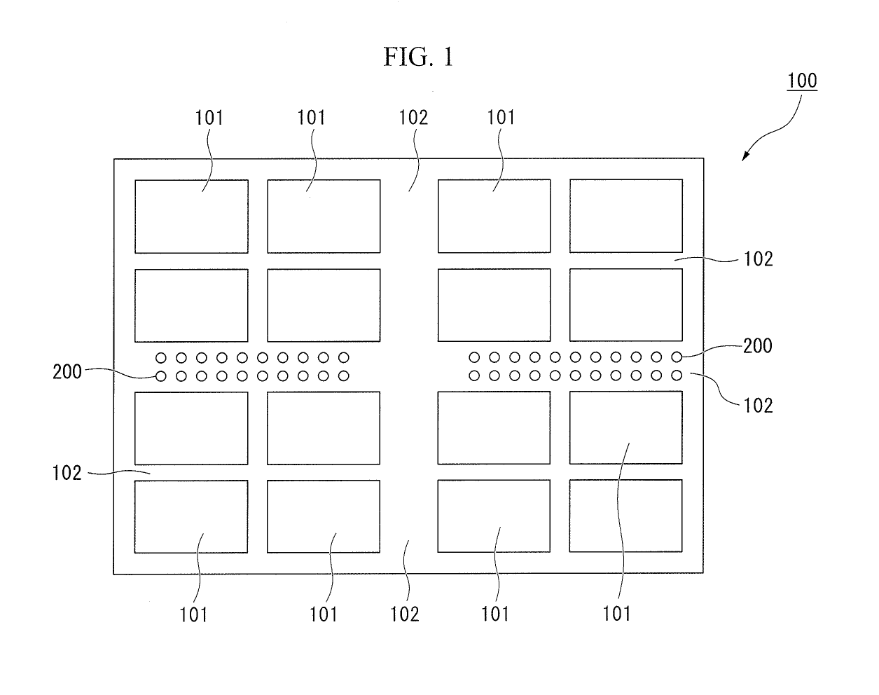

First, using FIG. 1, the general constitution of a semiconductor chip that is an example of a semiconductor device (DRAM) 100 of a first embodiment will be described. Because FIG. 1 is a plan view for the purpose of describing the positional relationship between memory cell regions 101 and a peripheral circuit region 102 of the semiconductor device 100, the illustrations of specific constituent elements of the semiconductor device 100 have been omitted.

As shown in FIG. 1, the semiconductor device 100 is generally constituted by the memory cell regions 101 and the peripheral circuit region 102 that is formed so as to surround the memory cell regions 101.

The memory cell regions 101 are regions in which a plurality of memory cells that include MOS transistors and capacitors to be described below are arranged in accordance with a prescribed rule.

The peripheral circuit region 102 is a region in which, for example, circuit blocks such as an input/output circuit with respect to the outside of the semiconductor chip are disposed and, specifically, this includes the provision of circuit blocks other than the memory cell array, such as a non-illustrated sense amplifier circuit, word line drive circuit, decoder circuit, and input/output circuits with respect to the outside of the semiconductor chip. The peripheral circuit region 102 is formed so as to surround each memory region 101.

A plurality of through electrodes (TSVs; through silicon vias) 200 are formed in a part of the peripheral circuit region 102. The through electrodes 200 are electrodes for the mutual electrical connection between a plurality of stacked semiconductor devices (semiconductor chips) 100, pass through the semiconductor devices 100, and have a plurality of bumps (protruding electrodes) for connection on one end and the other end thereof. By this constitution, the bumps of the plurality of adjacently stacked semiconductor devices 100 are connected, so that there is mutual electrical connection between the semiconductor devices 100.

By this constitution, the semiconductor devices 100 function as a DRAM (dynamic random access memory).

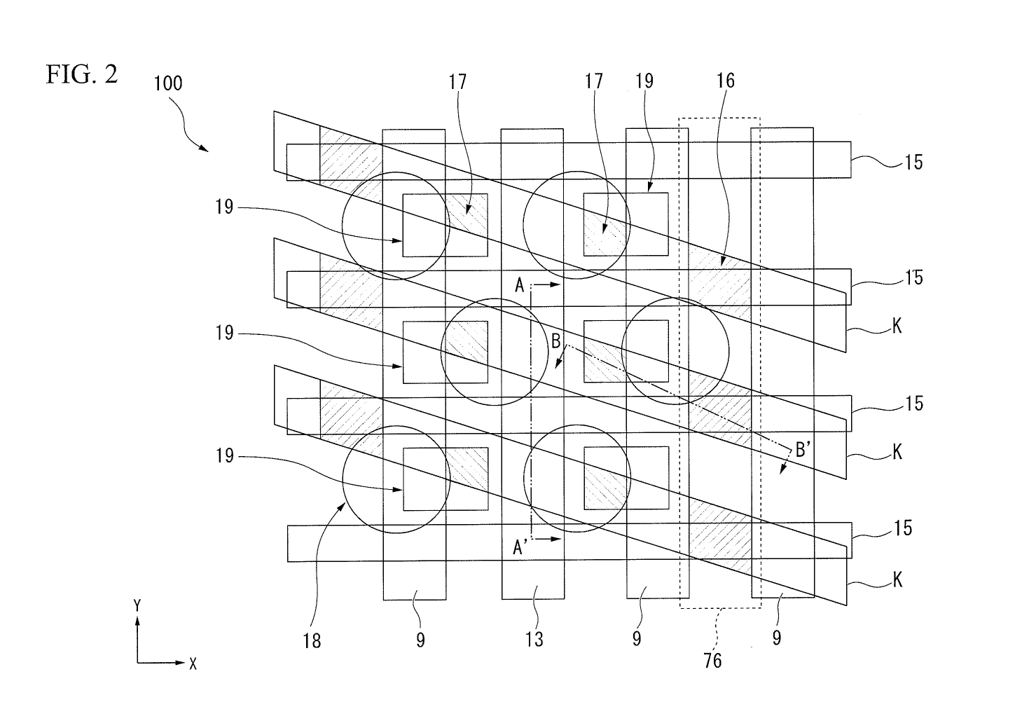

Next, the constitution of the above-noted memory cell region 101 will be described, using FIG. 2. FIG. 2 is a plan view showing a memory cell region 101 of the semiconductor device 100. As shown in FIG. 2, the semiconductor device 100 of the present embodiment has an arrangement of 6F² cells (where F is the minimum process dimension).

A memory cell region in the semiconductor device 100 is formed by a plurality of active regions K in the shape of bands, partitioned by element separation regions 4, at a prescribed interval. The active regions K are formed on the surface of a semiconductor substrate 50, which will be described later, and extend at a prescribed angle with respect to the direction of extension of each of the word lines 9 and each of the bit interconnects 15. The plan view condition and arrangement direction of the active regions K are not limited to those shown in FIG. 2.

A first word line 9, which functions as a gate electrode, and a second word line 13 for element separation are formed by burying at a prescribed interval in a prescribed direction (the Y direction in FIG. 2) so as to pass vertically through the active regions K. Also, the plurality of first word lines 9 are formed to extend in the Y direction and so as to be mutually distanced in the X direction. In the structure of the present embodiment, as shown in FIG. 2, two first word lines 9 and one second word line 13 are arranged in this sequence alternately in the X direction. The memory cells are formed in the respective regions in which the first word line 9 and the active region K intersect.

A plurality of bit interconnects 15 are disposed at a prescribed interval in the direction that is perpendicular to the direction of the first word lines 9 and the second word lines 13 (the X direction in FIG. 2).

A bit interconnect connection region 16 is partitioned and formed at a part of the active region K positioned below each of the bit interconnects 15.

A capacitor contact plug formation region 17 is partitioned and formed between mutually adjacent bit interconnects 15 in the Y direction, and also in the part of the region between the adjacent first word lines 9 and second word lines 13 in the X direction overlapped with the region K. The capacitor contact plug formation region 17, seen in a plan view, straddles across one part of the first word line 9, one part of the element separation region 4, and one part of the active region K.

A capacitor contact pad 18, which will be described in detail, is formed at a position that is staggered in the Y direction with respect to the capacitor contact plug formation region 17. The capacitor contact plug 18 is disposed between bit interconnects 15, and is disposed repeatedly in a staggered manner, either at the center part on every other first word line 9 in the Y direction, or at the center part on the upper side of every other first word line 9 in the Y direction.

A plurality of memory cells are formed in the overall memory cell region, and each of the memory cells is provided with a capacitor element (not shown). Capacitor contact plugs 19 thereof, as shown in FIG. 2, are disposed at a prescribed interval within the memory cell region so as not to mutually overlap.

The capacitor contact plug 19 is, for example, rectangular when seen in plan view and, seen in plan view, is formed so as to straddle one part of the capacitor contact plug formation region 17, one part of the first word line 9, one part of an STI region, and one part of the active region K. One part of the capacitor contact plug 19 is positioned over each of the first word lines 9. The other part of the capacitor contact plug 19 is in a region between adjacent bit interconnects 15, and disposed above a location between the first word line 9 and the second word line 13 and is connected to a capacitor 47.

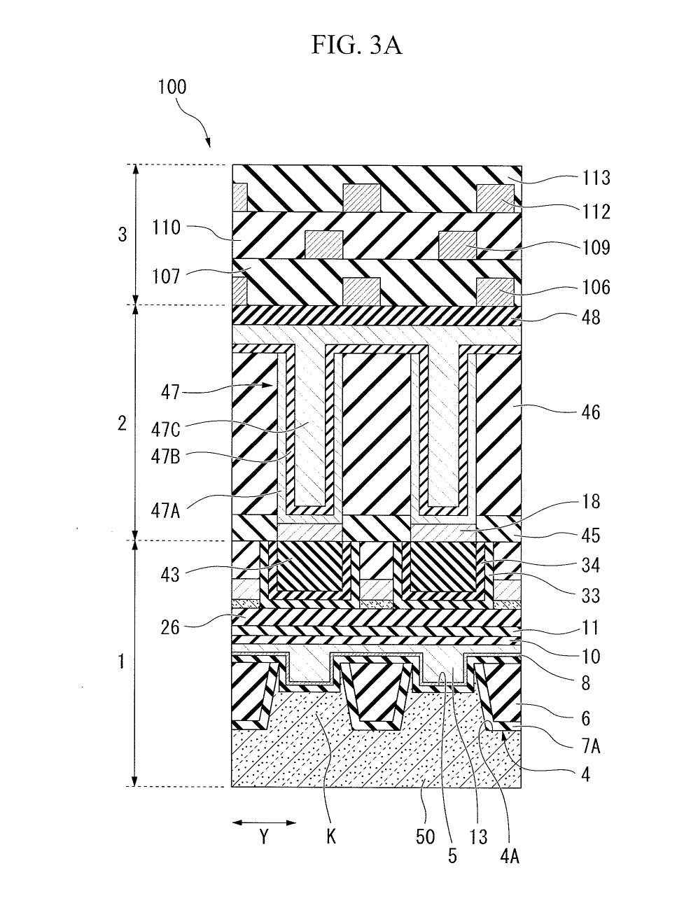

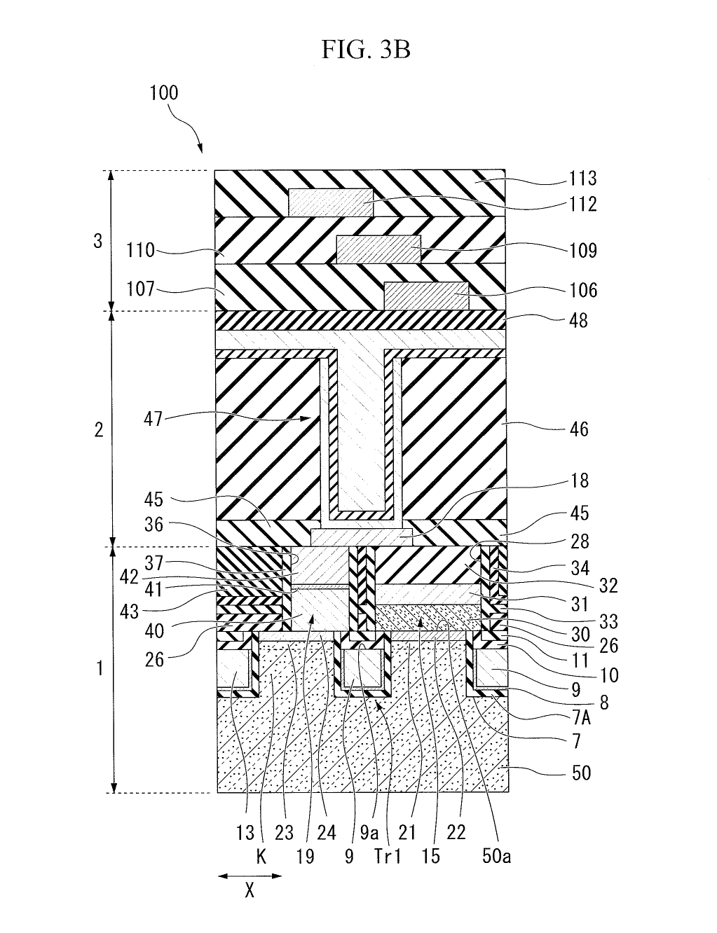

Using FIG. 3, the memory cells that constitute the semiconductor device 100 of the present embodiment will be described. FIG. 3 shows a partial cross-sectional structure of the semiconductor device 100, with FIG. 3A showing the cross-sectional structure along the line A-A′ of FIG. 2, and FIG. 3B showing the cross-sectional structure along the line B-B′ of FIG. 2. The memory cell in the present embodiment is generally constituted by a transistor formation layer 1 and a capacitor formation layer 2.

The transistor formation layer 1 is the region in which a buried-gate MOS transistor (cell transistor) Tr1 is formed, in which the semiconductor substrate 50, the cell transistor Tr1, the bit interconnect 15, and the capacitor contact plug 19 are formed.

The semiconductor substrate 50 is, for example, a p-type silicon substrate, on the surface (one surface) of which is formed the active region K and the element separation region 4. The element separation region 4 is constituted by an STI element separation film 7A made of a silicon nitride film formed so as to cover the inner surface of an element separation trench 4A, and an element separation insulating film 6 made of a silicon oxide (SiO₂) film formed so as to bury the inside of the element separation trench 4A.

The active region K is partitioned and formed by the element separation trench 4 and extends in the form of a line. For this reason, in contrast to an active region formed as an isolated island pattern in a conventional semiconductor device, the lithography resolution is high, and it is possible to form an impurity diffusion region (source/drain region) at the edge part of the active region with the desired shape.

The first word line 9 is made of a high melting point metal such as tungsten (W), extends in the Y direction of FIG. 2, and a plurality thereof are disposed at a prescribed interval in the X direction shown in FIG. 3B. The first word line 9 is formed by burying the bottom part of the trench 7 with an intervening inner layer 8 made of a first gate insulating film 7A and titanium nitride (TiN) or the like. The region in which the trench 7 and the active region K overlap functions as the channel region of the cell transistor Tr1.

The upper surface 9a of the first word line 9 is positioned below the upper surface 50a of the semiconductor substrate 50. A liner film 10 and a buried insulating film 11 are laminated in this sequence, so as to cover over the first word line 9 and bury the trench 7. The liner film 10 has the function of lining the buried insulating film 11, and supports the bottom and side surfaces of the buried insulating film 11.

In the present embodiment, the upper end edges of the first gate insulating film 7A and the liner film 10 are formed so as to reach the aperture of the trench 7. The upper surface of the buried insulating film 11, the upper edge of the of the gate insulating film 7A, and the upper edge of the liner film 10 are laminated so as to be substantially flush.

A solid film made of a deposited film such as a silicon oxide film formed by CVD or an SOD (spin-on dielectric: deposited insulating film such as polysilazane) film can be used as the buried insulating film 11. By annealing such a deposited film at a high temperature in an atmosphere containing water, it can be used as a solid film. It is preferable that the liner film 10 be formed to a film thickness of approximately 10 nm. This is because, by forming the liner film 10 to a film thickness of approximately 10 nm, it is possible to reliably stop corrosion due to etching. A silicon nitride film such as an Si₃N₄ film or the like can be used as the material of the liner film 109.

As shown in FIG. 3A, a channel trench 5 that is shallower than the element separation trench 4A is formed in the region between element separation trenches 4A adjacent in the Y direction. The second word line 13 having the same structure as the first word line 9 is formed, with an intervening first gate insulating film 7A and inner surface layer 8, on the inner surface of the channel trench 5 and on the upper surface of an element separation trench 4A that is adjacent to the channel trench 5.

As shown in FIG. 3B, the first word line 9 and the second word line 13 are disposed so as to be adjacent, with a prescribed interval therebetween in the X direction. The second word line 13 is formed, with an intervening first gate insulating film 7A and inner surface layer 8, by burying in the bottom part of the trench 7.

The liner film 10 and the buried insulating film 11 are laminated in this sequence over the second word line 13. These films shown in FIG. 3A and the films shown in FIG. 3B are formed simultaneously in the manufacturing method to be described later.

The second word line 13 is formed simultaneously with the first word line 9. The second word line 13 has the function of electrically separating a source region and a drain region (the impurity diffusion layers formed on both sides of the second word lines 13 shown in FIG. 3) of each of the adjacent cell transistors Tr1 in the active region K formed as a line. For example, by fixing the second word line 13 to a prescribed electrical potential (for example −0.1 V), it is possible to electrically separate adjacent memory cells.

As shown in FIG. 2, a plurality of first word lines 9 are formed so as to extend in the Y direction while being mutually distanced from one another in the X direction, and in the structure of the present embodiment, as shown in FIG. 3B, two first word lines 9 and one second word line 13 are alternately disposed in the X direction in this sequence.

By way of further describing a transistor formation layer 1 based on FIGS. 3A and 3B, as shown in FIG. 3B, a first low-concentration impurity diffusion layer 21 and a second high-concentration impurity diffusion layer 22 are formed sequentially from the deep side in a region that is on the upper surface 50a side of the semiconductor substrate 50 positioned between the first word lines 9 adjacent in the X direction, and that corresponds to the above-noted active region K. A second low-concentration impurity diffusion layer 23 and a second high-concentration impurity diffusion layer 24 are formed sequentially from the deep side in a region that is on the upper surface 50a side of the semiconductor substrate 50 positioned between the first word line 9 and the second word line 13 adjacent in the X direction, and corresponding to the above-noted active region K.

In the region shown in FIG. 3A, a first interlayer insulating film 26 is formed so as to cover over the buried insulating film 11. In the region shown in FIG. 3B, the first interlayer insulating film 26 is formed so as to cover over the upper surface 50a of the semiconductor substrate 50, that is, over the high-concentration impurity diffusion layers 22 and 24 and over the trench 7 into which the first word line 9, the liner layer 10, and the buried insulating film 11 are buried.

In a region between trenches 7 that are adjacent in the X direction in FIG. 3B, a first contact aperture 28 is formed with respect to the first interlayer insulating film 26. A bit interconnect 15 is formed over the first interlayer insulating film 26 so as to extend in a direction that is perpendicular to the first word line 9 shown in FIG. 2. The bit interconnects 15 are formed to extend outward up to the bottom part side of the first contact aperture 28 in the part of the first contact aperture 28. The bit interconnect 15 is formed so that part thereof overlaps with the buried insulating film 11, and also so as to connect with the first high-concentration impurity diffusion layer 22 below each of the first contact apertures 28. In the region in which the first contact aperture 28 is formed, therefore, a region in which the first bit interconnect 15 exists and in which the first high-concentration impurity diffusion layer 22 exists therebelow as the bit interconnect connection region 16 shown in FIG. 2.

The bit interconnect 15 has a three-layer structure having a bottom part conducting film 30 made of polysilicon, a metal film 31 made of a high melting point metal such as tungsten, and an upper insulating film 32 made of a silicon nitride film or the like, and an insulating film 33 made of a silicon nitride film or the like and a liner film 34 are each formed at both sides of the first bit interconnect 15 in the width direction shown in FIG. 3B and above the first interlayer insulating film 26 shown in FIG. 3A so as to be positioned at both sides of the bit interconnect 15 in the width direction. More specifically, the bottom part conducting film 30, as discussed in the description of the manufacturing method later, is made of impurity-doped polysilicon that is doped with an impurity such as phosphorus (P).

A second contact aperture 36, which is rectangular when seen in plan view, is formed in a region that is between bit interconnects 15 adjacent in the Y direction in FIG. 2 and that is also between a region above the first word line 9 and the second word line 13 that makes contact therewith. The capacitor contact plug 19, which is surrounded by a side wall 37 of a silicon nitride film or the like, is formed on the inside of the second contact aperture 36.

Within the second contact aperture 36, therefore, a part at which there is overlap with the active region K corresponds to the capacitor contact plug connection region 17 shown in FIG. 2.

As shown in FIG. 3B, the capacitor contact plug 19 has a three-layer structure having a bottom part conducting film 40 made of polysilicon or the like, a silicide layer 41 made of CoSi or the like, and a metal film 42 made of tungsten or the like.

The upper surfaces of the bit interconnect 15 and the capacitor contact plug 19 are formed at substantially the same height on the semiconductor substrate 50. In the region of the semiconductor substrate 50 on which the bit interconnect 15 and the capacitor contact plug 19 are not formed, a buried insulating film 43 is formed to a height that is substantially the same as the upper surfaces of the bit interconnect 15 and the capacitor contact plug 19.

In the capacitor formation layer 2 shown in FIG. 3A and FIG. 3B, as shown in FIG. 2, a capacitor contact pad 18 that is substantially round when seen in plan view is formed over each of the capacitor contact plugs 19 so as to be staggered when seen in plan view, so that there is partial overlap. The capacitor formation layer 2 is formed as an insulating film that buries the capacitor. The capacitor contact pad 18 is covered by a stopper film 45. A third interlayer insulating film 46 is formed over the stopper film 45. Each of the capacitors 47 is formed inside the third interlayer insulating film 46, so that they are each positioned above the capacitor contact pads 18.

As shown in FIG. 3A and FIG. 3B, the capacitor 47 in the present embodiment is constituted by a cup-shaped lower electrode 47A that is formed so as to make contact with the capacitor contact pad 18, a capacitor insulating film 47B that is formed to extend outwardly over the third interlayer insulating film 46 from the inner surface of the lower electrode 47A, and an upper electrode 47C that is formed so as to fill the inside of the lower electrode 47A on the inside of the capacitor insulating film 47B and to extend outwardly up to the upper surface side of the capacitor insulating film 47B.

The upper surface of the upper electrode 47C is covered by a fourth interlayer insulating film 48.

The structure of the capacitor 47 of the present embodiment is one example and, in addition to the structure of the present embodiment, other capacitor structures such as a crown type or a pedestal type (pillar type) may be disposed, such as are generally applied to DRAM memory cells.

An interconnect layer 3 is provided over the capacitor formation layer 2 as an insulating film in which a metal interconnect is buried. In the present embodiment, a first interconnect 106, a second interconnect 109, and a third interconnect 112 are provided as the three metal interconnect layers.

The first interconnect 106 is formed over the fourth interlayer insulating film 48. A fifth interlayer insulating film 107 is formed so as to cover over the first interconnect 106 and the fourth interlayer insulating film 48. The second interconnect 109 is formed over the fifth interlayer insulating film 107. A sixth interlayer insulating film 110 is formed so as to cover over the second interconnect 109 and the fifth interlayer insulating film 107. The third interconnect 112 is formed over the sixth interlayer insulating film 110. A protective film 113 is formed so as to cover the third interconnect 112 and the sixth interlayer insulating film 110.

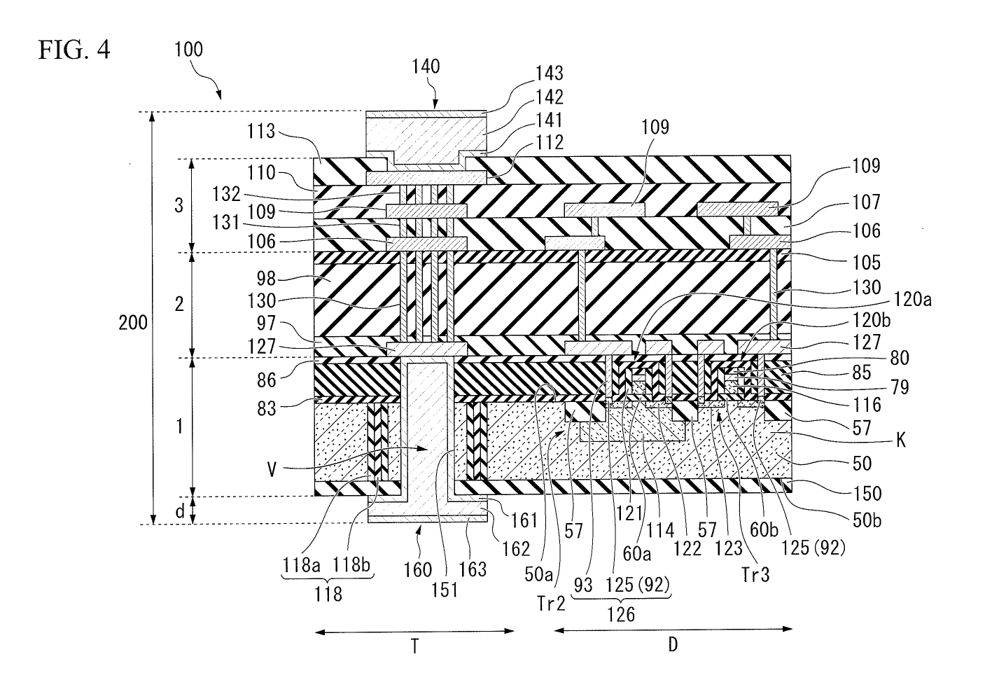

Next, the peripheral circuit region of the semiconductor device 100 according to the present embodiment will be described, using FIG. 4. As shown in FIG. 4, the peripheral circuit region of the semiconductor device 100 of the present embodiment is generally constituted by the transistor formation layer 1, the capacitor formation layer 2, and the interconnect layer 3. A through electrode formation region T and an element formation region D are provided in the peripheral circuit region. The element formation region D is a region in which a circuit to perform prescribed operations is formed, and MOS transistors or the like are disposed therein. The through electrode formation region T is a region in which the through electrode 200 is formed. The through electrode 200 is constituted by a via plug V, a local interconnect 127, a local contact plug 130, a first interconnect 106, a first contract plug 131, a second interconnect 109, a second contact plug 132, a third interconnect 112, and a surface bump 140, and is formed so as to pass through the transistor formation layer 1, the capacitor formation layer 2, and the interconnect formation layer 3.

Each of these constituent elements is described below, although the descriptions of elements that are the same as in the memory cell region are omitted.

A first MOS transistor Tr2 and a second MOS transistor Tr3 having a type of conductivity that differs from the first MOS transistor Tr2 are formed on the semiconductor substrate 50 of the transistor formation layer. Each of the elements are described below.

The semiconductor substrate 50 is made, for example, of a p-type silicon substrate. The lower surface 50b side of the semiconductor substrate 50 is covered by a rear surface insulating film 150 made of a silicon nitride film having a film thickness of 200 to 400 nm. The rear surface insulating film 150 has the function of preventing diffusion from the via plug V into the semiconductor substrate 50.

A silicon oxide film, which is an element separation region, is buried and formed on the upper surface 50a side of the semiconductor substrate 50, thereby partitioning the active region K.

The first MOS transistor Tr2 is a planar type p-channel transistor, and has a first gate electrode 120a.

The first gate electrode 120a is formed on the active region K, with a second gate insulating film 60a intervening therebetween. The first gate electrode 120a is constituted as a laminate of a second gate polysilicon film 116 (film that is the integration of the bottom part conducting film, which will be described later, and a first gate polysilicon film 115 in the peripheral circuit region), a metal film 79, and a silicon nitride film 80. The region in proximity to the upper surface of the active region K that makes contact, via the first gate electrode 120a and the second gate insulating film 60a, functions as the channel region of the first MOS transistor Tr2.

A nitride film side wall 121 made of a silicon nitride film is formed on the side surface of the first gate electrode 120a.

A first impurity diffusion layer 114, into which an n-type impurity (phosphorus or the like) is diffused, is formed in a region of the active region K in which the first MOS transistor Tr2 is disposed. The first impurity diffusion layer 114 functions as a n-type well.

A p-type second impurity diffusion layer 122 is formed on the inside of the first impurity diffusion layer 114, in the area surrounding the first gate electrode 120a. The second impurity diffusion layer 122 functions as the source/drain region of the first MOS transistor Tr2.

The second MOS transistor Tr3 is a planar type n-channel transistor, and has a first gate electrode 120b of a conductivity type differing from that of the first gate electrode 120a.

The first gate electrode 120b is formed on the active region K, with an intervening third gate insulating film 60b. The region in proximity to the upper surface of the active region K that makes contact via the first gate electrode 120b and the third gate insulating film 60b functions as the channel region of the first gate electrode 120b. The nitride film side wall 121 made of a silicon nitride film is formed on the side surface of the first gate electrode 120b.

An n-type third impurity diffusion layer 123 is formed inside the active region K in the area surrounding the first gate electrode 120b. The third impurity diffusion layer 123 functions as the source/drain region of the second MOS transistor Tr3.

A liner film 83 made of a silicon nitride film or the like having a film thickness of 10 to 20 nm is formed so as to cover the upper surface 50a side of the semiconductor substrate 50, the first gate electrode 120a, and the first gate electrode 120b. A deposited film 85 and a second interlayer insulating film 86 are laminated so as to cover one surface side of the liner film 83.

A plurality of peripheral contact plugs 126 made of a silicide layer 125 and a metal film 93 are formed so as to pass through the deposited film 85 and the second interlayer insulating film 86. The peripheral contact plugs 126 are each connected to the second impurity diffusion layer 122 and the third impurity diffusion layer 123.

A via plug V constituted by a seed layer 161, a copper bump 162, and a metal film 163 is formed so as to fill the inside of the aperture 151. The aperture 151 is formed so as to pass through the rear surface insulating film 150 of the through electrode formation region 150, the semiconductor substrate 50, the liner film 83, the deposited film 85, and the second interlayer insulating film 86. Of this via plug V, the part that protrudes from the other surface side of the rear surface insulating film 150 is taken as the second bump 160.

The seed film 161 is a film laminate that is the lamination of copper onto a titanium (Ti) film, formed so as to cover the inner wall surface of the aperture 150 and the lower surface side of the rear surface insulating film 150.

A copper bump 162 is formed so as to fill the inside of the aperture 151, via the seed film 161. A metal film 163 is made of a film laminate of an Au/Ni film with a film thickness of approximately 2 to 4 μm, and is formed so as to cover the lower surface side of the second pump 160.

The member 118 is constituted by a silicon nitride film 118a and a silicon oxide film 118b made of SiO₂, and is formed so as to pass through the semiconductor substrate 50. The member 118 is ring-shaped when seen in plan view, and is formed so as to surround the side surface of the via plug V. By this constitution, the insulation between adjacent through electrodes 200 is achieved by the member 118.

The insulation between the through electrode 200 and the element formation region D adjacent to the through electrode 200 is also achieved by the member 118.

The capacitor formation layer 2 is generally constituted by a local interconnect 127, a stopper film 97, a third interlayer insulating film 98, a fourth interlayer insulating film 105, and a local contact plug 130.

The local interconnect 127 is formed simultaneously with the capacitor contact pad 18 of the memory cell region and is formed from the same conducting layer, on the second interlayer insulating film 86.

The local interconnect 127 is directly connected to the via plug V and the peripheral contact plug 126. The local interconnect 127 is, in the element separation region D as well, connected to each of the MOS transistors (first MOS transistor Tr2 and second MOS transistor Tr3).

The stopper film 97 made of a silicon nitride film or the like and the third interlayer insulating film 98 made of a silicon oxide film or the like and having a film thickness of approximately 1 to 2 μm are laminated in this sequence so as to cover the upper surface of the local interconnect 127. The fourth interlayer insulating film 105 (48) that is made of a silicon oxide film or the like is formed so as to cover the third interlayer insulating film 98.

The plurality of local interconnect plugs 127 that are made of a metal film such as tungsten are formed so as to pass through the fourth interlayer insulating film 105, the third interlayer insulating film 98, and the stopper film 97.

A local interconnect 127 is connected to each of the local interconnects of the element formation region D and the through electrode formation region T.

The interconnect formation layer 3 is provided on the capacitor formation layer 2. In the present embodiment, the first interconnect 106, the second interconnect 109, and the third interconnect 112 are provided as a three-layer metal interconnect.

The first interconnect 106 is formed on the fourth interlayer insulating film 105. The fifth interlayer insulating film 107 is formed so as to cover over the first interconnect 106 and the fourth interlayer insulating film 105.

A first contact plug 131 that is made of a metal film such as tungsten is formed so as to pass through the fifth interlayer insulating film 107 and also be connected to the first interconnect 106.

The second interconnect 109 is formed over the fifth interlayer insulating film 107. The sixth interlayer insulating film 110 is formed so as to cover over the second interconnect 109 and the fifth interlayer insulating film 107. A second contact plug 132 that is made of a metal film such as tungsten is formed so as to pass through the sixth interlayer insulating film 110 of the through electrode formation region T and also be connected to the second interconnect 109.

The third interconnect 112 is formed over the sixth interlayer insulating film 110. The protective film 113 is formed so as to cover the third interconnect 112 and the sixth interlayer insulating film 110.

The first bump 140 is formed so as to pass through the protective film 113 of the through electrode formation region T and also so as to connect to one surface side (the upper surface side) of the third interconnect 112. The first bump 140 is constituted by a seed film 141, a copper bump 142, and a surface metal film 143. The seed film 141 is a film laminate made, for example, by laminating copper on a titanium (Ti) film, and is formed so as to cover the other surface side (lower surface side) of the first bump 140. The copper bump 142 has a height (film thickness) of approximately 10 to 12 μm, and is formed so as to extend outward from the one surface side of the protective film 113. The surface metal film 143 is made, for example, of an alloy film of tin and silver (Sn—Ag film) with a film thickness of 2 to 4 μm, and is formed so as to cover one surface side of the copper bump 142.

By the above-noted constitution, when a plurality of semiconductor chips are stacked, the first bumps 140 bond with the second bumps 160 provided on an adjacent semiconductor chip.

If the constitution is one in which the through electrode 200 makes a connection between the first bump 140 and the second bump 160, the constitution may be one that has an internal interconnect (not shown) that makes an electrical connection to the MOS transistor formed in the element formation region D. In this case, it is possible to use any of the local interconnect 127, the first interconnect 106, the second interconnect 109, and the third interconnect 112 as the internal interconnect. If necessary, any of the local contact plug 130, the first contact plug 131, and the second contact plug 132 can be removed, and an electrode formed that does not make an electrical connection between the first bump 140 and the second bump 160.

According to the semiconductor device 100 of the present embodiment, because the local interconnect 127 of the peripheral circuit region is formed of the same material as the capacitor contact pad 96 of the memory cell region, it is possible to suppress the electrical resistance of the through electrode 200. Also, because the via plug V is directly connected to the local interconnect 127, it is possible to suppress the electrical resistance of the through electrode 200. Also, because the via plug V is constituted by a seed film 161 and a copper bump 162 having a high conductivity, it is possible to achieve a high conductivity.

By the above, even in a mircrostructured semiconductor device 100 having a buried gate MOS transistor, it is possible to achieve good electrical characteristics. For this reason, it is possible to achieve a semiconductor device 100 that has a high level of integration, and can accommodate high-capacity data storage.

By the member 118 being formed so as to surround the side surface of the via plug V, it is possible to achieve insulation between adjacent through electrodes 200. It is also possible to achieve insulation between the through electrode 200 and an element separation region D adjacent to the through electrode 200. For this reason, even in a microstructured semiconductor device 100, it is possible to prevent a worsening of the electrical characteristics.

By the formation of a rear surface insulating film 150 made of a silicon nitride film having a film thickness of 200 to 400 nm between the other surface side of the semiconductor substrate 50 and the second bump 160, it is possible to prevent diffusion of copper into the semiconductor substrate 50 from the second bump 160 and the via plug V. For this reason, it is possible to prevent a worsening of the element characteristics in the semiconductor device 100.

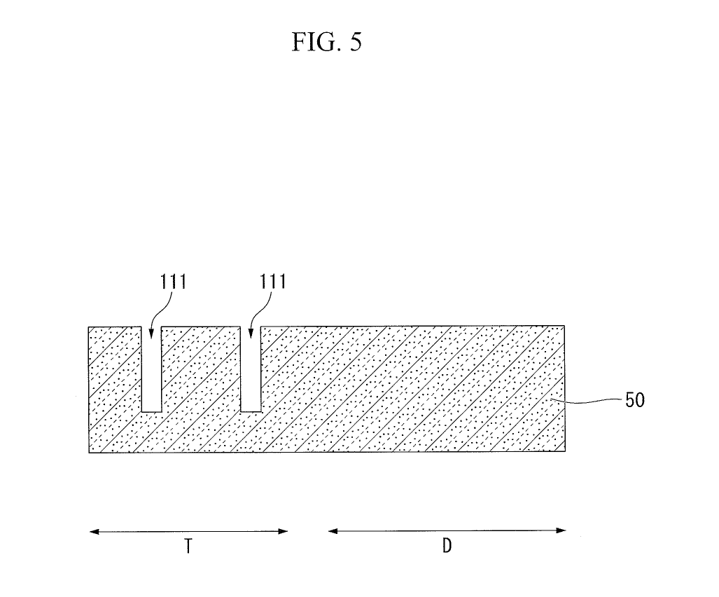

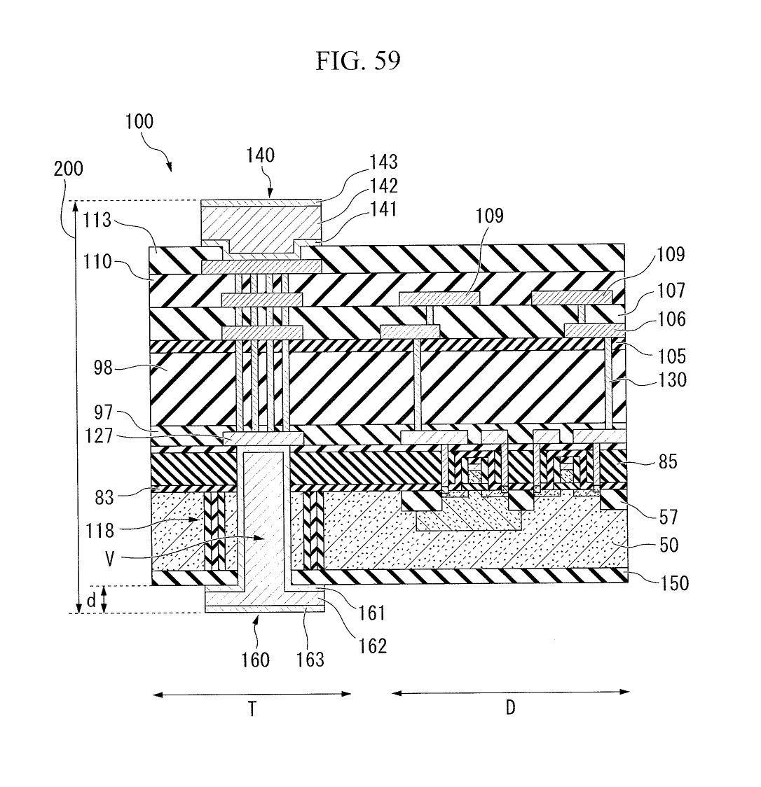

Next, a method of manufacturing the semiconductor device according to the present invention will be described, with references made to the drawings. First, an example of the method for manufacturing the semiconductor device 100 shown in FIG. 1 to FIG. 4 will be described based on FIG. 5 to FIG. 59. The memory cell regions and the peripheral circuit region, unless otherwise noted, are formed simultaneously. The cross-sectional views of the memory cell regions and the peripheral circuit region are presented in different scales. In the cross-sectional views of the memory cell region, the drawings with the suffix A are cross-sectional views along the line A-A′ in FIG. 2 and the drawings with the suffix B are cross-sectional views along the line B-B′ in FIG. 2.

First, as shown in FIG. 5, a first trench 111 is formed in the peripheral circuit region.

A semiconductor substrate 50 made of p-type silicon (Si) is first prepared. The semiconductor substrate 50 that is used may be one in which p-type wells in which the MOS transistors are to be formed have been formed beforehand by ion implantation.

Next, photolithography and dry etching are used to pattern the semiconductor substrate 50 in the through electrode formation region T, and the first trench 111 is formed. The first trench 111 is formed so as to be, for example, cylindrically shaped, so that it surrounds the side surface of the via plug V that is formed later, when the semiconductor substrate 50 is seen in plan view.

The depth of the first trench 111 can be set in accordance with the prescribed thickness of the semiconductor chip that is ultimately formed. In the present embodiment, for example, a first trench 111 having a depth of 50 μm is formed.

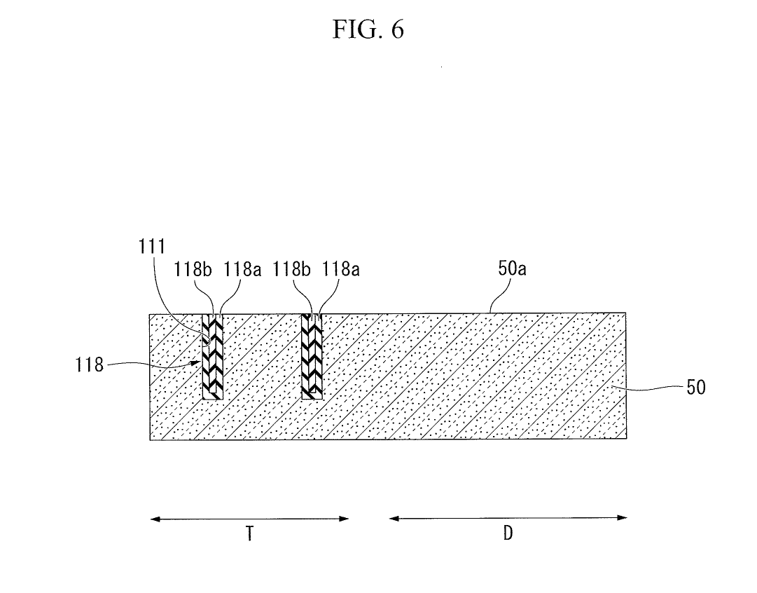

Next, as shown in FIG. 6, the member 118 is formed in the peripheral circuit region.

First, the silicon nitride film 118a is formed so as to over the inner wall of the first trench 111. When this is done, the formation conditions for the silicon nitride film 118a are adjusted so that the silicon nitride film 118a does not completely fill the first trench 111.

Next, a silicon oxide film 118b made of SiO₂ is deposited so as to fill the inside of the first trench 111. Next, the silicon nitride film 118a and silicon oxide film 118b over the semiconductor substrate 50 are removed by etching. By this etching, the silicon nitride film 118a and the silicon oxide film 118b remain only within the first trench 111, thereby forming the member 118.

When this is done, locations in the peripheral circuit region other than those in which the member 118 is formed and the upper surface (silicon surface) 50a of the semiconductor substrate 50 are exposed.

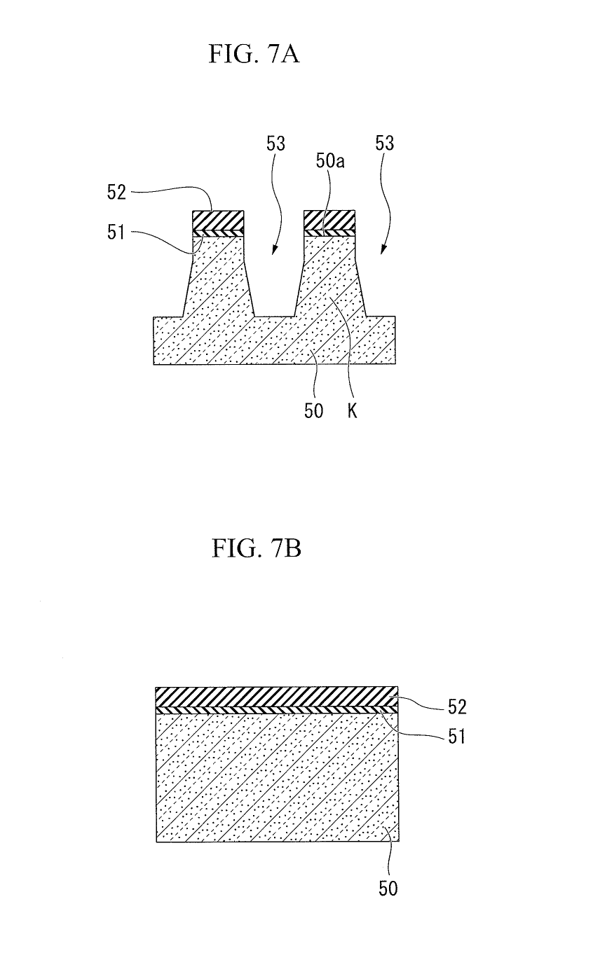

Next, as shown in FIGS. 7A and 7B, an element separation region 53 for the partitioning of the active region K is formed in the memory cell region. First, a silicon oxide film 51 and a silicon nitride film (Si₃N₄ film) 52 to act as a mask are sequentially formed so as to cover the upper surface 50a of the semiconductor substrate 50 in the memory cell region and the peripheral circuit region.

Next, as shown in FIG. 7A, photolithography and dry etching are used to pattern the silicon nitride film 52. Next, using this silicon nitride film 52 as a mask, the silicon oxide film 51 and the semiconductor substrate 50 are etched. Next, the element separation trench 53 is formed. The element separation trench 53 is formed as a pattern trench in the form of, for example, a line that extends in a prescribed direction so as to sandwich both sides of the band-shaped active regions K shown in FIG. 2, when the semiconductor substrate 50 is seen in plan view. When this is done, the upper surface 50a that is to be the active region K is covered by the silicon nitride film 52.

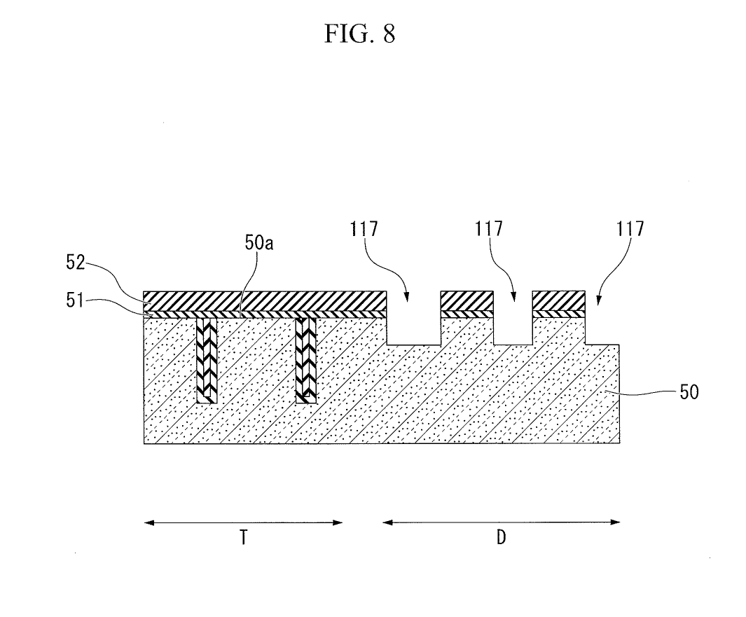

Simultaneously with the formation of the element separation trench 53, as shown in FIG. 8, the silicon nitride film 52 is used as a mask for etching of the silicon oxide film 51 and the semiconductor substrate 50 in the peripheral circuit region. By this etching, the element separation trench 117 is formed in the semiconductor substrate 50 in the peripheral circuit region.

The element separation trench 117 is formed so as to partition the regions for formation of the MOS transistors (first MOS transistor Tr2 and second MOS transistor Tr3) to be described later. The regions that will be the regions for formation of the transistors are at this point covered by the silicon nitride film 52 used as a mask.

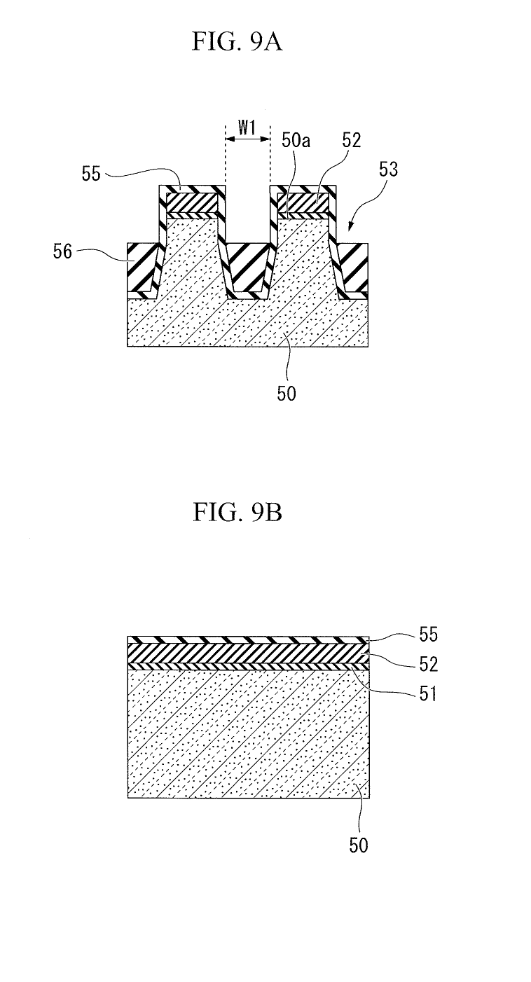

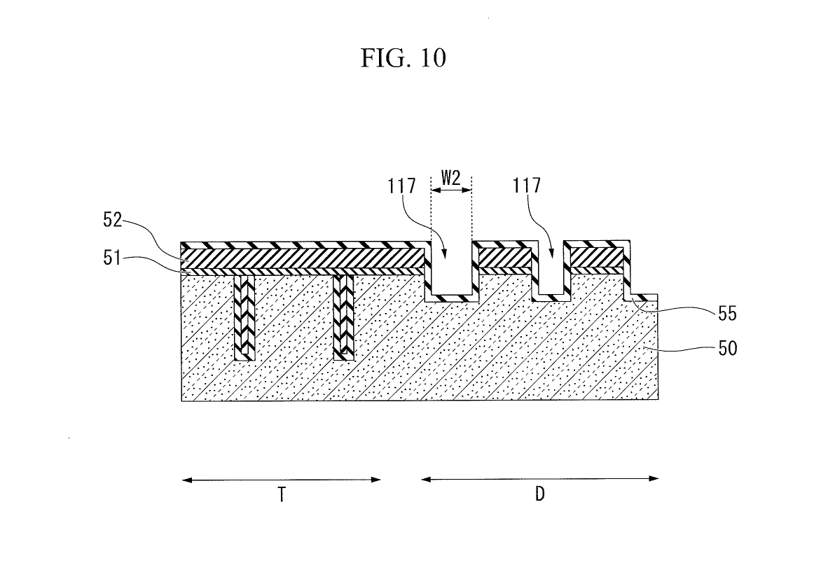

As shown in FIG. 9A, FIG. 9B, and FIG. 10, the silicon oxide film 55 is formed by thermal oxidation, so as to cover the surface of the semiconductor substrate 50 and the inner wall surface of the element separation trench 117. When this is done, the formation conditions for the silicon oxide film 55 are adjusted so that the inside of the element separation trench 117 is not completely filled by the silicon oxide film 55.

As shown in FIG. 9A and FIG. 9B, the silicon nitride film 56a is deposited so as to completely fill the inside of the element separation trench 53 of the memory cell region. Next, wet etching is done so as to leave the silicon nitride 56a in the lower side of the inside of the element separation trench 53. By this etching, an element separation insulating film 56 made of the silicon nitride film 56a filled to a position that is slightly lower than the upper surface 50a of the semiconductor substrate 50 is formed. The width of the element separation trench 53 will be taken as W1.

When this is done, as shown in FIG. 10, the element separation trench 117 in the peripheral circuit region is formed to have a width W2 that is sufficiently wider than the width W1 of the element separation trench 53 in the memory cell region.

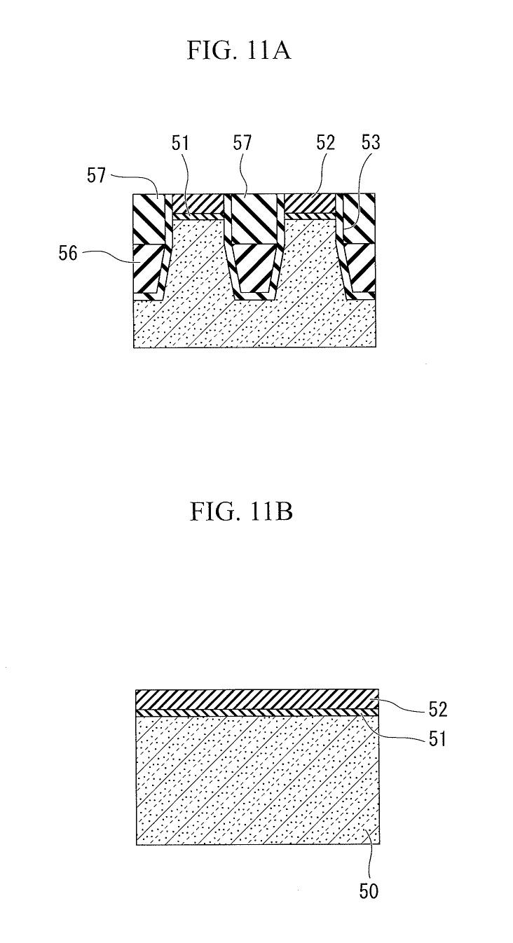

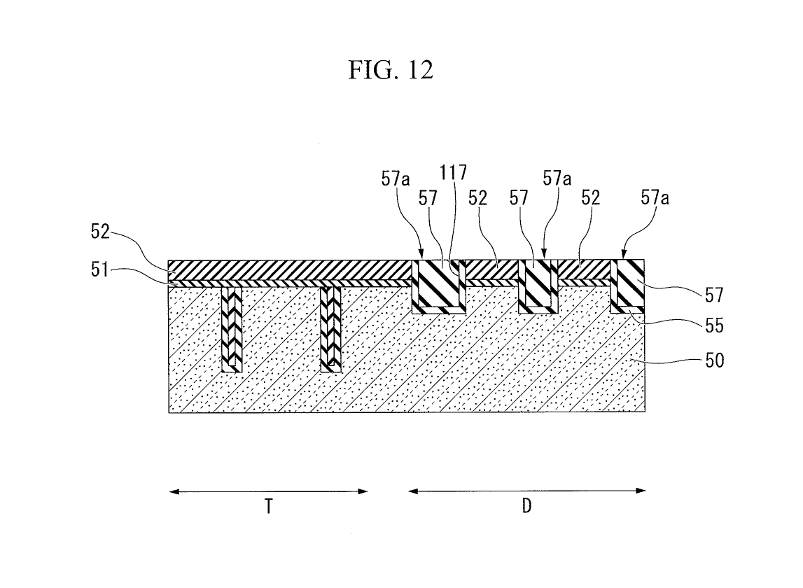

As shown in FIG. 11A, FIG. 11B, and FIG. 12, CVD is used to deposit a silicon oxide film 57 so as to fill the inside of the element separation trench 53 in the memory cell region (above the element separation insulating film 56) and the inside of the element separation trench 117 in the peripheral circuit region.

As shown in FIG. 11A and FIG. 11B, CMP (chemical mechanical polishing) is done until the silicon nitride film 52 used for a mask is exposed, and the surface of the silicon oxide film 57 is planarized.

By this CMP processing, the silicon oxide film 57 is planarized even in the peripheral circuit region, as shown in FIG. 12, and the silicon oxide film 57 remains inside the element separation trench 117. The silicon oxide film 57 remaining inside the element separation trench 117 becomes the element separator 57a.

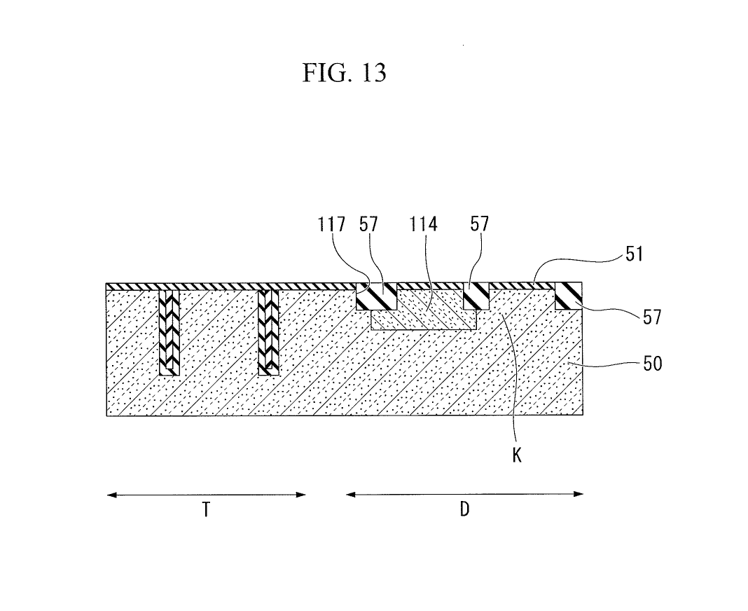

As shown in FIG. 13, a first impurity diffusion layer 114 is formed on the surface layer part of the active region K in the element formation region D.

First, a part of the silicon oxide film 57 and the silicon nitride film 52 for use as a mask are removed by wet etching. When this is done, the etching conditions are adjusted so that the upper surface of the silicon oxide film 57 (the element separator 57a) is substantially the same as the position of the upper surface of the silicon oxide film 51. For simplification in subsequent cross-sectional views of the peripheral circuit region, only the silicon oxide film 57 is shown inside the element separation trench 117.

Using a photoresist film (not shown) as a mask, an n-type impurity (for example phosphorus) is implanted into the surface of the semiconductor substrate 50, so as to form the first impurity diffusion layer 114 in a part of the element separation region D. This first impurity diffusion layer 114 is the region in which a p-channel MOS transistor is formed, by a process to be described later. When this is done, the regions of the peripheral circuit region other than the first impurity diffusion layer 114 and the memory cell region may have a p-type impurity diffusion layer formed therein by ion implantation of a p-type impurity such as boron (B).

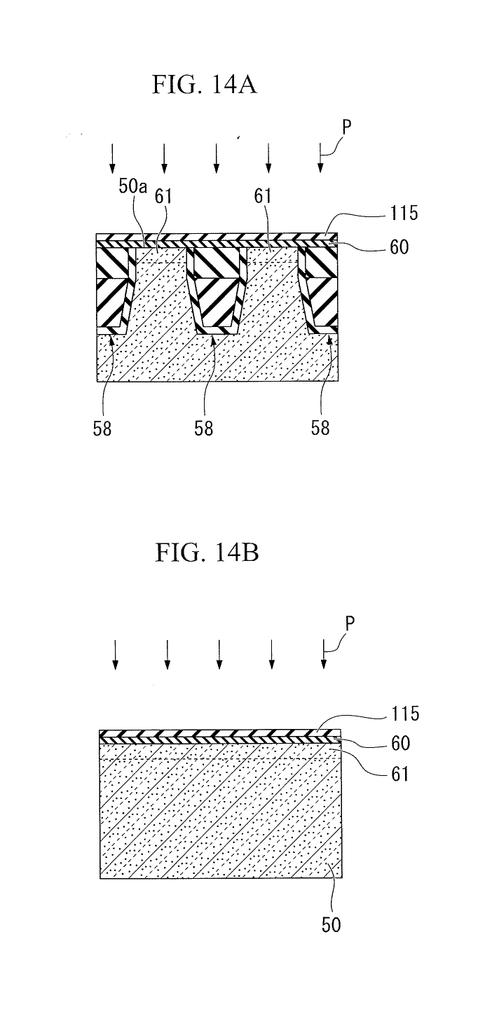

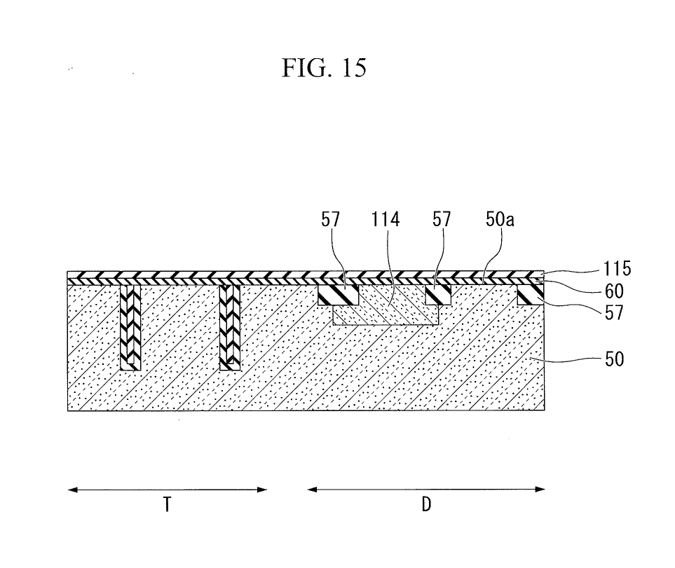

As shown in FIG. 14A, FIG. 14B, and FIG. 15, the first gate polysilicon film 115 is formed.

First, the silicon oxide film 51 is removed from the surfaces of the memory cell region and the peripheral circuit region of the semiconductor substrate 50 by wet etching, thereby exposing the upper surface 50a of the semiconductor substrate 50.

By this etching, an element separation region 58 in the form of a line having an STI (shallow trench isolation) structure is formed in the memory cell region.

A gate insulating film 60 is formed by thermal oxidation so as to cover the upper surface 50a of the semiconductor substrate 50. This gate insulating film 60 functions as the gate insulating film of the MOS transistors disposed in the peripheral circuit region (the first MOS transistor Tr2 and the second MOS transistor Tr3).

Next, CVD is used to form the first gate polysilicon film 115 made of non-doped polysilicon and having a film thickness of approximately 20 to 30 nm, so as to cover the gate insulating film 60.

As shown in FIG. 14A and FIG. 14B, the peripheral circuit region is covered with a photoresist film (not shown), and phosphorus is implanted into the memory cell region as a low-concentration n-type impurity. By doing this, an n-type low-concentration impurity diffusion layer 61 is formed in the memory cell region. When this is done, the ion implantation dose is, for example, within the range from 5×10¹² to 1×10¹³ atoms/cm². This low-concentration impurity diffusion layer 61 functions as the source/drain region of the cell transistors disposed in the memory cell region.

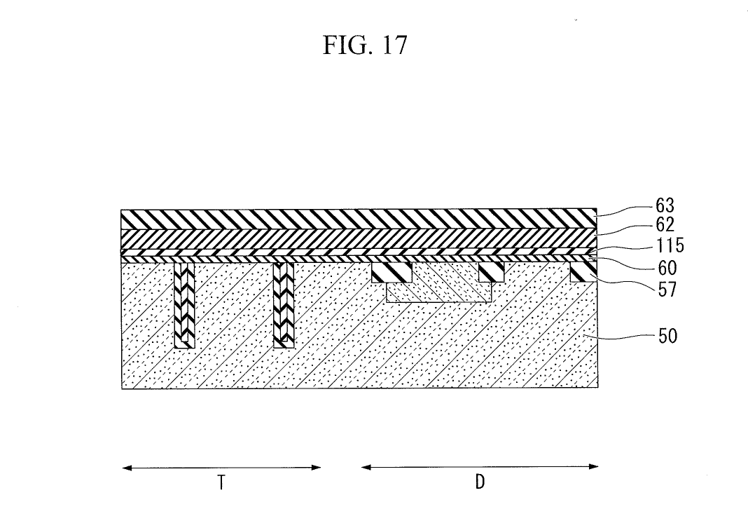

As shown in FIG. 17, CVD is used to form a first gate polysilicon film 115 made of non-doped polysilicon to a film thickness of approximately 20 to 30 nm, so as to cover the gate insulating film 60 in the peripheral circuit region.

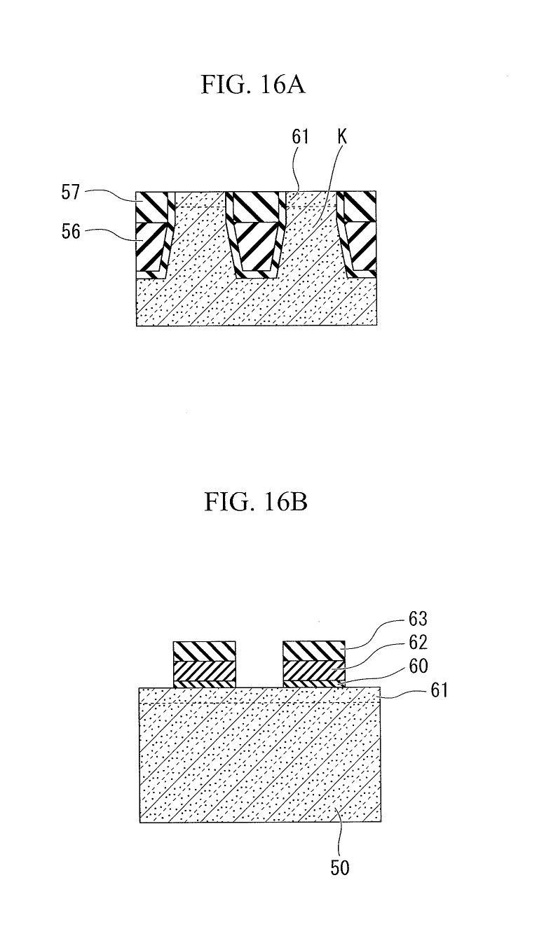

Next, the peripheral circuit region is covered by a photoresist film (not shown) and, as shown in FIG. 16A and FIG. 16B, ion implantation is done of an n-type impurity into the surface layer part of the active region K in the memory cell region. By this ion implantation, the n-type low-concentration impurity diffusion layer 61 is formed in the surface layer part of the active region K. When this is done, the ion implantation dose is, for example, 5×10¹² to 1×10¹³ atoms/cm². This low-concentration impurity diffusion layer 61 functions as the source/drain region of the buried-gate MOS transistor (cell transistor Tr1) disposed in the memory cell region.

As shown in FIG. 17, the peripheral circuit region is masked by a photoresist film (not shown), and the first gate polysilicon film 115 over the memory cell region is removed.

A silicon nitride film 62 for use as a mask and a carbon film (amorphous carbon film) 63 are deposed in sequence onto the peripheral circuit region and the memory cell region. Next, as shown in FIG. 14A and FIG. 14B, the silicon nitride film 62 and the carbon film 63 are patterned for forming a trench 65 in the memory cell region. When this is done, as shown in FIG. 15, patterning is not done of the silicon nitride film 62 and the carbon film 63 in the peripheral circuit region. For this reason, the top of the semiconductor substrate 50 in the peripheral circuit region remains covered by the gate insulating film 60, the first gate polysilicon film 115, the silicon nitride film 62, and the carbon film 63.

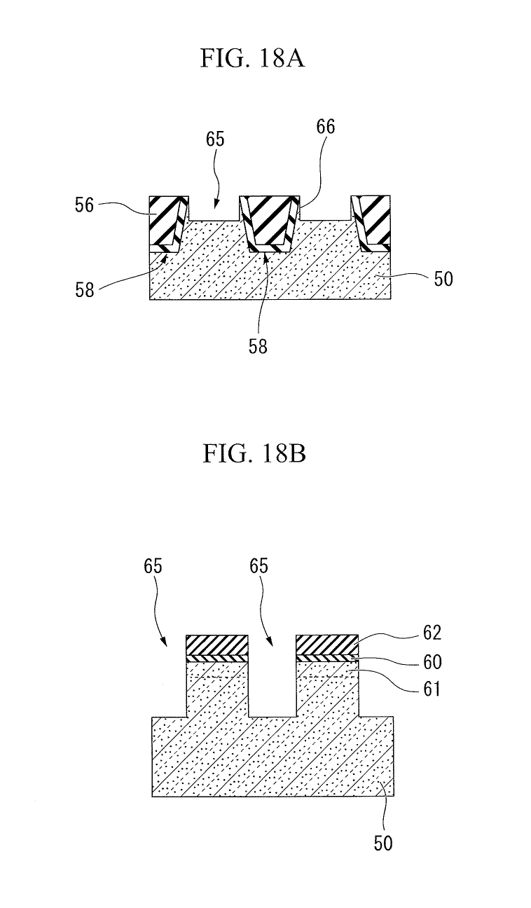

As shown in FIG. 18A and FIG. 18B, the semiconductor substrate 50 in the memory cell region is etched to form a plurality of mutually adjacent trenches 65. A trench 65 is formed as a line-shaped pattern extending in a prescribed direction (the Y direction in FIG. 2) that intersects with the active region K.

When this is done, the upper surface of the element separation region 58 positioned within the trench 65 is also etched, thereby forming a trench at a position that is lower than that of the upper surface of the semiconductor substrate 50. By controlling the etching conditions so that the etching rate of the silicon oxide film is slower than the etching rate of the semiconductor substrate 50, a relatively deep trench is etched into the semiconductor substrate 50, and a relatively shallow trench is etched into the element separation region 58, these being continuous and formed as a trench with a step in the bottom part thereof.

As shown in FIG. 18A, a thin film of polysilicon remains as the side wall 66 on the side surface part of the trench 65 that makes contact with the element separation region 58, this functioning as the channel region of a recess-type cell transistor.

If silicon part of the semiconductor substrate 50 is etched more quickly than the element separation insulating region (STI) 58, a channel region is formed as a recessed-channel type transistor.

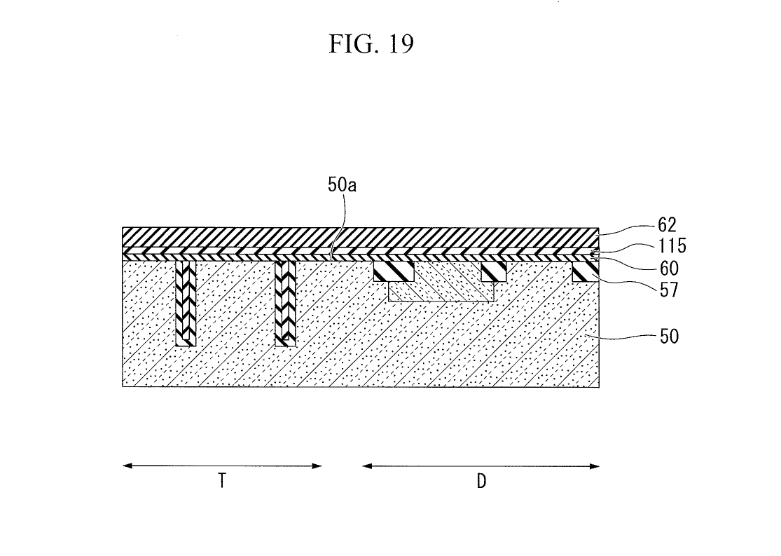

Next, the carbon film 63 is removed from the memory cell region and the peripheral circuit region. By removing the carbon film 63, as shown in FIG. 19, the upper surface 50a of the semiconductor substrate 50 in the peripheral circuit region is covered by the gate insulating film 60, the first gate polysilicon film 115, and the silicon nitride film 62.

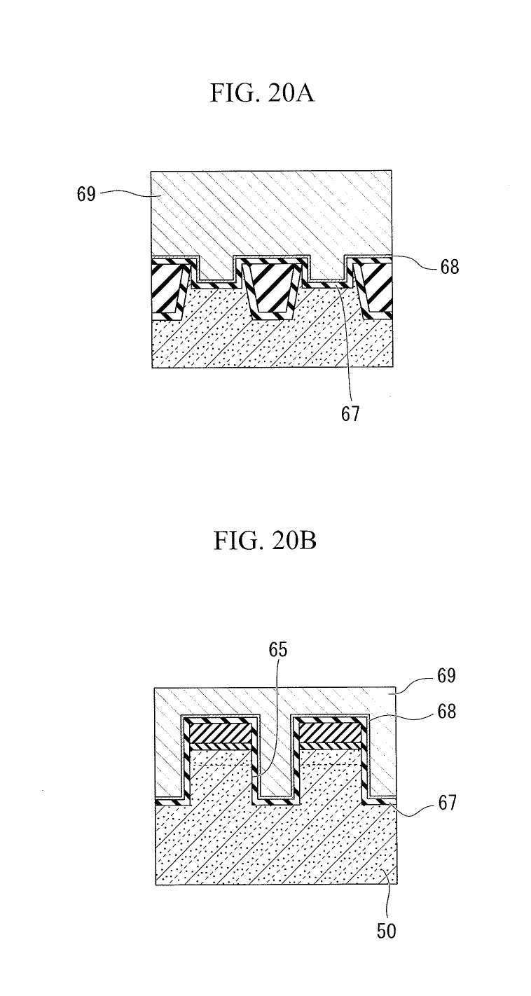

As shown in FIG. 20A and FIG. 20B, a first gate insulating film 67 made of a silicon oxide film having a film thickness of approximately 4 to 7 nm is formed by thermal oxidation so as to cover the memory cell region and the peripheral circuit region. When this is done, the first gate insulating film 67 in the memory cell region is formed so as to cover the inner surface of the trench 65. The first gate insulating film 67 functions as the gate insulating film of a buried-gate MOS transistor (cell transistor Tr1) disposed in the memory cell region.

An inner surface layer 68 made of titanium nitride (TiN) and a tungsten (W) layer 69 are deposited in sequence on the memory cell region and the peripheral circuit region, and taken as the cell gate electrode film. When this is done, the tungsten layer 69 in the memory cell region is formed to a film thickness that completely fills the inside of the trench 65.

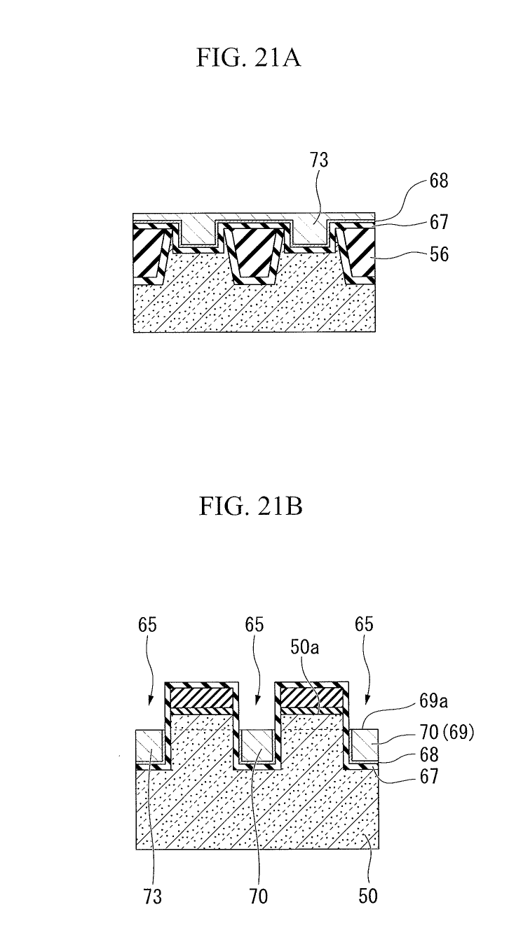

As shown in FIG. 21A and FIG. 21B, the upper surface 69a of the tungsten layer 69 is etched back to below the upper surface 50a of the semiconductor substrate 50. When this is done, the etch back conditions are adjusted so that the titanium nitride layer 68 and the tungsten layer 69 remain in the bottom part of the trench 65. By this etching, the first word line 70 and a second word line 73 made of the tungsten film in a structure that partially serves also as the gate electrode are formed on the inside of the trench 65.

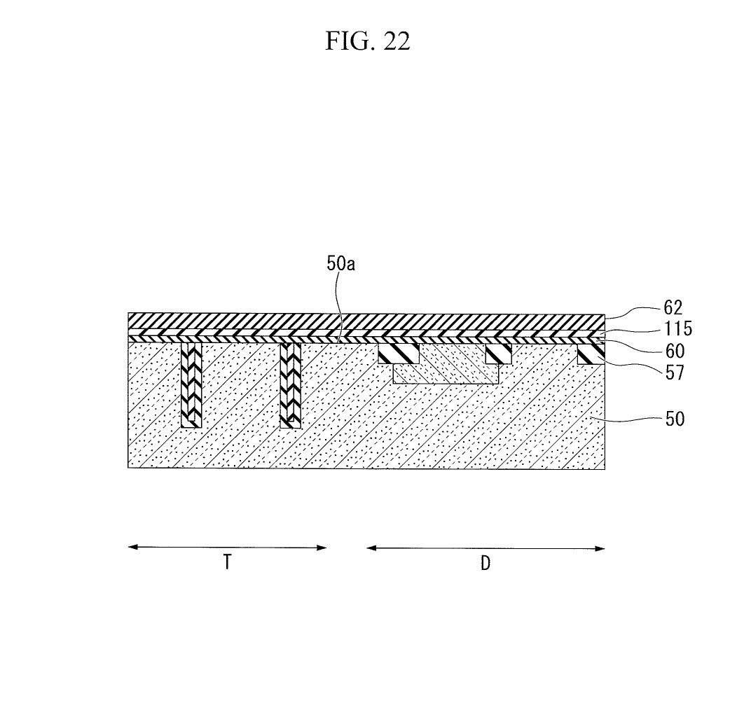

When this is done, as shown in FIG. 22, because the upper surface 50a of the semiconductor substrate 50 is flat in the peripheral circuit region, the inner surface layer 68 and the tungsten layer 69 are completely removed at the time of the etching described by FIG. 21A and FIG. 21B.

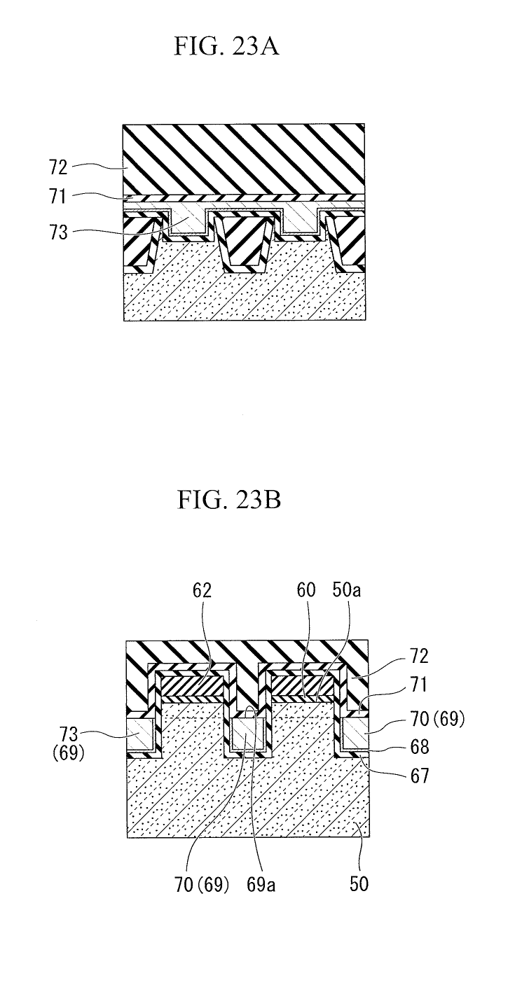

As shown in FIG. 23A and FIG. 23B, a first liner film 71 made of, for example, silicon nitride (Si₃N₄) having a film thickness of approximately 10 nm is formed so as to cover the upper surfaces of the first word line 70 and the second word line 73 (upper surface 69a of the tungsten film 69). When this is done, the formation conditions are adjusted so that the first liner film 71 does not bury the inside of the trench 65.

Using CVD or a spinner, a first buried insulating film 72 made of, for example, a silicon oxide film or an SOD (spin-on dielectric: polysilazane or the like) is formed on the memory cell region and the peripheral circuit region, so as to cover the first liner film 71 and also to bury the trench 65.

CMP processing is done to planarize the surface until the liner film 71 in the memory cell region is exposed. Next, CMP processing is done until the silicon nitride film 62 in the memory cell region is exposed, and polishing is done to remove the surface of the first buried insulating film 72, the first liner film 71, and the first gate insulating film 67. By this CMP processing, the first liner film 71 and the first buried insulating film 72 are caused to remain, in a constitution in which upper region of the trench 65 is buried.

By the above, the upper region of the trench 65 has a constitution in which it is buried by the first liner film 71 and the first buried insulating film 72. The first liner 71 serves the function of lining the first buried insulating film 72, and supports the bottom surface and the side surface of the first buried insulating film 72.

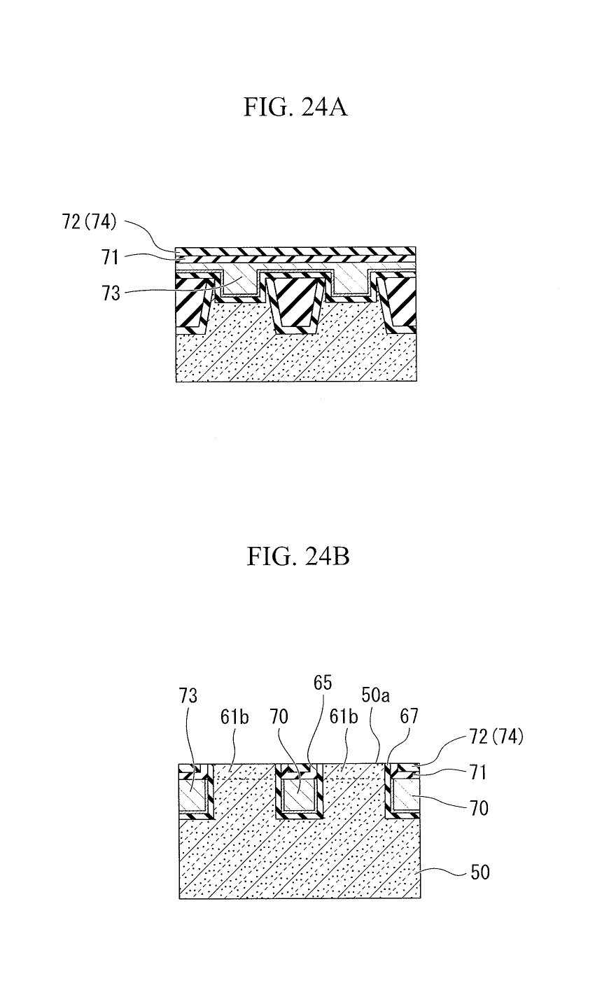

As shown in FIG. 24A and FIG. 24B, the silicon nitride film 62 and the silicon oxide film 60 in the memory cell region are removed by dry etching. By this etching, a part of the first buried insulating film 72 and the first liner film 71 are removed, and the upper surface of the first buried insulating film 72 is made substantially the same height as the upper surface 50a of the semiconductor substrate 50. When this is done, the upper surface 50a of the semiconductor substrate 50 outside the trench 65 and the upper surface of the first buried insulating film 72 in the trench 65 are exposed.

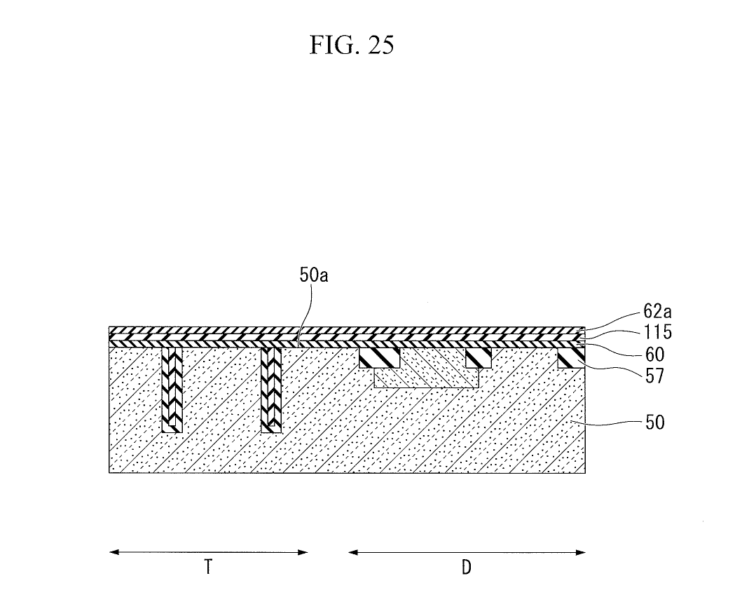

As shown in FIG. 25, the buried insulating film 72 and the liner film 71 in the peripheral circuit region are also completely removed by this etching. A part of the silicon nitride film 62 is also removed by etching back. In the peripheral circuit region, the upper surface 50a of the semiconductor substrate 50 is in the condition of being covered by the gate insulating film 60, the first polysilicon film 115, and the thin-film silicon nitride film 62a.

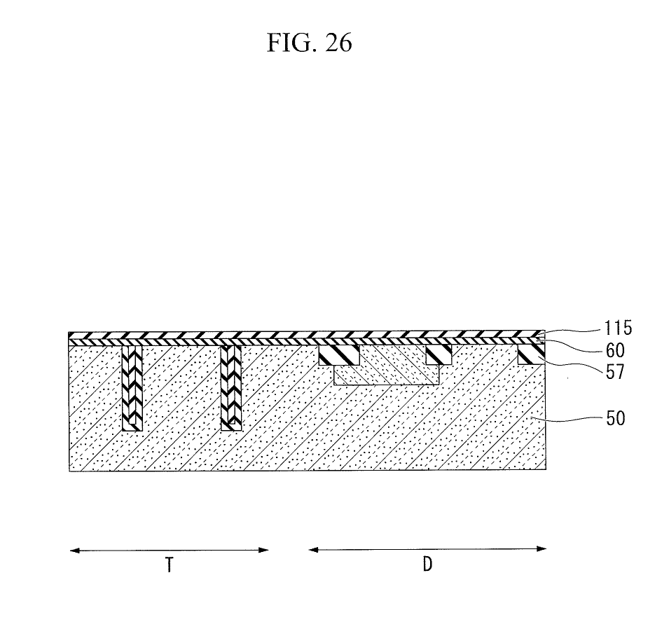

As shown in FIG. 26, the thin-film silicon nitride film 62a in the peripheral circuit region is removed by wet etching. By this etching, first gate polysilicon film 115 in the peripheral circuit region is exposed.

By the etching when the silicon nitride film 62a is removed, the liner film 71 in the memory cell region is also etched. When this is done, it is desirable to control the wet etching time so that the liner film 71 remains inside the trench 65. It is also desirable to control the wet etching conditions so that the surface of the buried insulating material 72 in the memory cell region be substantially the same height as the upper surface 50a of the semiconductor substrate 40. By the above, a buried insulating film 74 made of the buried insulating material 72 is formed.

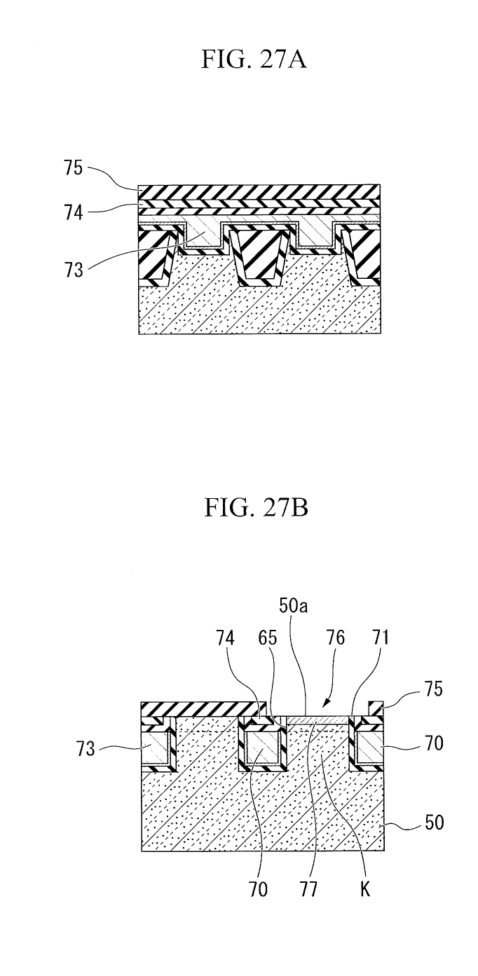

As shown in FIG. 27A and FIG. 27B, a first interlayer insulating film 75 made of, for example, a silicon oxide film with a film thickness of approximately 40 to 50 nm is formed so as to cover the memory cell region and the peripheral circuit region.

Next, part of the first interlayer insulating film 75 in the memory cell region is removed to form the first contact aperture 76.

At this point, the first contact aperture 76, similar to the case shown in FIG. 2, is formed as a line-shaped aperture pattern extending in the same direction (Y direction in FIG. 2) as the first word line 70.

By forming this aperture pattern, the upper surface 50a of the semiconductor substrate 50 is exposed in the part at which the first contact aperture 76 and the active region K intersect. This exposed region is taken as the bit interconnect connection region. Also, the upper end of the liner film 71 and part of the upper surface of the buried insulating film 74 are exposed at the bottom part of the first contact aperture 76.

Next, ion implantation is done into the surface layer part of the active region K exposed from the first contact aperture 76, so as to form an n-type first high-concentration impurity diffusion layer 77. When this is done, the ion implantation dose is, for example, 1×10¹⁴ to 5×10¹⁷ atoms/cm². This n-type first impurity diffusion layer 77 functions the source/drain region of a recess-type cell transistor, and also has the function of reducing the connection resistance of the bit interconnect formed in a subsequent process step.

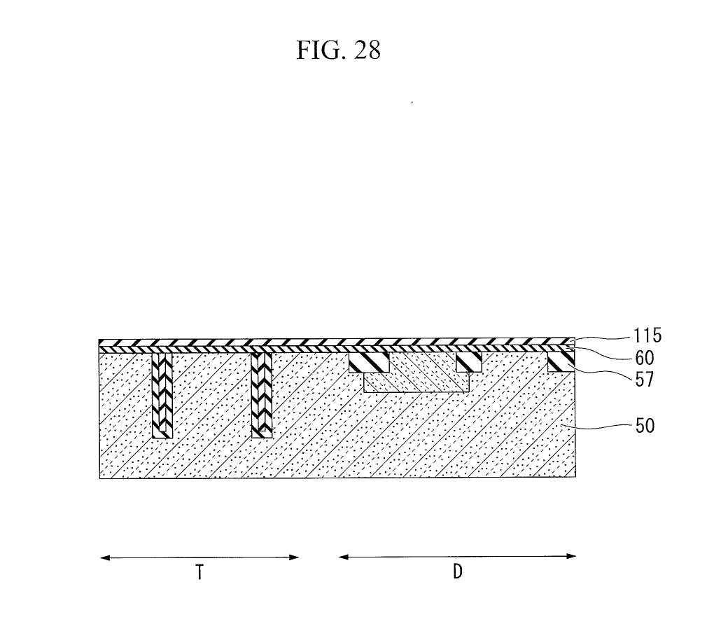

As shown in FIG. 28, using a photoresist film mask, the memory cell region is wet etched with dilute hydrofluoric acid (HF) as the etching chemical. By this etching, a clean silicon surface of the semiconductor substrate 50 (the upper surface 50a) is exposed. Also, by this etching, as shown in FIG. 28, the first interlayer insulating film 75 over the peripheral circuit region is removed, and the first gate polysilicon film 115 is exposed.

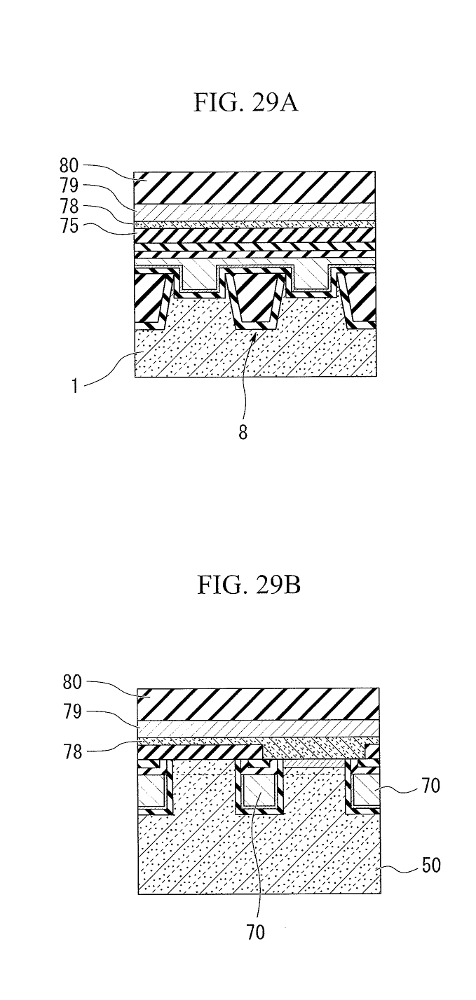

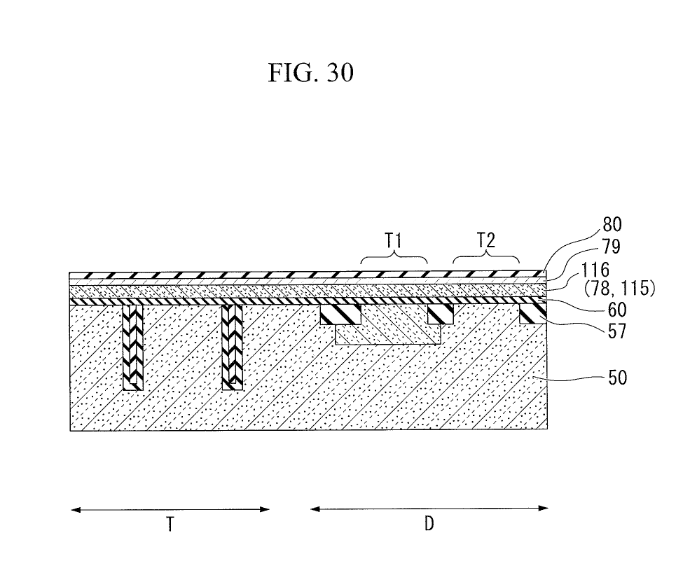

As shown in FIG. 29A, FIG. 29B, and FIG. 30, a bottom part conducting film 78 made of a polysilicon film that includes, for example, an n-type impurity (such as phosphorus) is formed in the memory cell region and the peripheral circuit region. By the formation of this bottom part conducting film 78, as shown in FIG. 30, the first gate polysilicon film 115 and the bottom part conducting film 78 are formed as one, and the second gate polysilicon film 116 is formed.

As shown in FIG. 30, using a photoresist film (not shown) as a mask, a p-type impurity such as boron is ion implanted into the second gate polysilicon film 116 on the region T1, in which the p-channel MOS transistor (first MOS transistor Tr2) of the peripheral circuit region is formed.

In the same manner, an n-type impurity such as phosphorus is implanted in the second gate polysilicon film 116 over the region T2, in which the n-channel MOS transistor (second MOS transistor Tr3) is formed.

By implantation of ions of differing conductivity types into the regions (T1 and T2), the conductivity type of the first gate electrode 120a of the first MOS transistor Tr2 formed on the peripheral circuit region is p type, and the conductivity type of the first gate electrode 120b of the second MOS transistor Tr3 is n type. For this reason, it is possible to improve the characteristics of the transistors.

When the n-type impurity is ion-implanted into the second gate polysilicon film 116, an n-type impurity may be simultaneously implanted into the bottom part conducting film 78 on the memory cell region. By ion implanting an n-type impurity into the bottom part conducting film 78, it is possible to reduce the resistance of the bit interconnect formed in the memory cell region.

Next, a metal film 79 made of a tungsten film or the like and a silicon nitride film 80 are sequentially deposited onto the bottom part conducting film 78 (second gate polysilicon film 116) in the memory cell region and the peripheral circuit region, and this is taken as the peripheral gate electrode film. This peripheral gate electrode film functions also as a bit interconnect in the memory cell region.

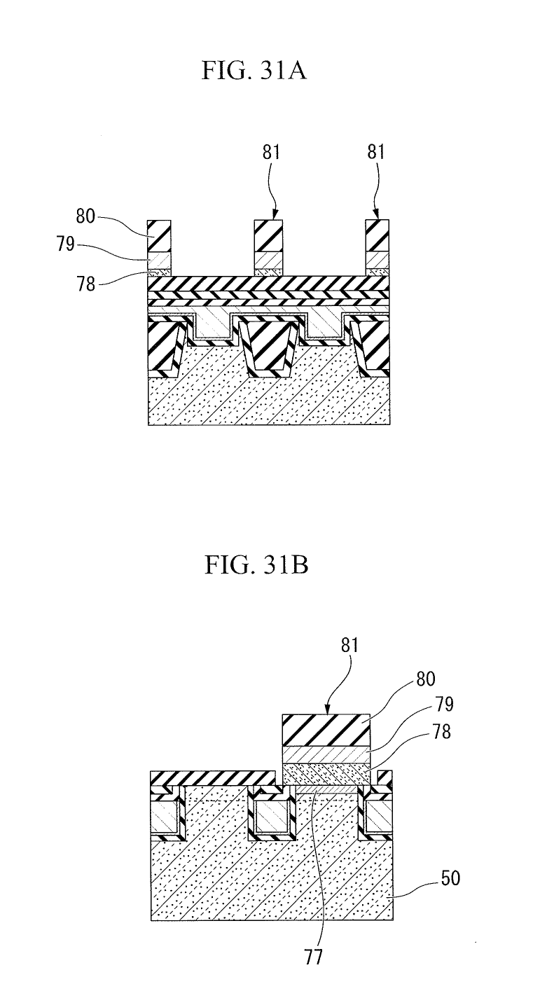

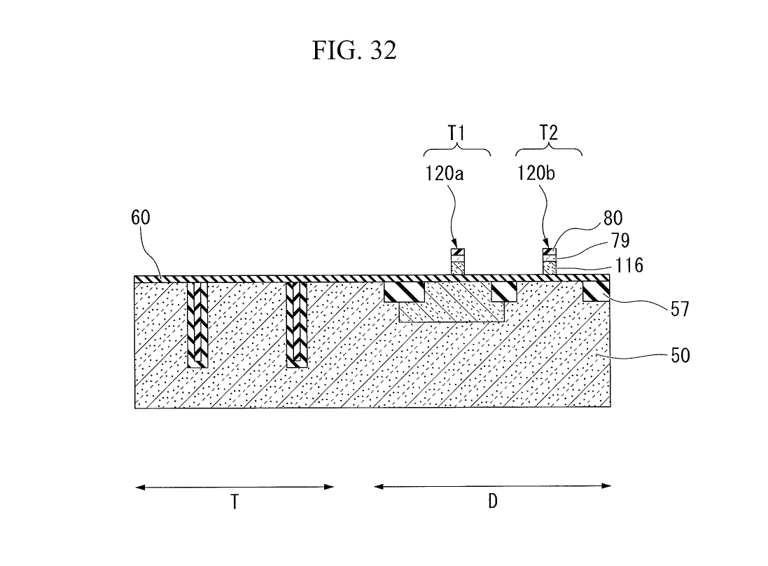

As shown in FIG. 31A, FIG. 31B, and FIG. 32, a film laminate of the bottom part conducting film 78, the metal film 79, and the silicon nitride film 80 in the memory cell region and the peripheral circuit region is patterned into a line shape. By this patterning, the bit interconnect 81 extending in a direction that intersects with the first word line 70 (the X direction in the case of the structure shown in FIG. 2) is formed in the memory cell region. Although the bit interconnect 81 shown in FIG. 31A and FIG. 31B, similar to the structure of the bit interconnect 15 shown in FIG. 2, is linear in a direction that is perpendicular to the first word line 70, the shape of the bit interconnect 81 is not restricted to being a straight line, and may be piecewise linear with bends, or may have a wavy shape. Also, the bottom part conducting film 78 on the layer below the bit interconnect 81 is connected to the first high-concentration impurity diffusion layer 77.

By this patterning, as shown in FIG. 32, the first gate electrode 120a of the first MOS transistor Tr2 is formed in the region T1 of the peripheral circuit region, and the first gate electrode 120b of the second MOS transistor Tr3 is formed in the region T2.

In the present embodiment, by simultaneously forming the bit interconnect 81 in the memory cell region 81 and the gate electrodes of the peripheral circuit region (first gate electrode 120a and second gate electrode 120b), it is possible to suppress an increase in the number of process steps.

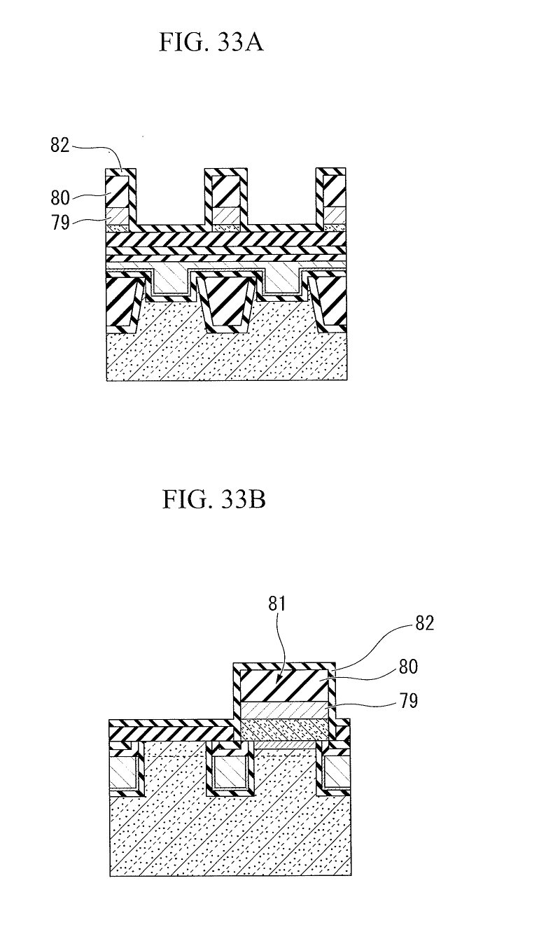

As shown in FIG. 33A and FIG. 33B, a silicon nitride film 82 is formed so as to cover the bit interconnect 81 in the memory cell region and the gate electrodes (first gate electrode 120a and second gate electrode 120b) in the peripheral circuit region.

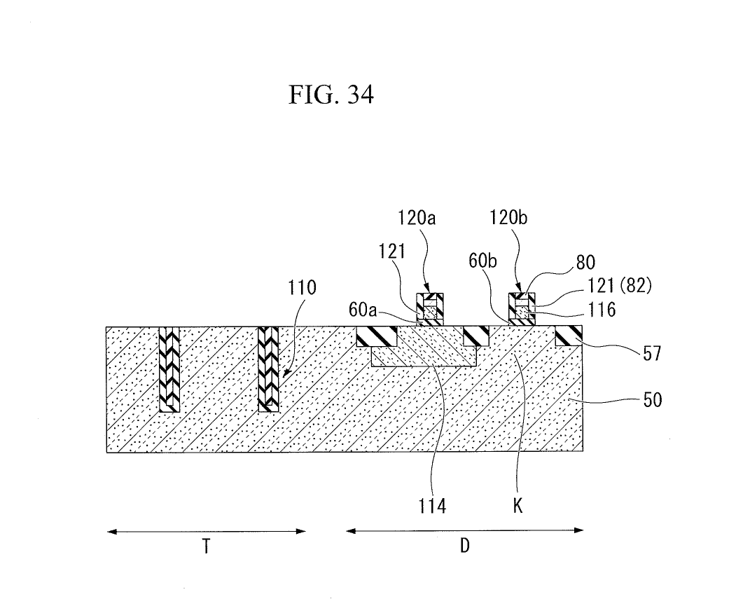

Using a photoresist film (not shown) as a mask, the memory cell region is subjected to anisotropic dry etching. By this etching, as shown in FIG. 34, a silicon nitride side wall 121 made of the silicon nitride film 82 is formed on the side surfaces of the gate electrodes in the memory cell region (first gate electrode 120a and first gate electrode 120b) in the peripheral circuit region. When this is done, the film thickness of the silicon nitride film side wall 121 can be adjusted in accordance with the desired MOS transistor characteristics. Also, before forming the silicon nitride side wall 121, a low-concentration impurity diffusion layer (LDD layer) may be formed by ion implantation into the active region K on both sides of the gate electrodes.

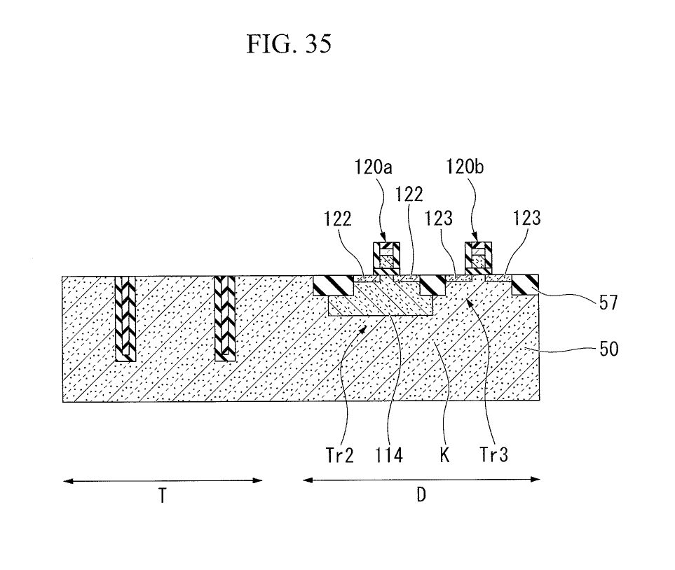

Using a photoresist film (not shown) as a mask, ion implantation is done into the peripheral circuit region, so as to form a second impurity diffusion layer 122 and a third impurity diffusion layer 123 in the surface layer part of the active region K, as shown in FIG. 35. The second impurity diffusion layer 122 is a region into which a p-type impurity diffuses, and functions as the source/drain region of the first MOS transistor Tr2. The third impurity diffusion layer 123 is a region into which an n-type impurity diffuses, and functions as the source/drain region of the second MOS transistor Tr3.

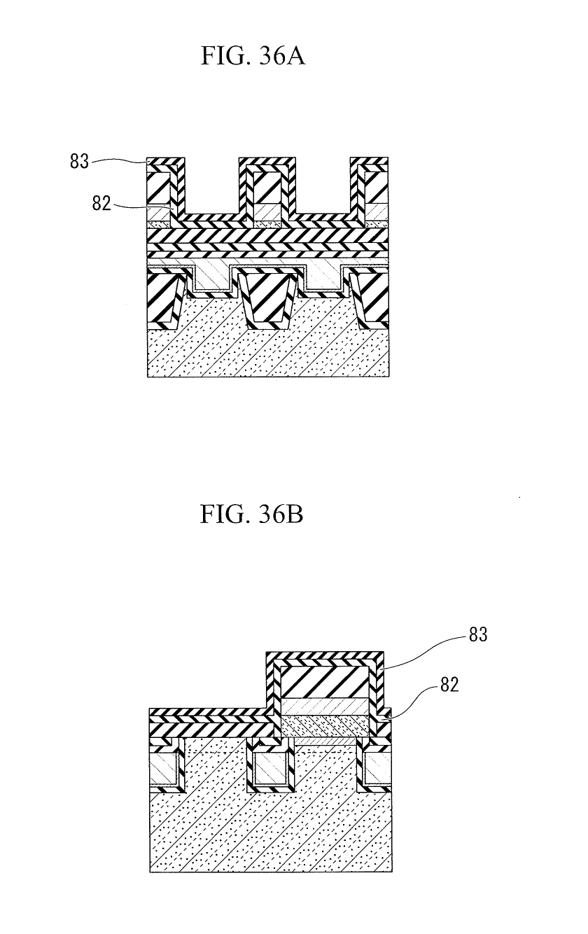

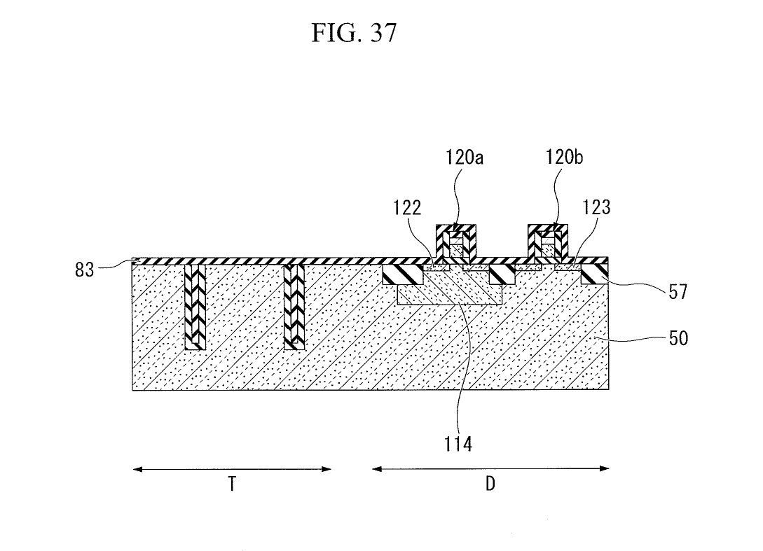

As shown in FIG. 36A, FIG. 36B, and FIG. 37, a liner film 83 made of silicon nitride film or the like with a film thickness of 10 to 20 nm is formed so as to cover the memory cell region and the peripheral circuit region. By forming the liner film 83 made from an oxidation-resistant film at this point, it is possible to prevent damage to already formed lower layers by oxidation in the SOD film annealing process to be described later.

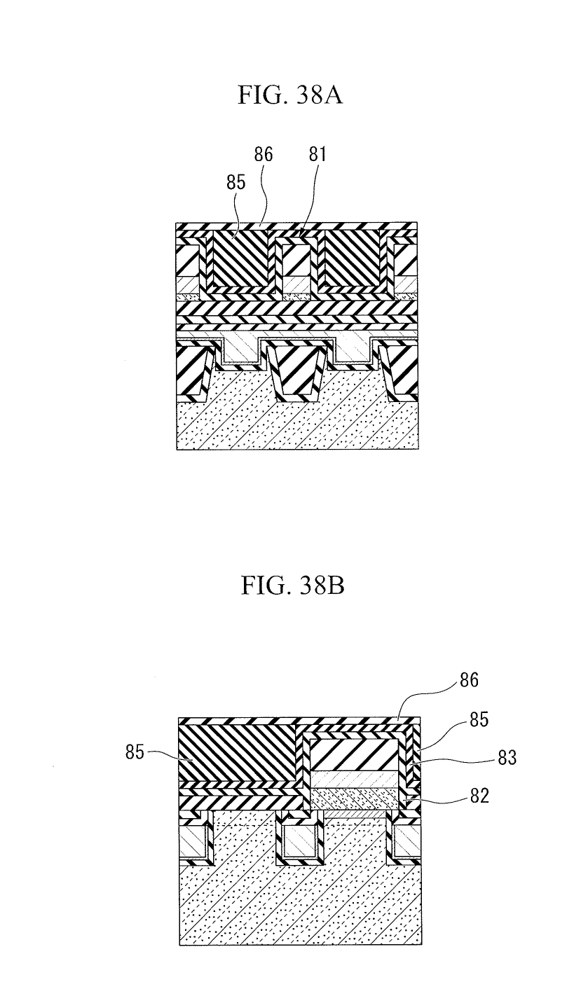

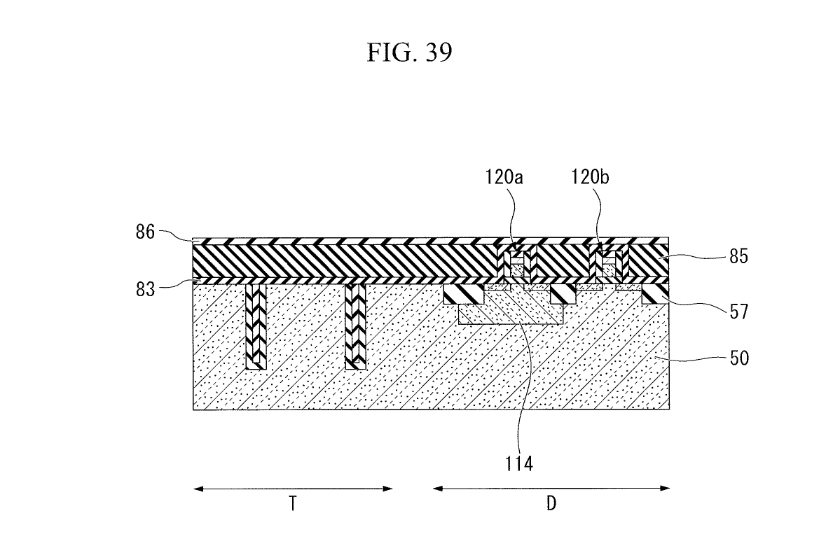

As shown in FIG. 38A, FIG. 38B, and FIG. 39, an SOD film, which is a deposited film, is deposited so as to fill between bit interconnects 81 in the memory cell region and fill between the first gate electrode 120a and the first gate electrode 120b in the peripheral circuit region. Next, annealing is performed in a high-temperature atmosphere that includes water, to modify the SOD film to be the solid deposited film 85. Next, CMP processing is performed until the upper surface of the liner film 83 in the memory cell region is exposed, and the surface of the deposited film 85 is planarized.

Using CVD the second interlayer insulating film 86 made of a silicon oxide film is formed so as to cover the memory cell region and the peripheral circuit region.

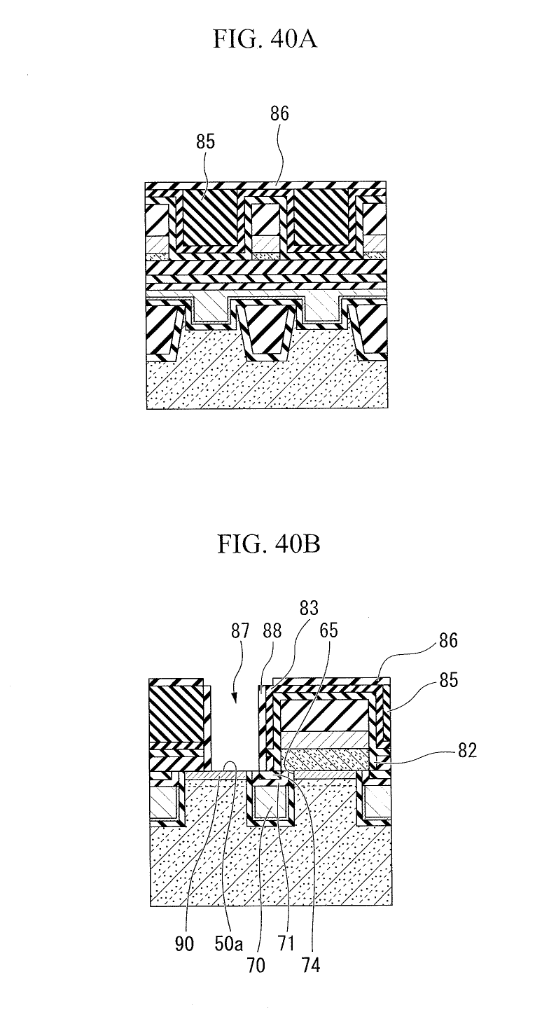

Using photolithograph and dry etching, a connection hole (second contact aperture) 87 is formed, as shown in FIG. 40A and FIG. 40B. When this is done, the position of formation of the second contact aperture 87, in the case of the structure described earlier with regard to FIG. 2, is taken to be opposite the capacitor contact plug formation region 17 of FIG. 2. In this case, the second contact aperture 87 can be formed using the SAC (self-alignment contact) method, in which the silicon nitride film 82 and liner film 83 already formed on the side surface of the bit interconnect 81 is used as the side wall.

By etching at the time of the formation of the second contact aperture 87, the upper surface 50a of the semiconductor substrate and the upper surface of the buried insulating film 74 are exposed at the region of intersection between the second contact aperture 87 and the active region K as shown in FIG. 2. A first word line 70 having a constitution that fills the trench 65 is positioned low the region of exposure of the semiconductor substrate, and a buried insulating film 74 is buried via a liner film 71 above.

Next, a side wall 88 made of a silicon nitride film is formed so as to cover the inner wall of the second contact aperture 87. Next, ion implantation of an n-type impurity (for example, phosphorus) is done into the upper surface 50a of the semiconductor substrate 50 exposed as the bottom part of the second contact aperture 87. By this ion implantation, an n-type second high-concentration impurity diffusion layer 90 is formed in the vicinity of the upper surface 50a of the semiconductor substrate 50 exposed at the bottom part of the second contact aperture 87. This second high-concentration impurity diffusion layer 90 functions as the source/drain region in the recess-type transistor in the present embodiment.

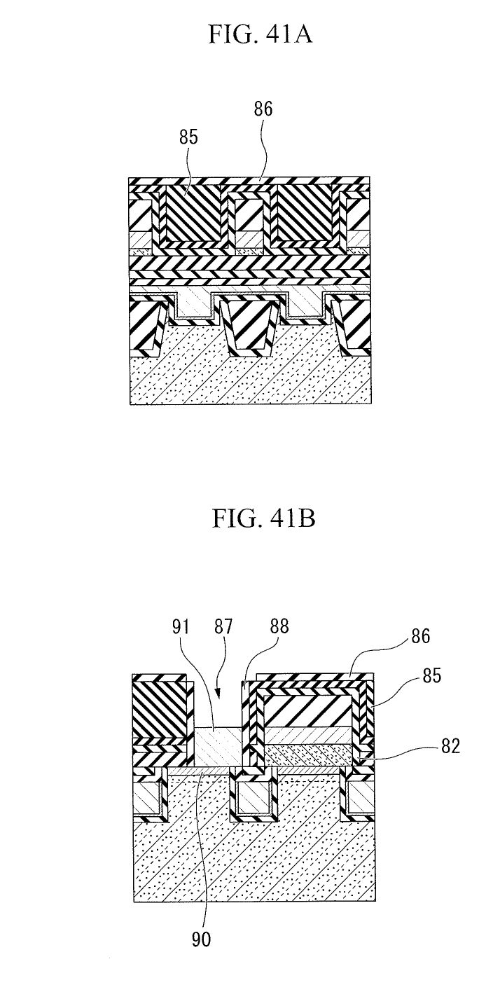

As shown in FIG. 41A and FIG. 41B, a polysilicon film containing phosphorus is deposited so that it fills inside the second contact aperture 87 and also so that it covers over the second interlayer insulating film 86. Next, etching is done so that the polysilicon film remains in the bottom part of the second contact aperture 87. By this etching, a bottom part conducting film 91 made of a polysilicon film is formed.

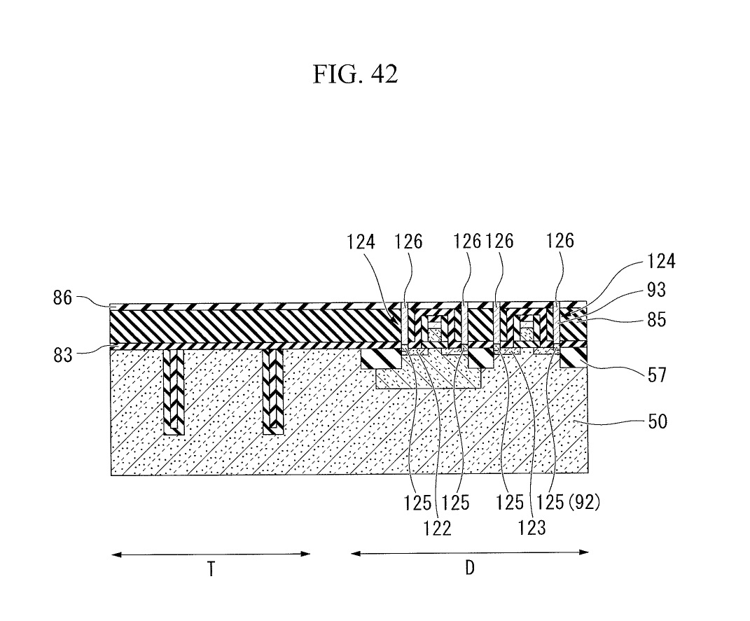

As shown in FIG. 42, using a photoresist film (not shown) as a mask, anisotropic dry etching is done to form a peripheral contact aperture 124 so that it passes through the second interlayer insulating film 86 and the deposited film 85 in the peripheral circuit region and also so that the upper surface 50a of the semiconductor substrate 50 is exposed. When this is done, the position of formation of the peripheral contact aperture 124 is adjusted so that second impurity diffusion layer 122 and the third impurity diffusion layer 123 are exposed as the bottom part of the peripheral contact aperture 124.

A silicide film 125 made of cobalt silicide (CoSi) or the like is formed in a part of the bottom surface of the peripheral contact aperture at which the second impurity diffusion layer 122 and the third impurity diffusion layer 123 are exposed.

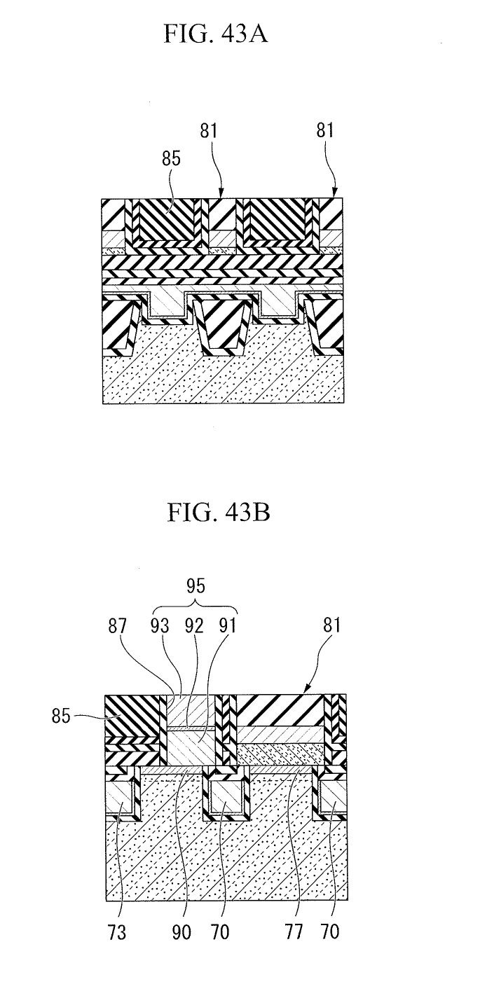

When this is done, the silicide layer 92 (125) is formed so as to cover the upper surface of the bottom part conducting film 91, as shown in FIG. 43A and FIG. 43B.

A metal film 93 made of, for example, tungsten is formed so as to fill the peripheral contact aperture 124 in the peripheral circuit region and the second contact aperture 87 in the memory cell region.

CMP processing is done to planarize the surface until the upper surface of the deposited film 85 in the memory cell region and the second interlayer insulating film 86 in the peripheral circuit region are exposed, and the silicide layer 92 and the metal film 93 on the deposited film 85 and on the second interlayer insulating film 86 are removed.

By this CMP processing, a capacitor contact plug 95 having a three-layer structure of the bottom part conducting film 91, the silicide layer 92, and the metal film 93 is formed in the memory cell region. Also, a peripheral contact plug 126 made of the silicide layer 125 (92) and the metal film 93 is formed in the peripheral circuit region. By this constitution, the peripheral contact plugs 126 are electrically conductive with the source/drain regions of the transistors.

According to the present embodiment, a capacitor contact plug 95 is formed over a second high-concentration impurity diffusion layer 90 that is positioned between an first adjacent word line 70 and second word line 73, and a bit interconnect 81 is formed over a first high-concentration impurity diffusion layer 77, so that the capacitor contact plug 95 and the bit interconnect 81 can be precisely disposed over the first word line 70 that has a trench structure, enabling a contribution to the micro-structuring of the semiconductor device.

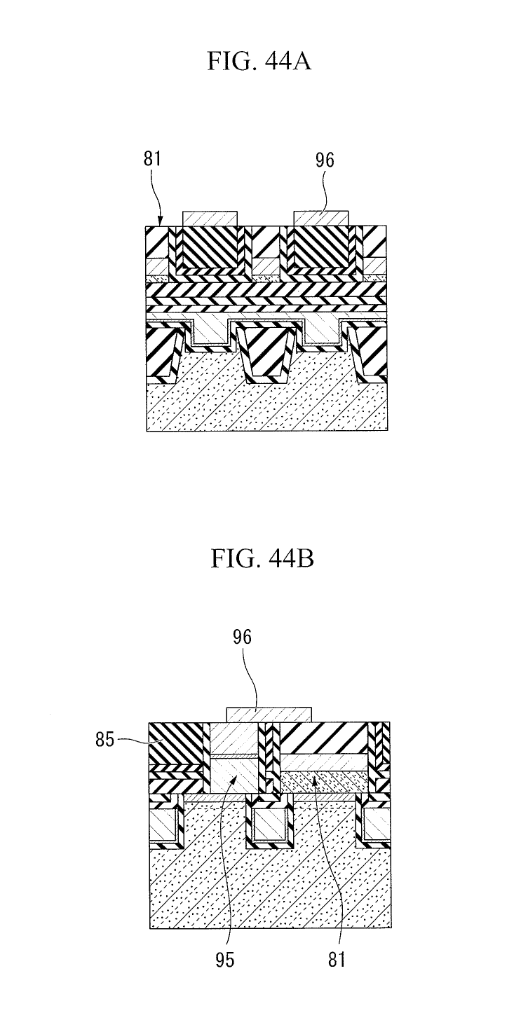

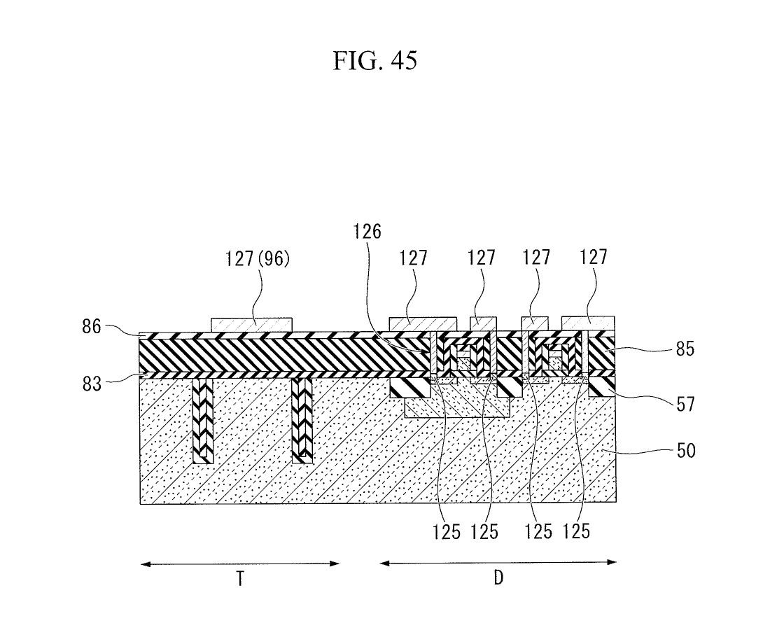

Next, tungsten nitride (WN) and tungsten (W) are sequentially deposited in the memory cell region and the peripheral circuit region, so as to form a metal film made of a film laminate (not shown). Next, the above-noted metal film in the memory cell region and the peripheral circuit region is patterned simultaneously. By this patterning, a capacitor contact pad 96 made of the metal film is formed in the memory cell region, as shown in FIG. 44A and FIG. 44B. As shown in FIG. 45, a local interconnect 127 made of the metal film is formed in the through electrode formation region T and in the element formation region D of the peripheral circuit region, simultaneously with the capacitor contact pad 96.

As shown in FIG. 44A and FIG. 44B, the capacitor contact pad 96 is constituted so as to be connected to the capacitor contact plug 95, and the local interconnect 127 is constituted so as to be connected to the peripheral contact plug 126.

As shown in FIG. 45, the local interconnect 127 that is disposed in the through electrode formation region T of the peripheral circuit region may be electrically conductive with another local interconnect 127 in a part not shown. The local interconnect 127 disposed in the through electrode formation region T functions to connect the via plug V formed in a subsequent process step.

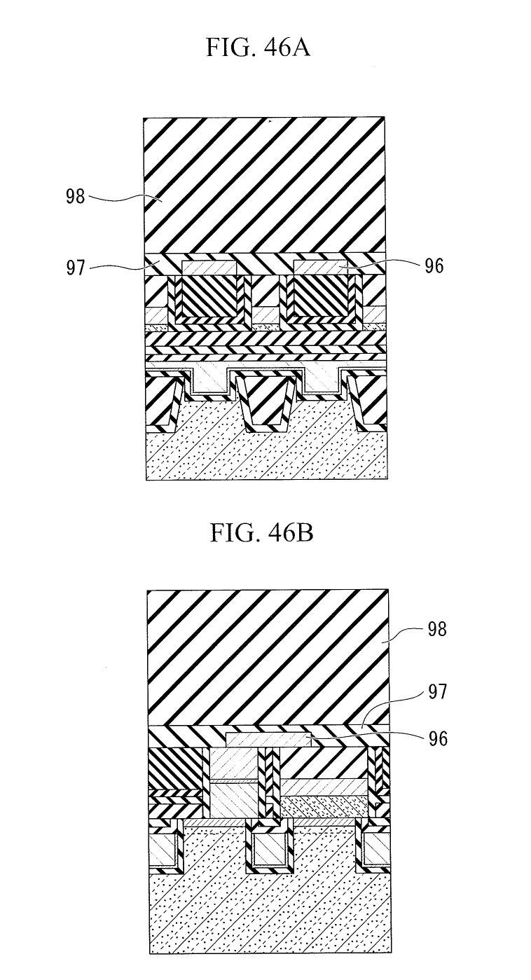

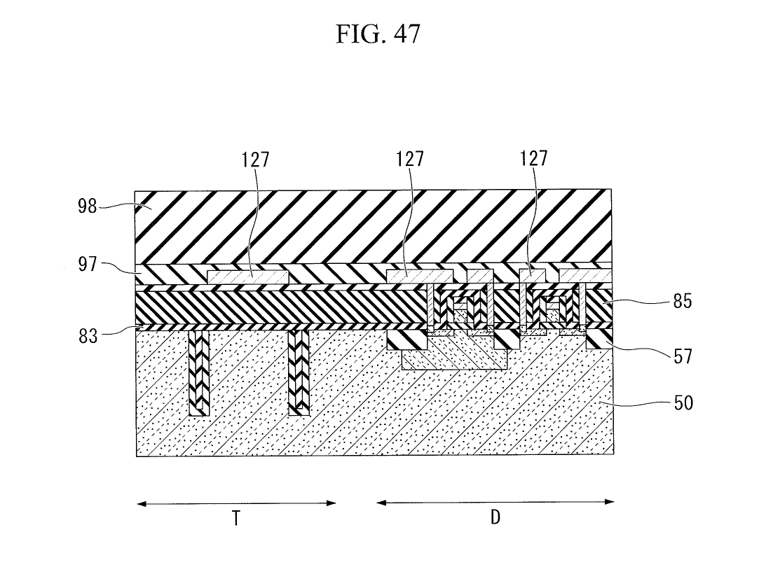

As shown in FIG. 46A, FIG. 46B, and FIG. 47, a stopper film 97 made of a silicon nitride film and a third interlayer insulating film 98 made of a silicon oxide film or the like with a film thickness of approximately 1 to 2 μm are sequentially laminated over the capacitor contact pad 96 in the memory cell region and over the local interconnect 127 in the peripheral circuit region. When this is done, the film thickness of the third interlayer insulating film 98 may be set appropriately in accordance with the desired electrostatic capacitance of the capacitor.

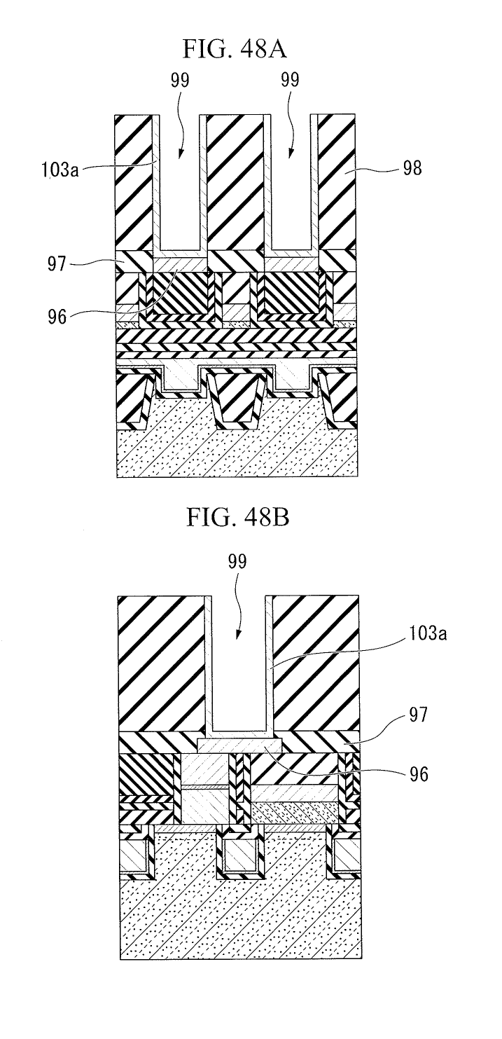

As shown in FIG. 48A and FIG. 48B, an aperture (contact aperture) 99 is formed in the third interlayer insulating film 98 and the stopper film 97, so as to expose the upper surface of the capacitor contact pad 96 in the memory cell region. Next, a first electrode 103a made of titanium nitride or the like is formed so as to cover the inner wall surface of the aperture 99. The first electrode 103a functions as the lower electrode of the capacitor element to be described later. The bottom part of the first electrode 103a is connected to the capacitor contract pad 96.

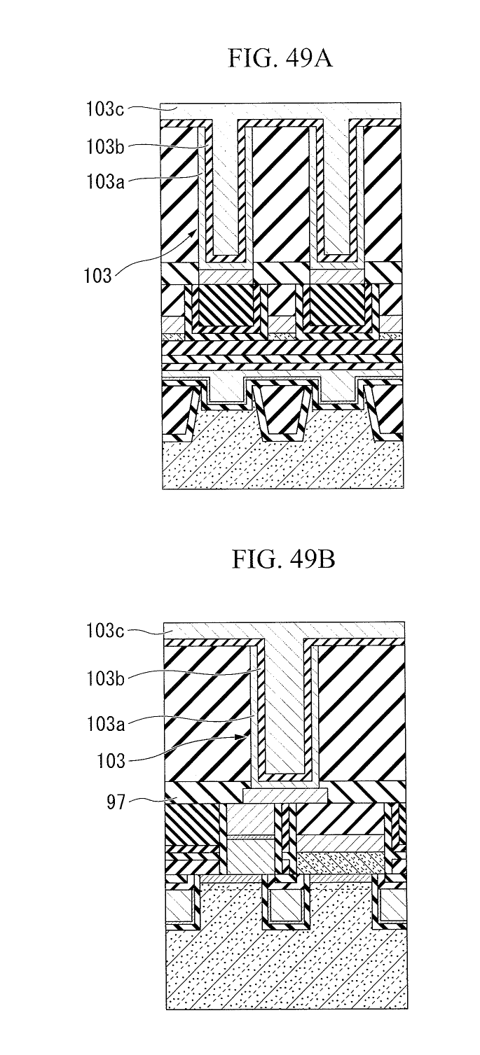

As shown in FIG. 49A and FIG. 49B, a capacitor 103 is formed. First, a capacitor insulating film 103b is formed so as to cover the inner wall surface of the first electrode 103a. When this is done, zirconia (ZrO₂), alumina (Al₂O₃), hafnia (HfO₂) or film laminate thereof can be used as the capacitor insulating film 103b.

An upper electrode 103c made of titanium nitride or the like is formed so as to cover the inner wall surface of the capacitor insulating film 103b. The above forms the capacitor 103.

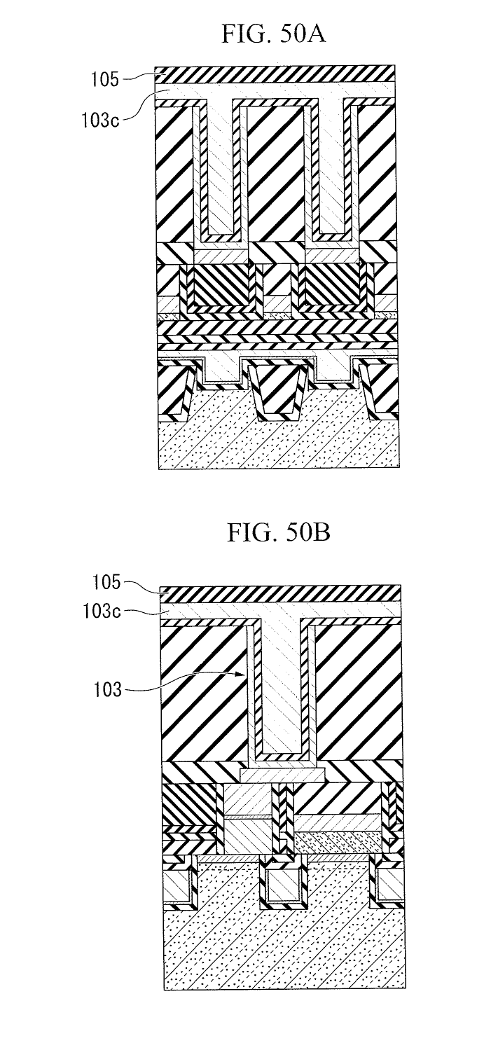

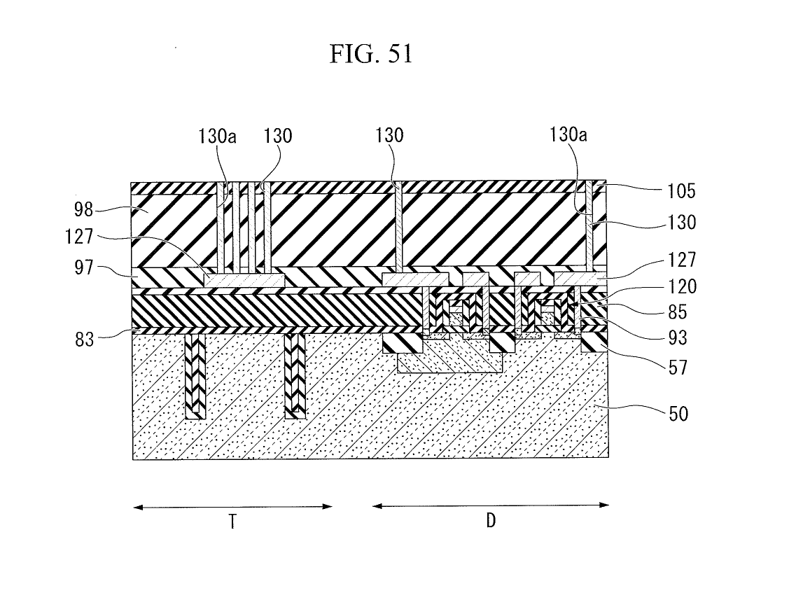

As shown in FIG. 50A, FIG. 50B, and FIG. 51, a fourth interlayer insulating film 105 made of a silicon oxide film or the like is formed so as to cover over the upper electrode 103c in the memory cell region and the third interlayer insulating film 98 in the peripheral circuit region.

As shown in FIG. 51, an aperture 130a is formed that passes through the element formation region D and the fourth interlayer insulating film 105, the third interlayer insulating film 98, and the stopper 97 in the through electrode formation T, and that also exposes the local interconnect 127.

A metal film of tungsten or the like is filled into the aperture 130a. By doing this, a local contact plug 130 is formed that connects to the element formation region D and the local interconnect 127 in the through electrode formation region T.

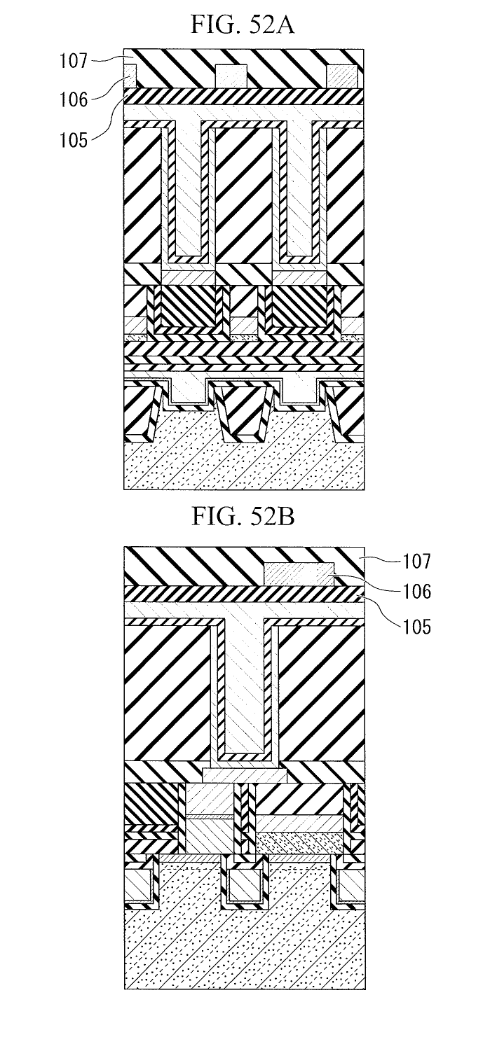

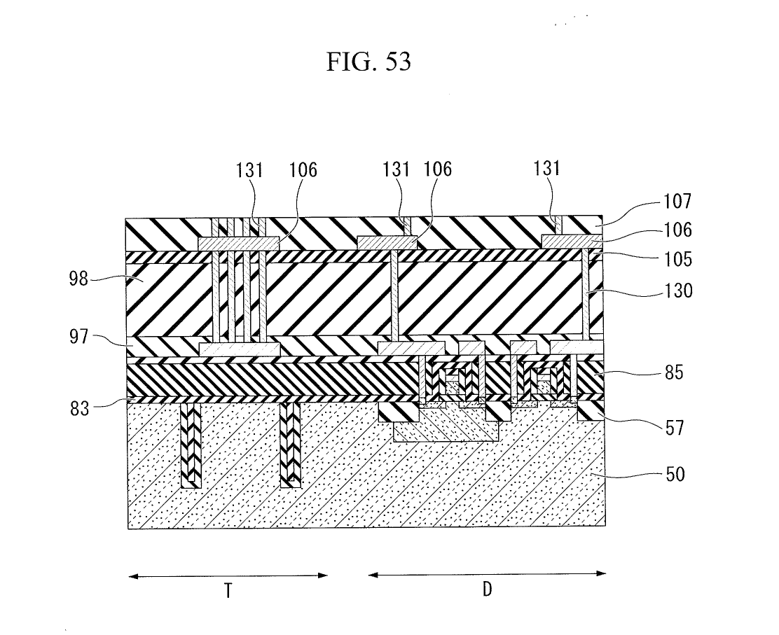

As shown in FIG. 52A, FIG. 52B, and FIG. 53, a first interconnect 106 made of aluminum (Al) or copper (Cu) or the like is formed over the fourth interlayer insulating film 105 in the memory cell region and the peripheral circuit region. When this is done, a sixth interconnect 106 in the peripheral circuit region is formed so as to connect to the local contact plug 130, as shown in FIG. 53. Next, a fifth interlayer insulating film 107 made of a silicon oxide film or the like is formed so as to cover the first interconnect 106 in the memory cell region and the peripheral circuit region.

As shown in FIG. 53, a first contact plug 131 made of a metal film such as tungsten or the like is formed so as to pass through the fifth interlayer insulating film 107 and also connect to the first interconnect 106.

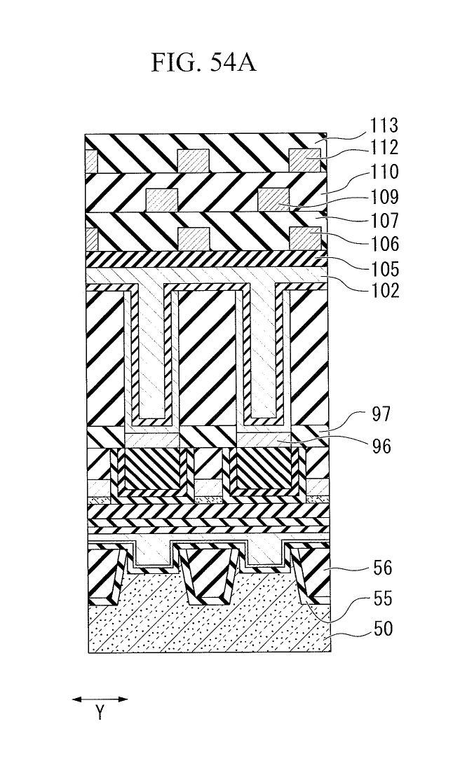

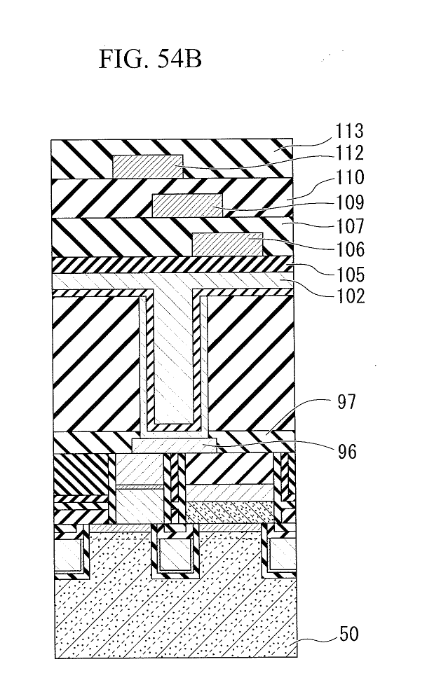

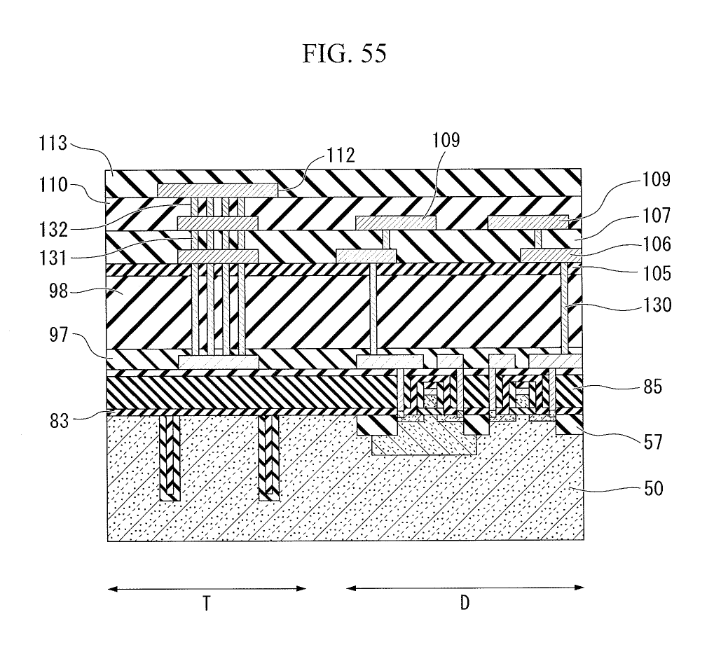

As shown in FIG. 54A, FIG. 54B, and FIG. 55, a second interconnect 109 made of aluminum (Al) or copper (Cu) or the like is formed over the fifth interlayer insulating film 107. When this is done, the second interconnect 109 in the peripheral circuit region is formed so as to connect to the first contact plug 131.

A sixth interlayer insulating film 110 made of a silicon oxide film or the like is formed so as to cover the second interconnect 109 in the memory cell region and the peripheral circuit region.

As shown in FIG. 54, a second contact plug 132 made of a metal film of tungsten or the like is formed so as to cover the sixth interlayer insulating film 110 in the through electrode formation region T and also so as to connect to the second interconnect 109.

A third interconnect 112 is formed over the sixth interlayer insulating film 110 in the through electrode formation region T. The third interconnect 112 is the uppermost interconnect layer, and also serves as a pad when forming a bump electrode on the surface. For this reason, it is desirable to avoid metal films such as copper that exhibit natural oxidation as the material of the third interconnect 112. Aluminum, for example, can be used as this material.

When this is done, the third interconnect 112 is formed so as to connect to the second contact plug 132. The region for forming the third interconnect is not restricted to the through electrode formation region T, and the third interconnect may be disposed in the element formation region D, in which case the third interconnect 112 may be made an interconnect layer that connects to the second interconnect 109.

As shown in FIG. 55, a protective film 113 made of, for example, a silicon oxynitride (SiON) film is formed so as to cover the third interconnect 112. By doing this, the memory cell region of the semiconductor device having the structure as shown in FIG. 2 and FIG. 3 is completed.

The processes for forming the through electrode 200 in the peripheral circuit region will be described.

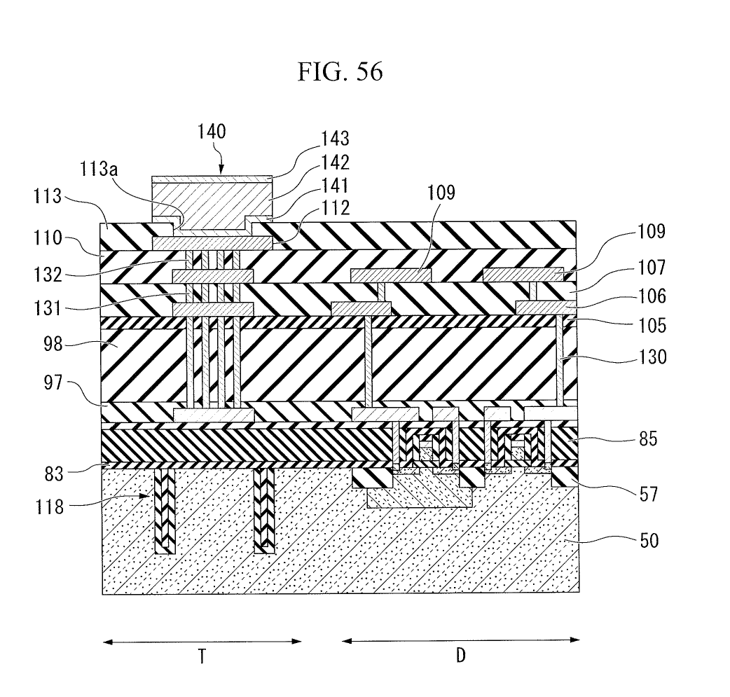

As shown in FIG. 56, an aperture 113a that passes through the protective film 113 and that exposes the upper surface (one surface) of the third interconnect 112 is formed.

A seed film 141, a copper film, and a surface metal film 143 are sequentially laminated in the aperture 113a and then patterned. By this patterning, a first bump 140 that is made of the seed film 141, the copper bump 142, and the surface metal film 143, and which connects to the third interconnect 112 is formed. When doing this, a film laminate made of, for example, a titanium (Ti) film onto which copper is laminated can be used as the seed film 141. It is preferable to form the copper bump 142 by electroplating to a height (film thickness) of 10 to 12 μm. As the surface metal film, it is possible to use, for example, an alloy film (Sn—Ag) of tin and silver having a film thickness of 2 to 4 μm.

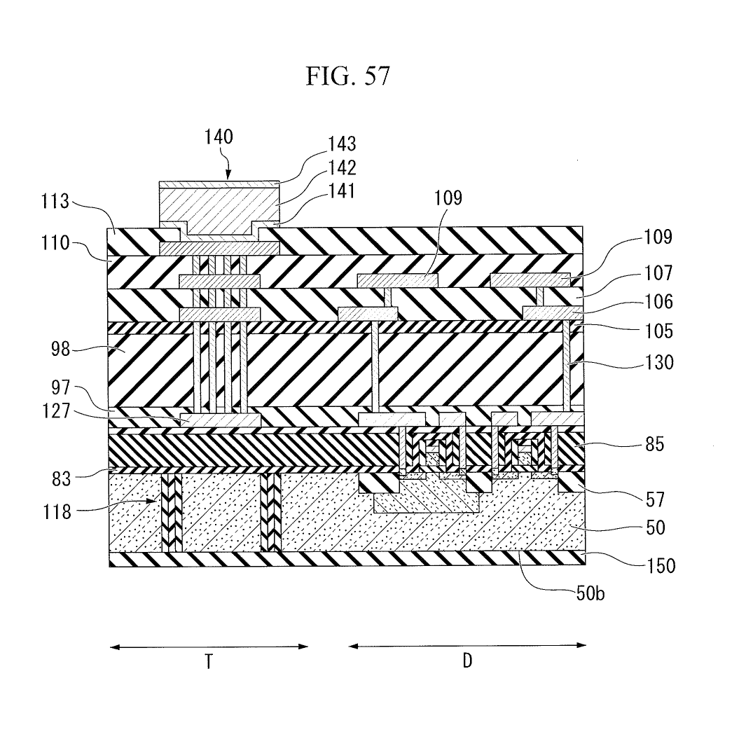

As shown in FIG. 57, the rear surface insulating film 150 is formed.

First, a supporting substrate made of an acrylic resin or fused quartz (not shown) is affixed to the lower surface 50b side of the semiconductor substrate 50. Next, with this supporting substrate fixed to the semiconductor substrate 50, the lower surface 50b of the semiconductor substrate 50 is ground (by back grinding) to a prescribed thickness (for example 50 μm).

By this grinding the end part of the member 118 that had been formed beforehand is exposed at the lower surface 50b side of the semiconductor substrate 50. By adopting this constitution, the member 118 is constituted to be completely surrounded by the side surface of the via plug V. For this reason, it is possible to achieve insulation between adjacent through electrodes 200. It is also possible to achieve insulation between a through electrode 200 and the element formation region D adjacent to the through electrode 200. For this reason, it is possible to prevent interference to the MOS transistors (first MOS transistor Tr2 and second MOS transistor Tr3).

The rear surface insulating film 150 made of, for example, a silicon nitride film with a film thickness of 200 to 400 nm is formed so as to cover the lower surface 50b side of the semiconductor substrate 50. The rear surface insulating film 150 prevents copper used in the via plug V formed in a subsequent process step from diffusing inward from the lower surface 50b side of the semiconductor substrate 50 during the manufacturing process. For this reason, by forming the rear surface insulating film 150, it is possible to prevent a worsening of element characteristics in the semiconductor device.

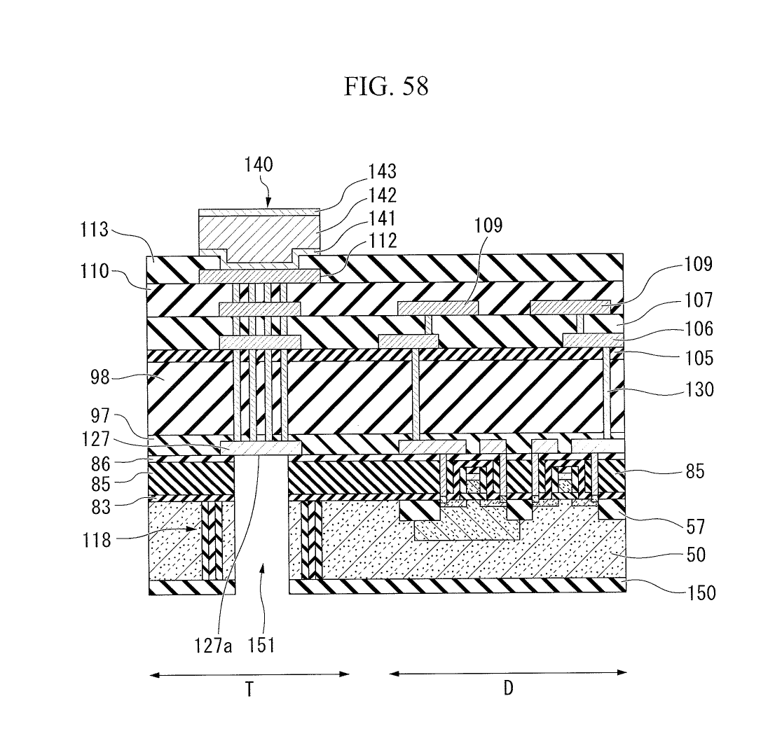

As shown in FIG. 58, an aperture 151 that passes through the rear surface insulating film 150 in the through electrode formation region T, the semiconductor substrate 50, the liner film 83, the deposited film 85, and the second interlayer insulating film 86 is formed by anisotropic dry etching, so as to expose the lower surface (other surface) 127a side of the local interconnect 127.

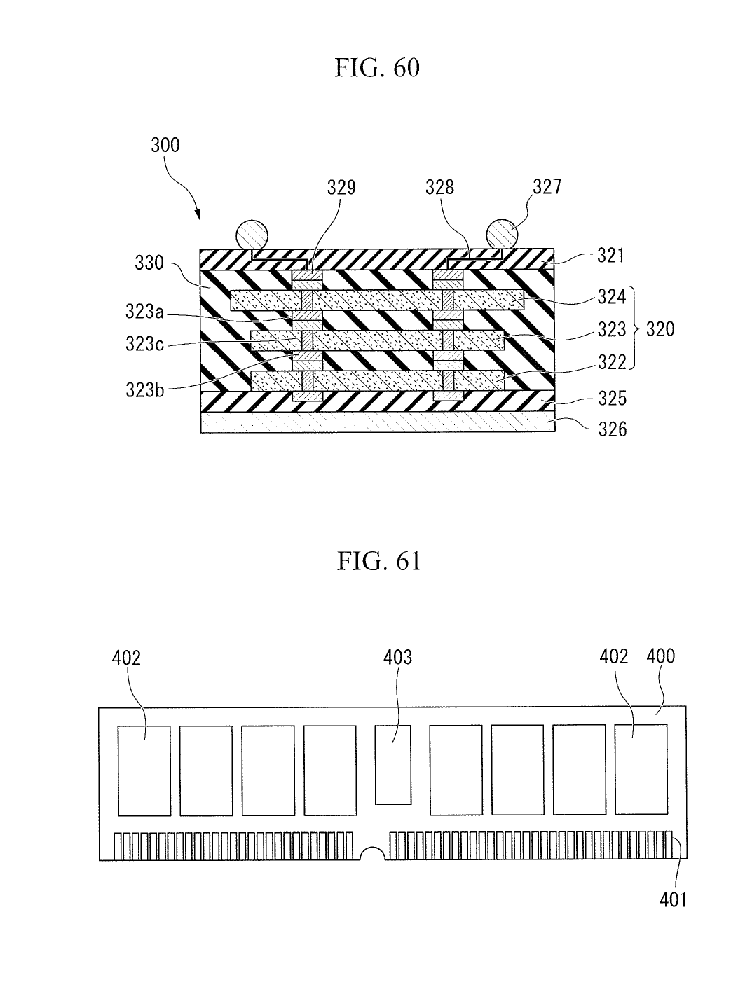

As shown in FIG. 60, the via plug V is formed.

First, a seed film 161 made from a film laminate of a titanium (Ti) film, onto which copper is laminated, is formed so as to cover the inner wall surface of the aperture 150 and the rear surface insulating film 150 other surface side. Next, electroplating is used to form a copper bump 162, via the seed film 161, so as to fill the aperture 151. This copper bump 162 functions as the via plug V. When this is done, the constitution of the copper bump 162 is such that it protrudes towards the lower surface side (other surface side) from the rear surface insulating film 150.

A metal film 163 made of a film laminate of, for example, an Au/Ni film of nickel (Ni) and gold (Au) sequentially laminated to a film thickness of approximately 2 to 4 μm is formed so as to cover the other surface side of the copper bump 162. By doing this, a via plug V made of the seed film 161, the copper bump 162, and the metal film 163 is formed. Of the via plug V, the part that protrudes from the lower surface side of the rear surface insulating film 150 is taken as the second bump 160.

When this is done, it is preferable to form the thickness that protrudes from the other surface side of the rear surface insulating film 150 to be 8 μm or less. Also, it is preferable to form the second bump 160 so that other surface side surface is flat.

By the above, a through electrode 200 made of the via plug V, the local interconnect 127, the local contact plug 130, the first interconnect 106, the first contact plug 131, the second interconnect 109, the second contract plug 132, the third interconnect 112, and the first bump 140 is formed.

After the above, the supporting substrate is removed, and dicing is done to obtain individual pieces that are complete semiconductor devices 100. It is possible to interchange the type of the metal film 143 on the first bump 140 side with the type of metal film 143 on the first bump 140 side. That is, the metal film 143 on the first bump 140 side may be made a film laminate made of an Au/Ni film, with the metal film 163 on the second bump 160 side being an alloy of tin and silver (Sn—Ag film).

Also, the metal film 143 and the metal film 163 are not restricted to being combinations of an Au/Ni film laminate and an Sn—Ag film. It is possible to apply a combination of metal films that enable connection and bonding when stacking the semiconductor chips.

According to the present embodiment, by simultaneously patterning metal films formed in the memory cell region and the peripheral circuit region of the semiconductor device 100, it is possible simultaneously for the capacitor contact pad 96 of the memory cell region and the local interconnect 127 of the peripheral circuit region. For this reason, even in a semiconductor device 100 having a buried-gate MOS transistor (cell transistor Tr1) in the memory cell region and a planar type MOS transistors (first MOS transistor Tr2 and second MOS transistor Tr3) in the peripheral circuit region, it is possible to suppress an increase in manufacturing process steps. For this reason, it is possible to suppress the manufacturing cost in the process steps for through electrode 200.

By forming a local interconnect 127 made of a metal film in the through electrode formation region T, the progress of etching when forming the aperture 151 can be stopped. For this reason, it is easy to adjust the depth of the aperture 151 by the formation position of the local interconnect 127. For this reason, the formation of a microstructured through electrode 200 is facilitated, even for a microstructured semiconductor device having a buried-gate MOS transistor.

Also, because the via plug V is directly connected to the local interconnect 127 made of a metal, it is possible to suppress the electrical resistance of the through electrode 200. By forming the seed film 161 that has a high electrical conductivity and a copper bump 162 by burying in the aperture 151, it is possible to form a through electrode 200 with high conductivity. For this reason, it is possible to suppress the resistance, even when a plurality of semiconductor devices 100 are stacked and through electrodes 200 are mutually connected. For this reason, by laminating a semiconductor chip between semiconductor devices 100, it is possible to achieve a high level of integration in the semiconductor device.

By forming the member 118 made of an insulator so as to surround the side surface of the via plug V, it is possible to achieve insulation between adjacent through electrodes 200 (via plugs V). Because it is also possible to achieve insulation between a via plug V and an element formation region D adjacent to the via plug V, it is possible to prevent interference with the MOS transistors (first MOS transistor Tr2 and second MOS transistor Tr3). For this reason, it is possible to cause the MOS transistors to operate stably.

By forming a rear surface insulating film 150 made of a silicon nitride film and having a film thickness of 200 to 400 nm so as to cover the lower surface 50b side of the semiconductor substrate 50, it is possible to prevent diffusion of copper from the via plug V into the semiconductor substrate 50 during the manufacturing process. For this reason, it is possible to prevent a worsening of the element characteristics in the semiconductor device 100.

By implanting ions having different conductivity types into each of the regions (T1 and T2) in the peripheral circuit region, it is possible to form gate electrodes (first gate electrodes 120a and 120b) having different types of conductivity on the peripheral circuit region. For this reason, it is possible to form MOS transistors having differing types of conductivity on the peripheral circuit region (first MOS transistor Tr2 and second MOS transistor Tr3), and to improve the characteristics of the transistors.

An example of application of a semiconductor device of the present invention will be described.

FIG. 60 is a schematic cross-sectional view showing a semiconductor device (DRAM package) 300 with a high level of integration, in which two DRAM chips (semiconductor chips) 323 and 324 are stacked, using the present invention. In FIG. 60, the cross-sectional view is shown with the external terminals (solder balls 327) position facing upward. The constitution is described below.

The DRAM package 300 has a metal substrate 326 that is substantially square. A chip stack 320 is mounted to one surface side of the substrate 326, via an attachment film 325.

The chip stack 320 is constituted, for example, by the stacking in sequence from one side semiconductor devices 322 and 323 and an interface chip (semiconductor chip) 324. Although in this example, the description is for the case of the stacking of three semiconductor chips, the number of chips is not restricted to being three, and may be four or more.

The semiconductor chips 322 and 323 have formed therein by the present invention memory cell circuits (not shown) and peripheral circuits for input and output of data to and from the memory with the outside.

The interface chip 324 is a chip for the purpose of controlling the semiconductor chips 322 and 323. The interface chip 324 has formed therein logic circuitry capable of controlling the input and output of data with respect to each of the semiconductor chips 322 and 323 and input and output of data with respect to the outside of the package.

On one surface side and another surface side of the semiconductor chips 322, 323, and 324, first bumps 323a and second bumps 323b.

The semiconductor chips 322, 323, and 324 are mutually electrically connected via the through electrodes 323c. The other surface side of the semiconductor chip 322 is fixed to the substrate 326 via the attachment film 325.

The first bumps 323a and second bumps 323b of each of the semiconductor chips 322, 323, and 324 are mutually attached by low-temperature (approximately 150 to 170° C.) heating and adjustment of the position of the through electrodes 323c. By fixing the semiconductor chip 322 to the substrate 326 beforehand, it is used as base for temporarily holding the first bumps 323a and the second bumps 323b of the semiconductor chips 323 and 324.

Because the specific structure of the through electrode 323c is as described in the previous embodiment, it is not described in detail for this embodiment. The semiconductor chips 322, 323, and 324 may have different sizes, as long as the dispositions of the through electrodes are the same.

A sealing element 330 made of resin is formed on one surface side of the substrate 326 to cover the chip stack 320. The sealing element 330 fills between each of the semiconductor chips 322, 323, and 324 of the chip stack 320 and also covers the sides of the chip stack 320. By this constitution, the semiconductor chips 322, 323, and 324 are protected by the sealing element 330 from shock.

A substantially square interconnect substrate 321 is disposed on one surface side of the interface chip 324. Terminals 329 are formed on the other surface side of the interconnect substrate 321, and the interconnect substrate 321 and the chip stack 320 are electrically connected via the terminals 329.

A plurality of solder balls 327 are formed on one surface side of the interconnect substrate 321. The solder balls 327 are terminals for input/output signals from the outside, and for application of power supply voltages, and function as external terminals of the DRAM package 300. The solder balls 327 and the terminals 329 are electrically connected by an interconnect formation layer 328.

According to the present embodiment, by using semiconductor chips that are provided with the through electrodes 323c of the present invention, it is possible to provide a DRAM package 300 that is dense and also that has good electrical characteristics.

The memory modules (semiconductor devices) providing the DRAM package having the through electrodes of the present invention will be described, using FIG. 61. FIG. 61 is a schematic plan view of a semiconductor memory module.

The semiconductor memory module 410 is generally constituted by DRAM packages 402, an interface chip 403, and input/output terminals 401. Each of these elements is described in detail below.

In a semiconductor memory module 410 according to the present embodiment, for example eight DRAM packages 402 and one interface chip 403 are mounted on a printed circuit board 400. The interface chip 403 need not be mounted on the printed circuit board 400.

The DRAM packages 402 have the same type of constitution as the DRAM package shown in FIG. 60. The printed circuit board is provided with a plurality of input/output terminals (I/O terminals) 401 for the purpose of making electrical connections between the DRAM packages 402 and the outside. By this constitution, data input and output are performed from, for example, an external memory controller, with respect to the DRAM packages 402, via the input/output terminals 401.

The interface chip 403 is a chip that controls the data input and output with respect to each DRAM package 403. The interface chip 403 performs timing adjustment of a clock signal (Clock) input from outside the semiconductor memory module 410 and the command address signal (Command Address), shapes signal waveforms, and supplies them to each of the DRAM packages 402.

The semiconductor memory module 410 of the present embodiment has semiconductor devices (DRAM packages 402) of a high level of integration, which has semiconductor devices of the present invention. For this reason, it is possible to accommodate microstructuring, and also possible to achieve large-capacity data storage.

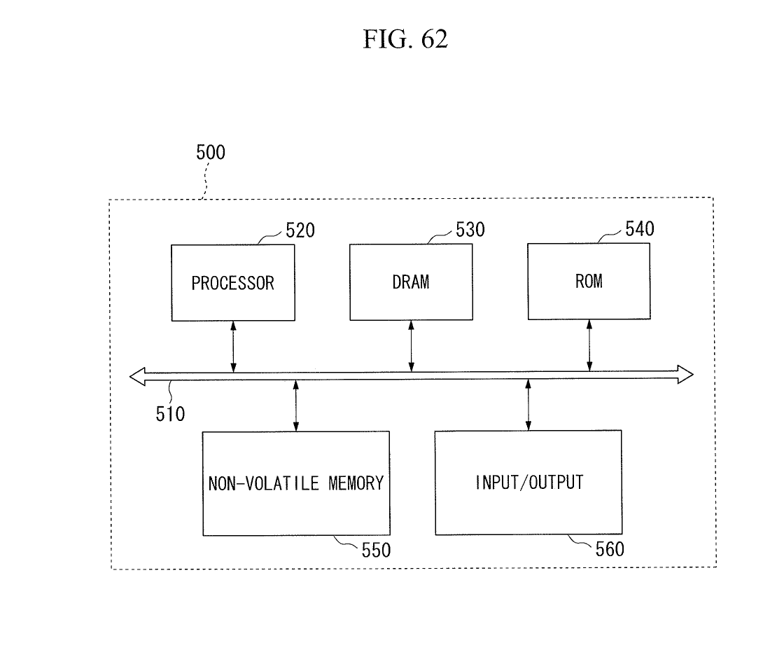

The data processing system 500, to which the present invention is applied, will be described, using FIG. 62. The data processing system 500 is an example of a system that has the above-noted semiconductor devices 100, 300, and 410.

The data processing system 500 includes a data processor 520 and a DRAM memory module 530 to which the present invention is applied.

Although there is mutual connection between the data processor 520 and the above-noted DRAM memory modules 530, via a system bus 510, connection may be made via a local bus, without going through the system bus 510. Although FIG. 62 illustrates one system bus 510, it necessary serial or parallel connection is done via connectors or the like.

Examples of the data processor 520 include an MPU (microprocessing unit) and a DSP (digital signal processor) or the like. The DRAM memory module 530 has the above-noted semiconductor devices 100, 300, and 410 formed using the present invention.

In the data processing system 500, if necessary, a non-volatile storage device 550, an input/output device 560, and a ROM (read only memory) 540 are connected to the system bus 510, although these are not essential elements.

The ROM 540 is used as storage for fixed data. A hard-disk or optical drive, or an SSD (solid-state drive) can be used as the non-volatile storage device 550. The input/output device 560 includes, for example, a display device such as an LCD display, and a data input device such as a keyboard. The input/output device 560 may be only an input device or only an output device.

Although as shown in FIG. 62, the number of each of the constituent elements of the data processing system 500 is made one for the purpose of simplicity, the number of each constituent element is not restricted in this manner, and is at least one and may be a plurality thereof. Although the data processing system 500 encompasses, for example, a computer system, it is not necessarily restricted in this manner.

Because the data processing system 500 of the present embodiment has the semiconductor device 100 and the memory module 410 that use the present invention, it can achieve high-speed data processing.

Specifically, because the semiconductor device 100 according to the present invention has a structure with buried-gate MOS transistors in a memory cell region and with a planer-type MOS transistor in the peripheral circuit region, it has a high level of integration. Also, because the local interconnect 127 made of metal and a via plug V are directly connected, it has good electrical characteristics. Also, because a DRAM package 420 provided with a semiconductor device 100 having these good electrical characteristics and high-speed data processing is provided in the semiconductor device memory module 410 according to the present embodiment, in addition to the operation of the semiconductor memory module operating at high speed, it has high performance with an increase in storage capacity.

By virtue of the above, it is possible to achieve high performance data processing speed in a data processing system 500 having the semiconductor memory module 410.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device includes hardware and/or software that is constructed and/or programmed to carry out the desired function.

The embodiments of methods, software, firmware or codes described above may be implemented by instructions or codes stored on a machine-accessible or machine readable medium. The instructions or codes are executable by a processing element or processing unit. The machine-accessible/readable medium may include, but is not limited to, any mechanisms that provide, store and/or transmit information in a form readable by a machine, such as a computer or electronic system. In some cases, the machine-accessible/readable medium may include, but is not limited to, random-access memories (RAMs), such as static RAM (SRAM) or dynamic RAM (DRAM), read-only memory (ROM), magnetic or optical storage medium and flash memory devices. In other cases, the machine-accessible/readable medium may include, but is not limited to, any mechanism that receives, copies, stores, transmits, or otherwise manipulates electrical, optical, acoustical or other form of propagated signals such as carrier waves, infrared signals, digital signals, including the embodiments of methods, software, firmware or code set forth above.

Furthermore, the particular features, structures, or characteristics may be combined in any suitable manner in one or more embodiments.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a semiconductor substrate having a memory cell region and a peripheral circuit region;
memory cells in the memory cell region;
buried word lines in a plurality of grooves of the semiconductor substrate in the memory cell region;
a first interlayer insulating film over the semiconductor substrate;
a first interconnect over the first interlayer insulating film in the peripheral circuit region; and
a via plug penetrating the semiconductor substrate and the first interlayer insulating film, the via plug being coupled to the first interconnect in the peripheral circuit region.

2. The semiconductor device according to claim 1, wherein the via plug is in contact with the first interconnect.

3. The semiconductor device according to claim 1, wherein the first interconnect comprises a local interconnect disposed on the first interlayer insulating film.

4. The semiconductor device according to claim 1, wherein the via plug includes a projecting portion that projects from the semiconductor substrate.

5. The semiconductor device according to claim 1, further comprising:
a first insulating film on a first surface of the semiconductor substrate,
wherein the first interlayer insulating film is disposed over a second surface of the semiconductor substrate, the second surface is opposite to the first surface,
wherein the via plug penetrates the first insulating film, the semiconductor substrate and the first interlayer insulating film, and
wherein the projecting portion projects from the first insulating film.

6. The semiconductor device according to claim 1, further comprising:
a first isolating film in the semiconductor substrate, the first isolating film surrounding the via plug in the semiconductor substrate, the first isolating film isolating the via plug from outside the first isolating film.

7. The semiconductor device according to claim 1, further comprising:
a capacitive contact pad disposed over the first interlayer insulating film, and the capacitive contact pad being in a memory cell region of the semiconductor substrate,
wherein the first interconnect comprises a local interconnect disposed over the first interlayer insulating film, the local interconnect being in a peripheral circuit region of the semiconductor substrate,
the capacitive contact pad comprises a first patterned portion of a conductive film, and
the first interconnect comprises a second patterned portion of the conductive film.

8. The semiconductor device according to claim 7, further comprising:
a capacitor being disposed in the memory cell region, the capacitor being coupled to the capacitive contact pad.

9. The semiconductor device according to claim 8, further comprising:
a second interlayer insulating film covering the capacitive contact pad and the first interconnect, the second interlayer insulating film burying the capacitor.

10. The semiconductor device according to claim 9, further comprising:
a third interlayer insulating film disposed over the second interlayer insulating film; and
multi-level interconnects buried in the third interlayer insulating film.

11. The semiconductor device according to claim 10, further comprising:
a first bump disposed over the third interlayer insulating film in the peripheral circuit region; and
a contact plug penetrating the second and third interlayer insulating films in the peripheral circuit region, the contact plug being coupled through the multi-level interconnects to the first bump, and the contact plug being coupled through the first interconnect to the via plug.

12. The semiconductor device according to claim 1, wherein the via plug comprises:
a copper bump;
a seed film covering side surfaces and a top surface of the copper bump, the top surface facing to the first interconnect; and
a metal film covering a bottom surface of the copper bump, the bottom surface being projected outside the semiconductor substrate.

13. A semiconductor device comprising:
a semiconductor substrate having a memory cell region and a peripheral circuit region;
a first interlayer insulating film over the semiconductor substrate;
a first local interconnect disposed over the first interlayer insulating film, the first local interconnect being in the peripheral circuit region, the first local interconnect comprising a first patterned portion of a conductive film;
a capacitive contact pad disposed over the first interlayer insulating film, the capacitive contact pad being in the memory cell region, the capacitive contact pad comprising a second patterned portion of the conductive film; and
a via plug penetrating the semiconductor substrate and the first interlayer insulating film, the via plug being coupled to the first local interconnect.

14. The semiconductor device according to claim 13, further comprising:
a capacitor being disposed in the memory cell region, the capacitor being coupled to the capacitive contact pad.

15. The semiconductor device according to claim 13, wherein the via plug includes a projecting portion that projects from the semiconductor substrate.

16. A semiconductor device comprising:
a semiconductor substrate having a memory cell region and a peripheral circuit region;
a first interlayer insulating film over the semiconductor substrate;
memory cells in the memory cell region;
buried word lines in a plurality of grooves of the semiconductor substrate in the memory cell region;
a first local interconnect disposed over the first interlayer insulating film, the first local interconnect being in the peripheral circuit region, the first local interconnect comprising a first patterned portion of a conductive film;
a capacitive contact pad disposed over the first interlayer insulating film, the capacitive contact pad being in the memory cell region, the capacitive contact pad comprising a second patterned portion of the conductive film;
a via plug penetrating the semiconductor substrate and the first interlayer insulating film, the via plug being coupled to the first interconnect, the via plug including a projecting portion that projects from the semiconductor substrate.

17. The semiconductor device according to claim 16, further comprising:
a capacitor being disposed in the memory cell region, the capacitor being coupled to the capacitive contact pad;
a second interlayer insulating film over the first interlayer insulating film, the second interlayer insulating film burying the first local interconnect and the capacitive contact pad;
a third interlayer insulating film over the second interlayer insulating film;
a fourth interlayer insulating film over the third interlayer insulating film;
a first bump over the fourth interlayer insulating film, the first bump being in the peripheral circuit region;
multi-level interconnects buried in the fourth interlayer insulating film, the multi-level interconnects being in the peripheral circuit region; and
a contact plug structure penetrating the second, third and fourth interlayer insulating films in the peripheral circuit region, the contact plug structure being coupled through the multi-level interconnects to the first bump, and the contact plug structure being coupled through the first local interconnect to the via plug.

18. The semiconductor device according to claim 17, further comprising:
a first isolating film in the semiconductor substrate, the first isolating film surrounding the via plug in the semiconductor substrate, the first isolating film isolating the via plug from outside the first isolating film.

19. The semiconductor device according to claim 17, further comprising:
a bottom insulating film on a first surface of the semiconductor substrate,
wherein the first interlayer insulating film is disposed over a second surface of the semiconductor substrate, the second surface is opposite to the first surface,
wherein the via plug penetrates the bottom insulating film, the semiconductor substrate and the first inter-layer insulating film, and
wherein the projecting portion projects from the first insulating film.

20. The semiconductor device according to claim 16, wherein the first local interconnect and the capacitive contact pad have substantially the same thickness and substantially the same material.
